(19) United States
(12) Patent Application Publication
(10) Pub. No.: US 2022/0173324 A1
(43) Pub. Date: Jun. 2, 2022

(54) ORGANIC LIGHT EMITTING DIODE AND ORGANIC LIGHT EMITTING DEVICE INCLUDING THE SAME

(71) Applicant: LG Display Co., Ltd., Seoul (KR)

(72) Inventors: Young-Jun YU, Paju-si (KR); Sang-Beom KIM, Paju-si (KR); Hyun-Chul CHOI, Paju-si (KR); In-Bum SONG, Paju-si (KR); Do-Han KIM, Paju-si (KR); Jeong-Dae SEO, Paju-si (KR); Tae-Shick KIM, Paju-si (KR)

(21) Appl. No.: 17/539,460

(22) Filed: Dec. 1, 2021

(30) Foreign Application Priority Data
Dec. 1, 2020 (KR) 10-2020-0165606

(51) Int. Cl. H01L 51/00; C09K 11/06

(52) U.S. Cl. CPC H01L 51/0058; H01L 51/008; C09K 11/06; H01L 51/5044; C09K 2211/1011; C09K 2211/1018; C09K 2211/1007

(57) ABSTRACT

An organic light emitting device that includes a substrate and an organic light emitting diode positioned on the substrate is provided. The organic light emitting diode includes a first electrode, a second electrode facing the first electrode, a first emitting material layer including a first compound and positioned between the first and second electrodes, and a second emitting material layer including a second compound and positioned between the first emitting material layer and the second electrode. Each of the first and second compounds is an anthracene derivative, and a deuteration ratio of the first compound is greater than that of the second compound.

### CROSS-REFERENCE TO RELATED APPLICATIONS

The present application claims the benefit of Korean Patent Application No. 10-2020-0165606 filed in the Republic of Korea on Dec. 1, 2020, which is hereby incorporated by reference in its entirety.

### BACKGROUND

### Technical Field

The present disclosure relates to an organic light emitting device, and more specifically, to an organic light emitting diode (OLED) having enhanced emitting efficiency and lifespan and an organic light emitting device including the same.

### Description of the Related Art

As demands for a flat panel display device having a small occupied area have been increased, an organic light emitting display device including an OLED has been the subject of recent research and development.

The OLED emits light by injecting electrons from a cathode as an electron injection electrode and holes from an anode as a hole injection electrode into an emitting material layer (EML), combining the electrons with the holes, generating an exciton, and transforming the exciton from an excited state to a ground state. A flexible substrate, for example, a plastic substrate, can be used as a base substrate where elements of an OLED are formed. In addition, the organic light emitting display device can be operated at a voltage (e.g., 10V or below) lower than a voltage required to operate other display devices. Moreover, the organic light emitting display device has advantages in the power consumption and the color sense.

The OLED includes a first electrode as an anode over a substrate, a second electrode, which is spaced apart from and faces the first electrode, and an organic emitting layer therebetween.

For example, the organic light emitting display device may include a red pixel region, a green pixel region and a blue pixel region, and the OLED may be formed in each of the red, green and blue pixel regions.

However, the OLED in the blue pixel does not provide sufficient emitting efficiency and lifespan such that the organic light emitting display device has a limitation in the emitting efficiency and the lifespan.

### BRIEF SUMMARY

The present disclosure is directed to an OLED and an organic light emitting device including the OLED that substantially obviate one or more of the problems associated with the limitations and disadvantages of the related conventional art.

Additional features and advantages of the present disclosure are set forth in the description which follows, and will be apparent from the description, or evident by practice of the present disclosure. The objectives and other advantages of the present disclosure are realized and attained by the features described herein as well as in the appended drawings.

To achieve these and other advantages in accordance with the purpose of the embodiments of the present disclosure, as described herein, an aspect of the present disclosure is an organic light emitting diode comprising a first electrode; a second electrode facing the first electrode; a first emitting material layer including a first compound and positioned between the first and second electrodes; and a second emitting material layer including a second compound and positioned between the first emitting material layer and the second electrode, wherein the first compound is represented by Formula 1, and the second compound is represented by Formula 2:

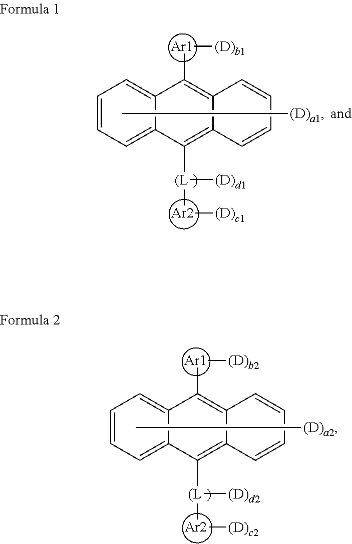

wherein each of Ar1 and Ar2 is independently a C6 to C20 aryl group, and L is a C6 to C20 arylene group, wherein each of a1 and a2 is independently an integer of 0 to 8, and each of b1, b2, c1, c2, d1 and d2 is independently an integer of 0 to 20, and wherein a sum of a1, b1, c1 and d1 is greater than a sum of a2, b2, c2 and d2.

Another aspect of the present disclosure is an organic light emitting device comprising a substrate; and an organic light emitting diode positioned on the substrate and including a first electrode; a second electrode facing the first electrode; a first emitting material layer including a first compound and positioned between the first and second electrodes; and a second emitting material layer including a second compound and positioned between the first emitting material layer and the second electrode, wherein the first compound is represented by Formula 1, and the second compound is represented by Formula 2:

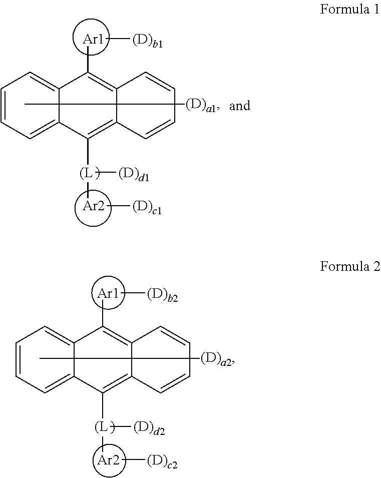

wherein each of Ar1 and Ar2 is independently a C6 to C20 aryl group, and L is a C6 to C20 arylene group, wherein each of a1 and a2 is independently an integer of 0 to 8, and each of b1, b2, c1, c2, d1 and d2 is independently an integer of 0 to 20, and wherein a sum of a1, b1, c1 and d1 is greater than a sum of a2, b2, c2 and d2.

It is to be understood that both the foregoing general description and the following detailed description are exemplary and explanatory and are intended to further explain the present disclosure as claimed.

### BRIEF DESCRIPTION OF THE SEVERAL VIEWS OF THE DRAWINGS

The accompanying drawings, which are included to provide a further understanding of the present disclosure and are incorporated in and constitute a part of this specification, illustrate embodiments of the present disclosure and together with the description serve to explain the principles of the present disclosure.

FIG. 1 is a schematic circuit diagram illustrating an organic light emitting display device of the present disclosure.

FIG. 2 is a schematic cross-sectional view illustrating an organic light emitting display device according to a first embodiment of the present disclosure.

FIG. 3 is a schematic cross-sectional view illustrating an OLED according to a second embodiment.

FIG. 4 is a schematic cross-sectional view illustrating an organic light emitting display device according to a third embodiment of the present disclosure.

FIG. 5 is a schematic cross-sectional view illustrating an organic light emitting display device according to a fourth embodiment of the present disclosure.

FIG. 6 is a schematic cross-sectional view illustrating an OLED according to a fifth embodiment.

### DETAILED DESCRIPTION

Reference will now be made in detail to some of the examples and preferred embodiments, which are illustrated in the accompanying drawings.

The OLED of the present disclosure includes a plurality of emitting parts, e.g., two or more emitting parts, and each of emitting material layers in two or more emitting parts includes an anthracene derivative. In this instance, the anthracene derivative in one emitting material layer and the anthracene derivative in another emitting material layer have different deuteration ratios. For example, an organic light emitting device including the OLED may be an organic light emitting display device or an organic lightening device. As an example, an organic light emitting display device, which is a display device including the OLED of the present disclosure, will be mainly described.

In the present disclosure, an aryl group, an arylene group, a heteroaryl group and a heteroarylene group may be unsubstituted or substituted with alkyl and/or aryl without specific definition.

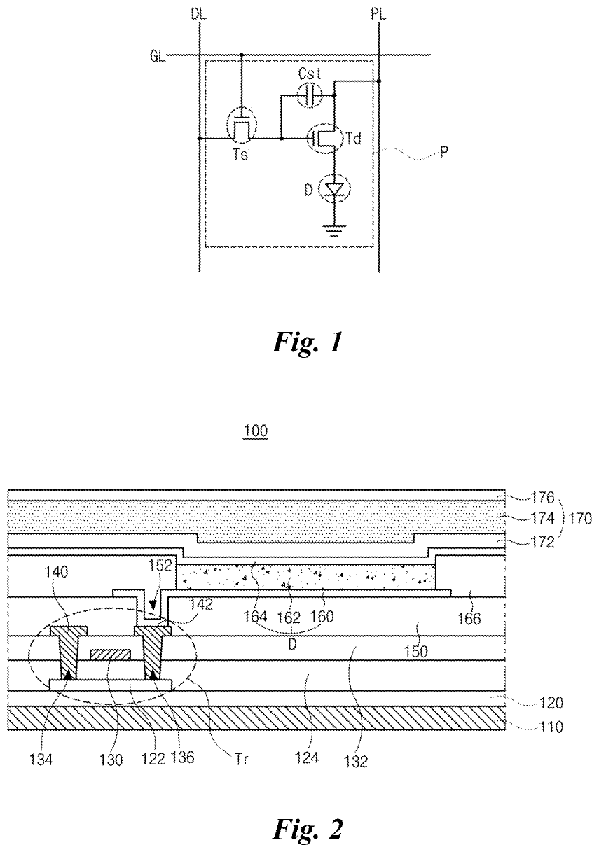

FIG. 1 is a schematic circuit diagram illustrating an organic light emitting display device of the present disclosure.

As illustrated in FIG. 1, a gate line GL and a data line DL, which cross each other to define a pixel region (pixel) P, and a power line PL are formed in an organic light emitting display device. A switching thin film transistor (TFT) Ts, a driving TFT Td, a storage capacitor Cst and an OLED D are formed in the pixel region P. The pixel region P may include a red pixel region, a green pixel region and a blue pixel region. In addition, the pixel region P may further include a white pixel region.

The switching thin film transistor Ts is connected to the gate line GL and the data line DL, and the driving thin film transistor Td and the storage capacitor Cst are connected between the switching thin film transistor Ts and the power line PL. The OLED D is connected to the driving thin film transistor Td. When the switching thin film transistor Ts is turned on by the gate signal applied through the gate line GL, the data signal applied through the data line DL is applied onto a gate electrode of the driving thin film transistor Td and one electrode of the storage capacitor Cst through the switching thin film transistor Ts.

The driving thin film transistor Td is turned on by the data signal applied onto the gate electrode so that a current proportional to the data signal is supplied from the power line PL to the OLED D through the driving thin film transistor Td. The OLED D emits light having a luminance proportional to the current flowing through the driving thin film transistor Td. In this case, the storage capacitor Cst is charged with a voltage proportional to the data signal so that the voltage of the gate electrode in the driving thin film transistor Td is kept constant during one frame. Therefore, the organic light emitting display device can display a desired image.

FIG. 2 is a schematic cross-sectional view illustrating an organic light emitting display device according to a first embodiment of the present disclosure.

As illustrated in FIG. 2, the organic light emitting display device 100 includes a substrate 110, a TFT Tr and an OLED D connected to the TFT Tr. For example, the organic light emitting display device 100 may include a red pixel region, a green pixel region and a blue pixel region, and the OLED D may be formed in each of the red, green and blue pixel regions. Namely, the OLEDs D emitting red light, green light and blue light may be provided in the red, green and blue pixel regions, respectively.

The substrate 110 may be a glass substrate or a flexible substrate. For example, the flexible substrate may be a polyimide (PI) substrate, a polyethersulfone (PES) substrate, a polyethylenenaphthalate (PEN) substrate, a polyethylene terephthalate (PET) substrate or a polycarbonate (PC) substrate.

A buffer layer 120 is formed on the substrate, and the TFT Tr is formed on the buffer layer 120. The buffer layer 120 may be omitted in some embodiments.

A semiconductor layer 122 is formed on the buffer layer 120. The semiconductor layer 122 may include an oxide semiconductor material or polycrystalline silicon.

When the semiconductor layer 122 includes the oxide semiconductor material, a light-shielding pattern (not shown) may be formed under the semiconductor layer 122. The light to the semiconductor layer 122 is shielded or blocked by the light-shielding pattern such that thermal degradation of the semiconductor layer 122 can be prevented. On the other hand, when the semiconductor layer 122 includes polycrystalline silicon, impurities may be doped into both sides of the semiconductor layer 122.

A gate insulating layer 124 is formed on the semiconductor layer 122. The gate insulating layer 124 may be formed of an inorganic insulating material such as silicon oxide or silicon nitride.

A gate electrode 130, which is formed of a conductive material, e.g., metal, is formed on the gate insulating layer 124, overlying a center of the semiconductor layer 122.

In FIG. 2, the gate insulating layer 124 is formed on an entire surface of the substrate 110. Alternatively, the gate insulating layer 124 may be patterned to have the same shape as the gate electrode 130.

An interlayer insulating layer 132, which is formed of an insulating material, is formed on the gate electrode 130. The interlayer insulating layer 132 may be formed of an inorganic insulating material, e.g., silicon oxide or silicon nitride, or an organic insulating material, e.g., benzocyclobutene or photo-acryl.

The interlayer insulating layer 132 includes first and second contact vias 134 and 136 contacting opposite sides of the semiconductor layer 122. The first and second contact vias 134 and 136 are positioned at opposite sides of the gate electrode 130 to be spaced apart from the gate electrode 130.

The first and second contact vias 134 and 136 are formed through the gate insulating layer 124. Alternatively, when the gate insulating layer 124 is patterned to have the same shape as the gate electrode 130, the first and second contact vias 134 and 136 is formed only through the interlayer insulating layer 132.

A source electrode 140 and a drain electrode 142, which are formed of a conductive material, e.g., metal, are formed on the interlayer insulating layer 132.

The source electrode 140 and the drain electrode 142 are spaced apart from each other with respect to the gate electrode 130 and respectively contact opposite sides of the semiconductor layer 122 through the first and second contact vias 134 and 136.

The semiconductor layer 122, the gate electrode 130, the source electrode 140 and the drain electrode 142 constitute the TFT Tr. The TFT Tr serves as a driving element. Namely, the TFT Tr may correspond to the driving TFT Td (of FIG. 1).

In the TFT Tr, the gate electrode 130, the source electrode 140, and the drain electrode 142 are positioned over the semiconductor layer 122. Namely, the TFT Tr has a coplanar structure.

Alternatively, in the TFT Tr, the gate electrode may be positioned under the semiconductor layer, and the source and drain electrodes may be positioned over the semiconductor layer such that the TFT Tr may have an inverted staggered structure. In this instance, the semiconductor layer may include amorphous silicon.

Although not shown, the gate line and the data line cross each other to define the pixel region, and the switching TFT is formed to be connected to the gate and data lines. The switching TFT is connected to the TFT Tr as the driving element.

In addition, the power line, which may be formed to be parallel to and spaced apart from one of the gate and data lines, and the storage capacitor for maintaining the voltage of the gate electrode of the TFT Tr in one frame may be further formed.

A passivation layer 150, which includes a drain contact via 152 contacting the drain electrode 142 of the TFT Tr, is formed to cover the TFT Tr.

A first electrode 160, which is connected to the drain electrode 142 of the TFT Tr through the drain contact via 152, is separately formed in each pixel region and on the passivation layer 150. The first electrode 160 may be an anode and may be formed of a conductive material having a relatively high work function. For example, the first electrode 160 may be formed of a transparent conductive material such as indium-tin-oxide (ITO) or indium-zinc-oxide (IZO).

When the organic light emitting display device 100 is operated in a bottom-emission type, the first electrode 160 may have a single-layered structure of the transparent conductive material layer. When the organic light emitting display device 100 is operated in a top-emission type, a reflection electrode or a reflection layer may be formed under the first electrode 160. For example, the reflection electrode or the reflection layer may be formed of silver (Ag) or aluminum-palladium-copper (APC) alloy. In this instance, the first electrode 160 may have a triple-layered structure of ITO/Ag/ITO or ITO/APC/ITO.

A bank layer 166 is formed on the passivation layer 150 to cover an edge of the first electrode 160. Namely, the bank layer 166 is positioned at a boundary of the pixel region and exposes a center of the first electrode 160 in the pixel region.

An organic emitting layer 162 is formed on the first electrode 160. The organic emitting layer 162 includes a plurality of emitting parts, e.g., at least two emitting parts. In addition, the organic emitting layer 162 may further include a charge generation layer between adjacent emitting parts.

Each emitting part includes an emitting material layer (EML). In addition, each emitting part may further include at least one of a hole injection layer (HIL), a hole transporting layer (HTL), an electron blocking layer (EBL), a hole blocking layer (HBL), an electron transporting layer (ETL) and an electron injection layer (EIL).

The organic emitting layer 162 is separated in each of the red, green and blue pixel regions. As illustrated below, at least two of the EMLs in the emitting parts include an anthracene derivative (e.g., an anthracene compound), and the anthracene derivative in one emitting material layer and the anthracene derivative in another emitting material layer have different deuteration ratios. As a result, the emitting efficiency and the lifespan of the OLED D and the organic light emitting display device 100 are improved.

The second electrode 164 is formed over the substrate 110 where the organic emitting layer 162 is formed. The second electrode 164 covers an entire surface of the display area and may be formed of a conductive material having a relatively low work function to serve as a cathode. For example, the second electrode 164 may be formed of aluminum (Al), magnesium (Mg), silver (Ag) or their alloy, e.g., Al—Mg alloy (AlMg) or Ag—Mg alloy (MgAg). In the top-emission type organic light emitting display device 100, the second electrode 164 may have a thin profile (small thickness) to provide a light transmittance property (or a semi-transmittance property).

The first electrode 160, the organic emitting layer 162 and the second electrode 164 constitute the OLED D.

An encapsulation film 170 is formed on the second electrode 164 to prevent penetration of moisture into the OLED D. The encapsulation film 170 includes a first inorganic insulating layer 172, an organic insulating layer 174 and a second inorganic insulating layer 176 sequentially stacked, but it is not limited thereto. The encapsulation film 170 may be omitted in some embodiments.

The Organic light emitting display device 100 may further include a polarization plate (not shown) for reducing an ambient light reflection. For example, the polarization plate may be a circular polarization plate. In the bottom-emission type organic light emitting display device 100, the polarization plate may be disposed under the substrate 110. In the top-emission type organic light emitting display device 100, the polarization plate may be disposed on or over the encapsulation film 170.

In addition, in the top-emission type organic light emitting display device 100, a cover window (not shown) may be attached to the encapsulation film 170 or the polarization plate. In this instance, the substrate 110 and the cover window have a flexible property such that a flexible organic light emitting display device may be provided.

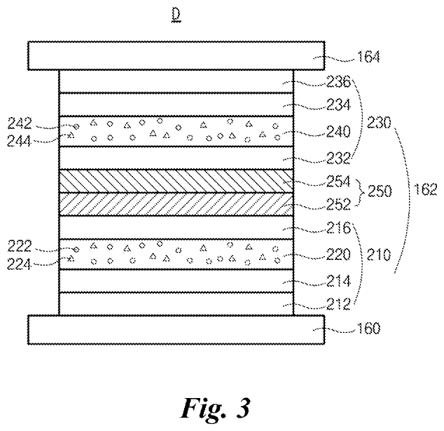

FIG. 3 is a schematic cross-sectional view illustrating an OLED according to a second embodiment.

As shown in FIG. 3, the OLED D includes the first and second electrodes 160 and 164 facing each other and the organic emitting layer 162 between the first and second electrodes 160 and 164. The organic emitting layer 162 includes a first emitting part 210 including a first EML 220 and a second emitting part 230 including a second EML 240. The organic emitting layer 162 may further include a charge generation layer (CGL) 250 between the first and second emitting parts 210 and 230.

The organic light emitting display device 100 (of FIG. 2) may include a red pixel region, a green pixel region and a blue pixel region, and the OLED D may be positioned in the blue pixel region.

The first electrode 160 is an anode injecting a hole, and the second electrode 164 is a cathode injecting an electron. One of the first and second electrodes 160 and 164 is a reflection electrode, and the other one of the first and second electrodes 160 and 164 is a transparent electrode (or a semi-transparent electrode).

For example, the first electrode 160 may be formed of ITO or IZO, and the second electrode 164 may be formed of Al, Mg, Ag, AlMg or MgAg.

The CGL 250 is positioned between the first and second emitting parts 210 and 230, and the first emitting part 210, the CGL 250 and the second emitting part 230 are sequentially stacked on the first electrode 160. Namely, the first emitting part 210 is positioned between the first electrode 160 and the CGL 250, and the second emitting part 230 is positioned between the second electrode 164 and the CGL 250.

The first emitting part 210 includes a first EML 220.

In addition, the first emitting part 210 may further include at least one of an HIL 212 between the first electrode 160 and the first EML 220, a first HTL 214 between the HIL 212 and the first EML 220, a first ETL 216 between the first EML 220 and the CGL 250 (or between the first EML 220 and the second emitting part 230).

Moreover, the first emitting part 210 may further include at least one of an EBL (not shown) between the first HTL 214 and the first EML 220 and an HBL (not shown) between the first EML 220 and the first ETL 216.

The second emitting part 230 includes a second EML 240.

In addition, the second emitting part 230 may further include at least one of a second HTL 232 between the CGL 250 and the second EML 240 (or between the first emitting part 210 and the second EML 240), a second ETL 234 between the second EML 240 and the second electrode 164 and an EIL 236 between the second ETL 234 and the second electrode 164.

Moreover, the second emitting part 230 may further include at least one of an EBL (not shown) between the second HTL 232 and the second EML 240 and an HBL (not shown) between the second EML 240 and the second ETL 234.

The first EML 220 includes a first compound 222, and the second EML 240 includes a second compound 242. In addition, the first EML 220 may further include a third compound 224, and the second EML 240 may further include a fourth compound 244. The first and second compounds 222 and 242 act as a host in the first and second EMLs 220 and 240, respectively, and the third and fourth compounds 224 and 244 act as a dopant (emitter) in the first and second EMLs 220 and 240, respectively.

The first and second compounds 222 and 242 are the anthracene derivatives and have different deuteration ratios. The third and fourth compounds 224 and 244 may be a boron derivative (a boron compound). Each of the first and second EMLs 220 and 240 includes the anthracene derivative and the boron derivative such that the blue light is emitted from each of the first and second EMLs 220 and 240. Namely, the OLED D is a blue OLED.

The first compound 222 included in the first EML 220, which is adjacent to the first electrode 160 being the anode, has a first deuteration ratio, and the second compound 242 included in the second EML 240, which is adjacent to the second electrode 164 being the cathode, has a second deuteration ratio being smaller than the first deuteration ratio. Namely, the OLED D includes a first compound 222 being the anthracene derivative and having the first deuteration ratio between the first and second electrodes 160 and 164 and a second compound 242 being the anthracene derivative and the second deuteration ratio, which is smaller than the first deuteration ratio, between the first EML 220 and the second electrode 164.

The first compound 222 may be represented by Formula 1, and the second compound 242 may be represented by Formula 2.

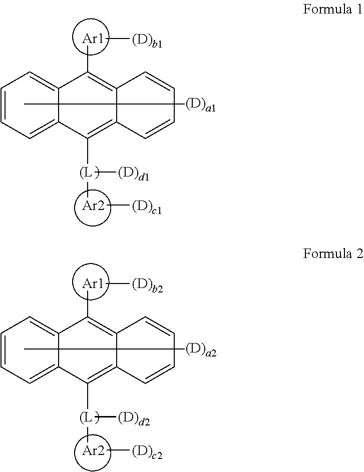

In Formulas 1 and 2, each of Ar1 and Ar2 is independently a C6 to C20 aryl group, and L is a C6 to C20 arylene group. Each of a1 and a2 is independently an integer of 0 to 8, and each of b1, b2, c1, c2, d1 and d2 is independently an integer of 0 to 20. A sum of a1, b1, c1 and d1 is greater than a sum of a2, b2, c2 and d2. Here, D is deuterium, each of a1 and a2 is a number of deuterium on a corresponding anthracene in Formulas 1 and 2, each of b1 and b2 is a number of deuterium on a corresponding Ar1 in Formulas 1 and 2, each of c1 and c2 is a number of deuterium on a corresponding L in Formulas 1 and 2, and each of d1 and d2 is a number of deuterium on a corresponding Ar2 in Formulas 1 and 2. The bond crossing all the rings means that any and all the locations of the entire fused ring can be substituted.

The first and second compounds 222 and 242 may be an anthracene derivative having the same chemical structure (or chemical formula) but different deuteration ratios. In other words, the first compound 222 has a first deuteration ratio, and the second compound 242 has a second deuteration ratio.

For example, in Formulas 1 and 2, each of Ar1 and Ar2 may be independently selected from the group consisting of phenyl, naphthyl and anthracenyl, and L may be selected from the group consisting of phenylene and naphthylene. In one embodiment, Ar1 may be 1-naphthyl, Ar2 may be 2-naphthyl, and L may be phenylene.

The first compound 222 in Formula 1 may be represented by Formula 3, and the second compound 242 in Formula 2 may be represented by Formula 4.

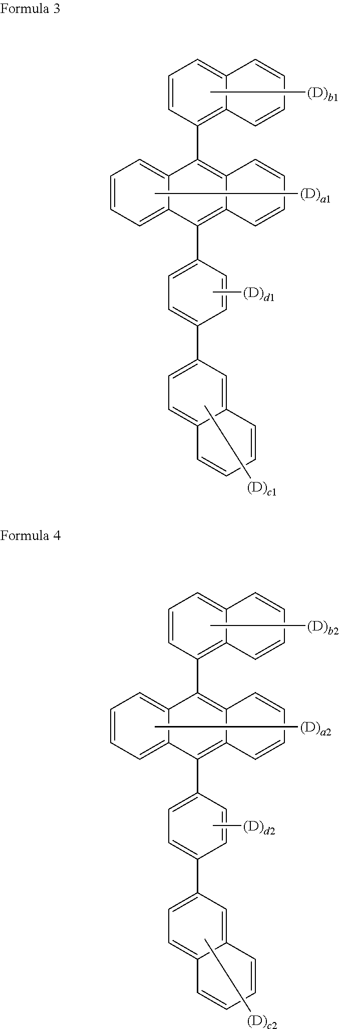

In Formulas 3 and 4, each of a1 and a2 is independently an integer of 0 to 8, each of b1, b2, c1 and c2 is independently an integer of 0 to 7, and each of d1 and d2 is independently an integer of 0 to 4. A sum of a1, b1, c1 and d1 is greater than a sum of a2, b2, c2 and d2. The bond crossing all the rings means that any and all the locations of the entire fused ring can be substituted.

For example, the deuteration ratio of the first compound 222 in Formula 3 may be equal to or greater than about 70%, e.g., being equal to or greater than 84%, preferably 100%. The deuteration ratio of the second compound 242 in Formula 4 may be equal to or smaller than about 73%, e.g., 0 to 73%.

For example, in Formula 3, a1 is 8, b1 is 7, c1 is 7, and d1 is 4, thus the first compound 222 may be a compound in Formula 5. Namely, the first compound 222 may be an anthracene derivative, in which all hydrogens are deuterated (e.g., a wholly-deuterated anthracene derivative).

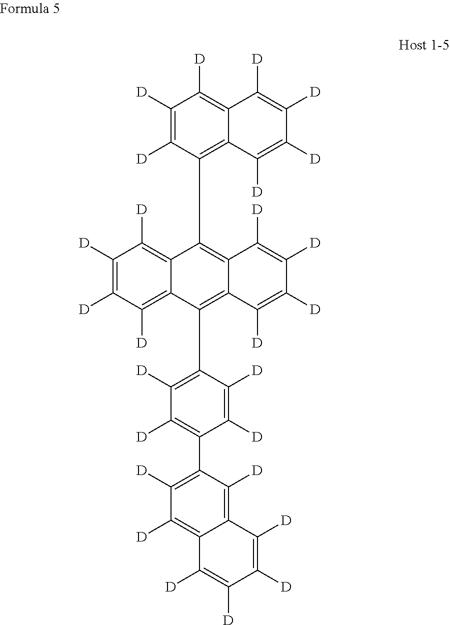 [SMILES: [2H]c1c([2H])c(-c2c3c([2H])c([2H])c([2H])c([2H])c3c(-c3c([2H])c([2H])c([2H])c4c([2H])c([2H])c([2H])c([2H])c34)c3c([2H])c([2H])c([2H])c([2H])c23)c([2H])c([2H])c1-c1c([2H])c([2H])c2c([2H])c([2H])c([2H])c([2H])c2c1[2H]]

For example, in Formula 4, at least one of a2, b2, c2 and d2 is 0, thus the second compound 242 may be one of compounds in Formula 6. Namely, the second compound 242 may be an anthracene derivative, in which no hydrogen is deuterated (e.g., a non-deuterated anthracene derivative) or a part of hydrogens are deuterated (e.g., a partially-deuterated anthracene derivative).

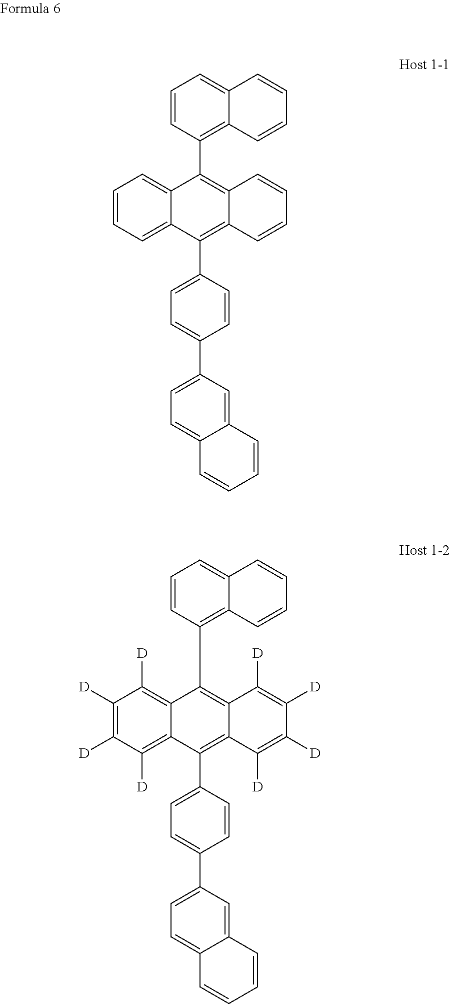

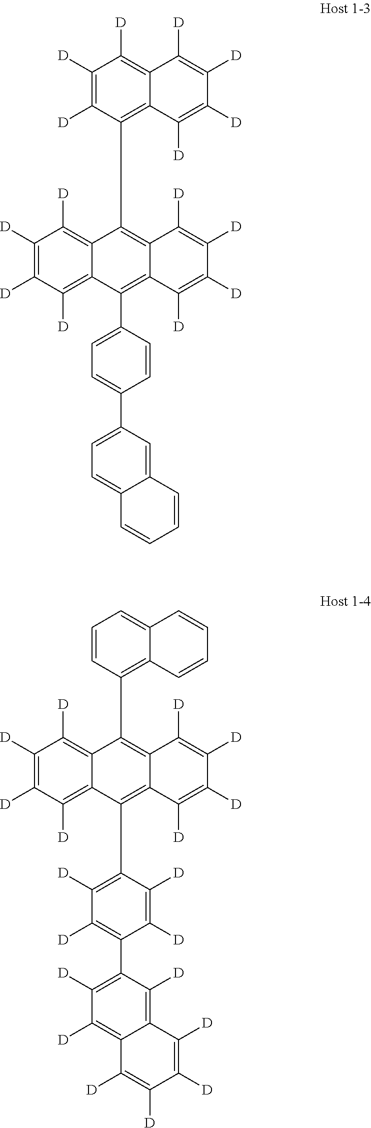 [SMILES: [2H]c1c([2H])c([2H])c2c(-c3c4c([2H])c([2H])c([2H])c([2H])c4c(-c4ccc(-c5ccc6ccccc6c5)cc4)c4c([2H])c([2H])c([2H])c([2H])c34)c([2H])c([2H])c([2H])c2c1[2H] ; [2H]c1c([2H])c(-c2c3c([2H])c([2H])c([2H])c([2H])c3c(-c3cccc4ccccc34)c3c([2H])c([2H])c([2H])c([2H])c23)c([2H])c([2H])c1-c1c([2H])c([2H])c2c([2H])c([2H])c([2H])c([2H])c2c1[2H]]

Namely, the first compound 222 included in the first EML 220 being closer to the first electrode 160 as the anode may have a first deuteration ratio, e.g., 100%, and the second compound 242 included in the second EML 240 being closer to the second electrode 164 as the cathode may have a second deuteration ratio, e.g., 0%, about 30%, about 57%, or about 73%, being smaller than the first deuteration ratio.

Each of the third and fourth compounds 224 and 244 may be represented by Formula 7.

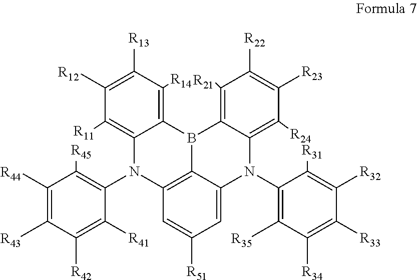

In Formula 7, each of R₁₁, R₁₂, R₁₃ and R₁₄, each of R₂₁, R₂₂, R₂₃ and R₂₄, each of R₃₁, R₃₂, R₃₃, R₃₄ and R₃₅ and each of R₄₁, R₄₂, R₄₃, R₄₄ and R₄₅ is independently selected from the group of hydrogen, deuterium (D), a C1 to C10 alkyl group, a C6 to C30 aryl group unsubstituted or substituted with C1-C10 alkyl, a C12 to C30 arylamino group and a C5 to C30 heteroaryl group, or adjacent two of R₁₁, R₁₂, R₁₃ and R₁₄, adjacent two of R₂₁, R₂₂, R₂₃ and R₂₄, adjacent two of R₃₁, R₃₂, R₃₃, R₃₄ and R₃₅ and adjacent two of R₄₁, R₄₂, R₄₃, R₄₄ and R₄₅ together with the carbon atoms to which they are attached are connected (combined) to form a fused ring, e.g., an aryl ring or a heteroaryl ring. R₅₁ is selected from the group consisting of hydrogen, D, a C1 to C10 alkyl group and a C3 to C30 cycloalkyl group, a C6 to C30 aryl group, a C5 to C30 heteroaryl group unsubstituted or substituted with at least one of deuterium and C1-C10 alkyl and a C6 to C30 arylamino group unsubstituted or substituted with at least one of deuterium and C1-C10 alkyl.

Each of R₁₁, R₁₂, R₁₃ and R₁₄, each of R₂₁, R₂₂, R₂₃ and R₂₄, each of R₃₁, R₃₂, R₃₃, R₃₄ and R₃₅ and each of R₄₁, R₄₂, R₄₃, R₄₄ and R₄₅ may be same or different.

In the boron derivative being the third and fourth compounds 224 and 244, the benzene ring, which is connected to boron atom and two nitrogen atoms, is substituted with an unsubstituted or deuterium-substituted (e.g., D-substituted) C12 to C30 arylamino group or an unsubstituted or D-substituted C5 to C30 heteroaryl group such that the emitting property of the OLED D may be further improved. Namely, when R₅₁ in Formula 7 is an unsubstituted or D-substituted C12 to C30 arylamino group or an unsubstituted or D-substituted C5 to C30 heteroaryl group, e.g., carbazole, the emitting property of the OLED D may be further improved.

For example, the C1 to C10 alkyl group may be one of methyl, ethyl, propyl, butyl, and pentyl (amyl). The substituted or unsubstituted C6 to C30 aryl group may be one of phenyl and naphthyl and may be substituted with D or C1-C10 alkyl. In addition, the C12 to C30 arylamino group may be one of diphenylamino group, phenyl-biphenylamino group, phenyl-naphthylamino group, and dinaphthylamino group, and the C5 to C30 heteroaryl group may be one of pyridyl, quinolinyl, carbazolyl, dibenzofuranyl, and dibenzothiophenyl. In this instance, each of arylamino group, aryl group, alkyl group, and heteroaryl group may be substituted with D.

Each of R₁₁, R₁₂, R₁₃ and R₁₄, each of R₂₁, R₂₂, R₂₃ and R₂₄, each of R₃₁, R₃₂, R₃₃, R₃₄ and R₃₅ and each of R₄₁, R₄₂, R₄₃, R₄₄ and R₄₅ may be independently selected from the group consisting of H, D, methyl, ethyl, propyl, butyl, and pentyl (amyl). R₅₁ may be selected from the group consisting of an unsubstituted or D-substituted diphenylamino group, an unsubstituted or D-substituted phenyl-biphenylamino group, an unsubstituted or D-substituted phenyl-naphthylamino group, an unsubstituted or D-substituted biphenyl-naphthylamino group, and an unsubstituted or D-substituted carbazoyl.

In one embodiment, one of R₁₁, R₁₂, R₁₃ and R₁₄, one of R₂₁, R₂₂, R₂₃ and R₂₄, one of R₃₁, R₃₂, R₃₃, R₃₄ and R₃₅ and one of R₄₁, R₄₂, R₄₃, R₄₄ and R₄₅ may be tert-butyl or tert-pentyl (or tert-amyl), and the rest of R₁₁, R₁₂, R₁₃ and R₁₄, the rest of R₂₁, R₂₂, R₂₃ and R₂₄, the rest of R₃₁, R₃₂, R₃₃, R₃₄ and R₃₅ and the rest of R₄₁, R₄₂, R₄₃, R₄₄ and R₄₅ may be hydrogen or deuterium, and R₅₁ may be a D-substituted diphenylamino group. When the compound is used as the dopant, the emitting efficiency and the color sense of the OLED are improved.

The third and fourth compounds 224 and 244 may be same or different and may be independently one of the compounds in Formula 8.

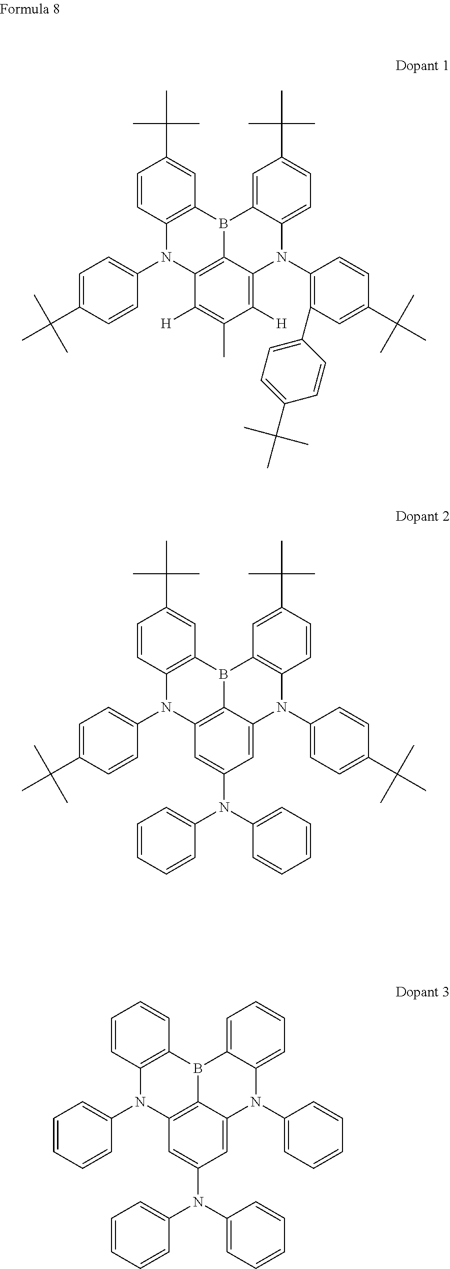

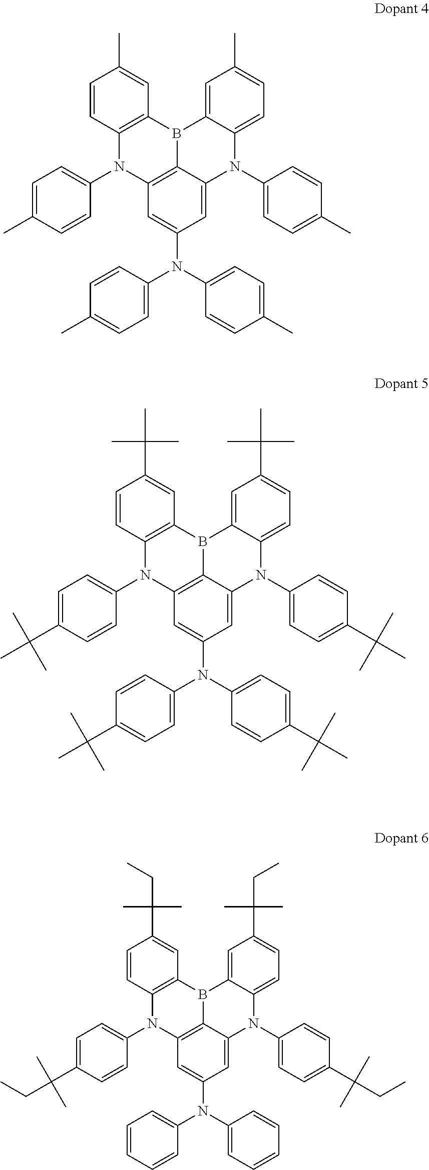

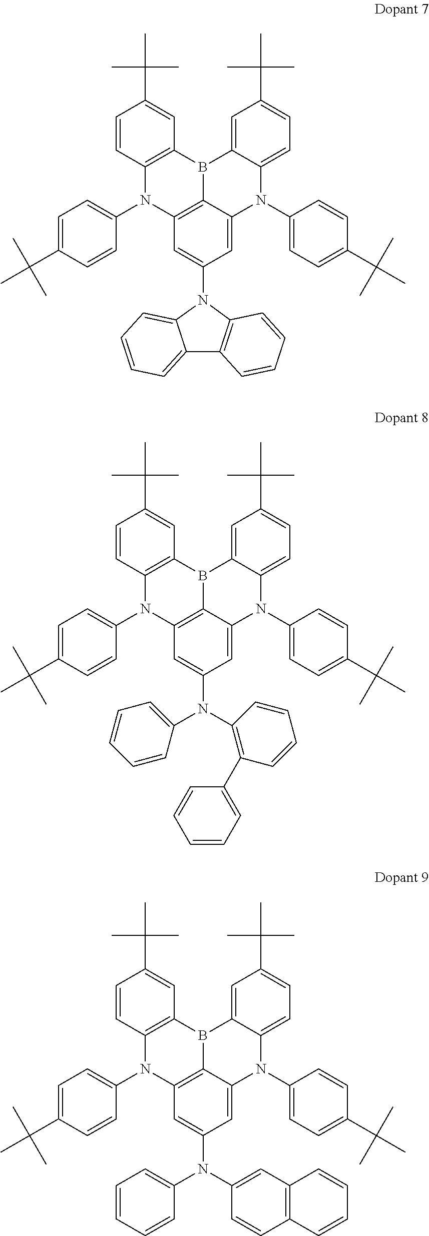

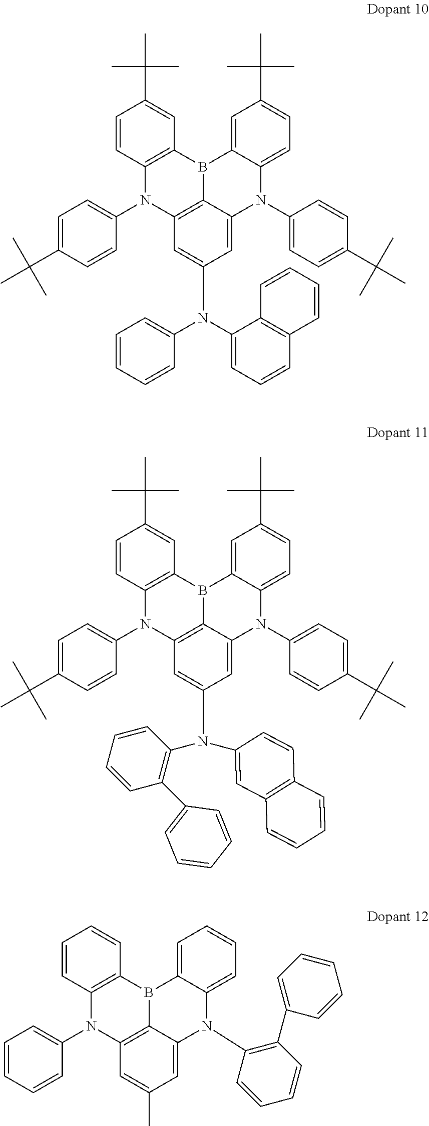

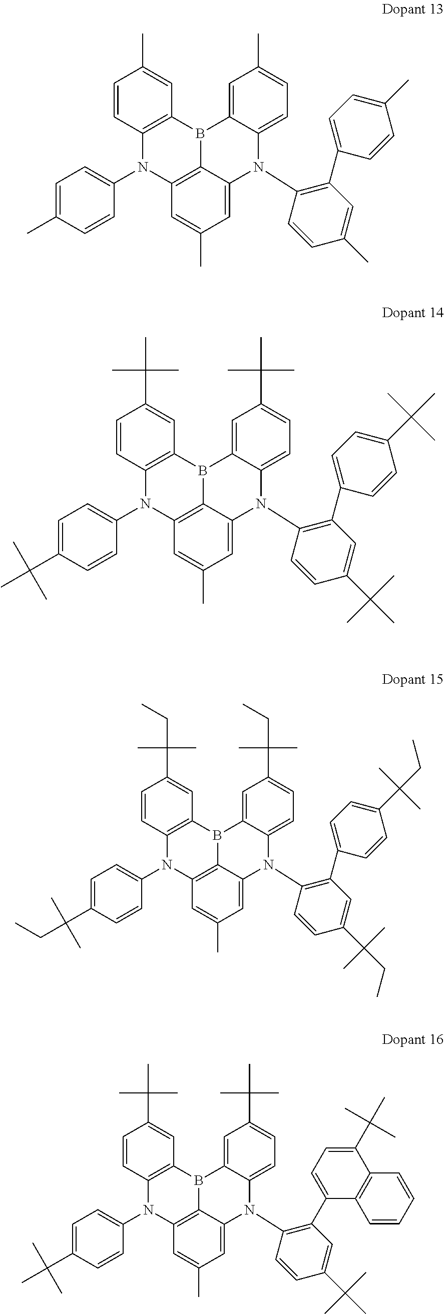

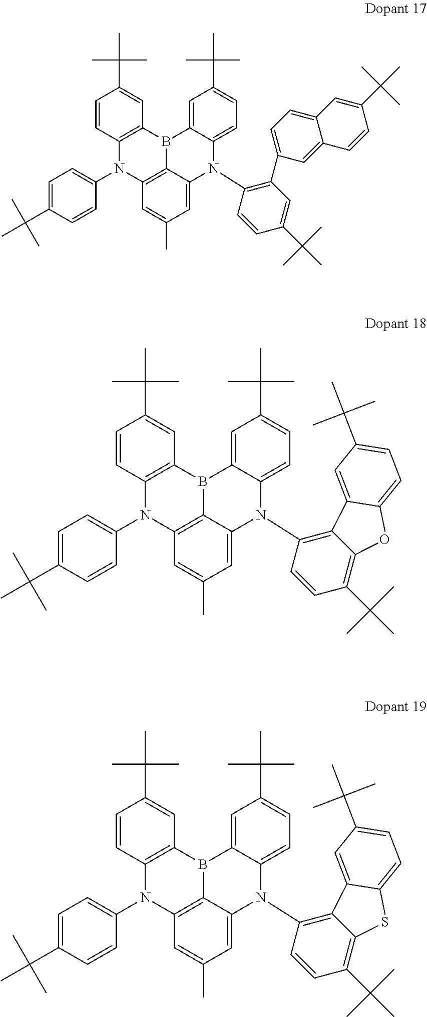

The third compound 224 may have a weight % of 0.1 to 10, e.g., 1 to 5, in the first EML 220, and the fourth compound 244 may have a weight % of 0.1 to 10, e.g., 1 to 5, in the second EML 240. For example, the weight % of the third compound 224 in the first EML 220 may be equal to or greater than that of the fourth compound 244 in the second EML 240.

Each of the first and second EMLs 220 and 240 may have a thickness of 100 Å to 1000, e.g., 100 to 500 Å, but it is not limited thereto. For example, the thickness of the first EML 220 may be equal to or smaller than that of the second EML 240.

The CGL 250 is positioned between the first and second emitting parts 210 and 230. Namely, the first and second emitting parts 210 and 230 are connected through the CGL 250. The CGL 250 may be a P-N junction CGL of an N-type CGL 252 and a P-type CGL 254.

The N-type CGL 252 is positioned between the first ETL 216 and the second HTL 232, and the P-type CGL 254 is positioned between the N-type CGL 252 and the second HTL 232.

In the OLED D, the first EML 220 includes the first compound 222, which is an anthracene derivative and has a first deuteration ratio, and the second EML 240 includes the second compound 242, which is an anthracene derivative and has a second deuteration ratio being smaller than the first deuteration ratio. Accordingly, the OLED D and the organic light emitting display device 100 have advantages in the emitting efficiency and the lifespan.

In addition, since the first and second emitting parts 210 and 230 for emitting blue light are stacked, the organic light emitting display device 100 provides an image having high color temperature.

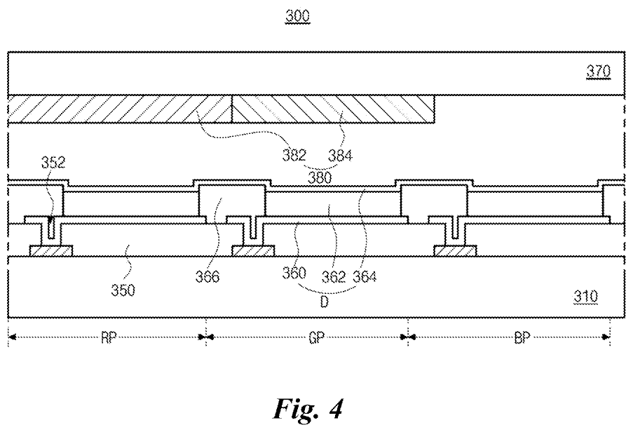

FIG. 4 is a schematic cross-sectional view illustrating an organic light emitting display device according to a third embodiment of the present disclosure.

As shown in FIG. 4, the organic light emitting display device 300 includes a first substrate 310, where a red pixel region RP, a green pixel region GP and a blue pixel region BP are defined, a second substrate 370 facing the first substrate 310, an OLED D, which is positioned between the first and second substrates 310 and 370 and providing white emission, and a color conversion layer 380 between the OLED D and the second substrate 370 in the red pixel region RP and the green pixel region GP.

Although not shown, a color filter may be formed between the second substrate 370 and each color conversion layer 380.

A TFT Tr, which corresponding to each of the red, green and blue pixel regions RP, GP and BP, is formed on the first substrate 310, and a passivation layer 350, which has a drain contact via 352 contacting an electrode, e.g., a drain electrode, of the TFT Tr is formed to cover the TFT Tr.

The OLED D including a first electrode 360, an organic emitting layer 362 and a second electrode 364 is formed on the passivation layer 350. In this instance, the first electrode 360 may be connected to the drain electrode of the TFT Tr through the drain contact via 352.

The OLED D has a structure of FIG. 3 and is disposed in all of the red pixel region RP, the green pixel region GP and the blue pixel region BP. The OLED D emits the blue light. Namely, organic emitting layer 362 includes a first emitting part including a first EML and a second emitting part including a second EML and positioned between the first emitting part and the second electrode. The first EML includes a first compound being an anthracene derivative and having a first deuteration ratio, and the second EML includes a second compound being an anthracene derivative and having a second deuteration ratio. The second deuteration ratio is smaller than the first deuteration ratio.

A bank layer 366 covering an edge of the first electrode 360 is formed at a boundary of the red, green and blue pixel regions RP, GP and BP. Namely, the bank layer 366 is positioned at a boundary of the red, green and blue pixel regions RP, GP and BP and exposes a center of the first electrode 360 in the red, green and blue pixel regions RP, GP and BP. As mentioned above, since the OLED D emits the white light in the red, green and blue pixel regions RP, GP and BP, the emitting layer 362 may be formed as a common layer in the red, green and blue pixel regions RP, GP and BP without separation in the red, green and blue pixel regions RP, GP and BP. The bank layer 366 may be formed to prevent the current leakage at an edge of the first electrode 360 and may be omitted.

The color conversion layer 380 includes a first color conversion layer 382 corresponding to the red pixel region RP and a second color conversion layer 384 corresponding to the green pixel region GP. The color conversion layer 380 is not presented in the blue pixel region BP. Accordingly, the OLED D in the blue pixel region BP may face the second electrode 370 without a color conversion layer. For example, the color conversion layer 380 may include an inorganic color conversion material such as a quantum dot.

The blue light from the OLED D is converted into the red light by the first color conversion layer 382 in the red pixel region RP, and the blue light from the OLED D is converted into the green light by the second color conversion layer 384 in the green pixel region GP.

Accordingly, the organic light emitting display device 300 can display a full-color image.

On the other hand, when the light from the OLED D passes through the first substrate 310, the color conversion layer 380 is disposed between the OLED D and the first substrate 310.

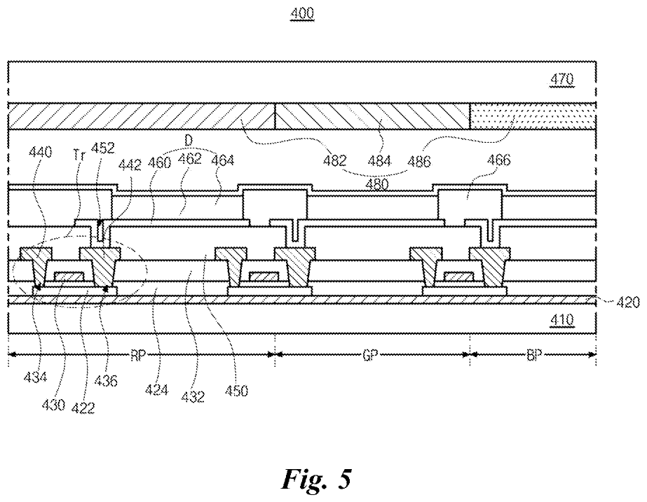

FIG. 5 is a schematic cross-sectional view illustrating an organic light emitting display device according to a fourth embodiment of the present disclosure.

As shown in FIG. 5, the organic light emitting display device 400 includes a first substrate 410, where a red pixel region RP, a green pixel region GP and a blue pixel region BP are defined, a second substrate 470 facing the first substrate 410, an OLED D, which is positioned between the first and second substrates 410 and 470 and providing white emission, and a color filter layer 480 between the OLED D and the second substrate 470.

Each of the first and second substrates 410 and 470 may be a glass substrate or a plastic substrate. For example, each of the first and second substrates 410 and 470 may be a polyimide substrate.

A buffer layer 420 is formed on the substrate, and the TFT Tr corresponding to each of the red, green and blue pixel regions RP, GP and BP is formed on the buffer layer 420. The buffer layer 420 may be omitted.

A semiconductor layer 422 is formed on the buffer layer 420. The semiconductor layer 422 may include an oxide semiconductor material or polycrystalline silicon.

A gate insulating layer 424 is formed on the semiconductor layer 422. The gate insulating layer 424 may be formed of an inorganic insulating material such as silicon oxide or silicon nitride.

A gate electrode 430, which is formed of a conductive material, e.g., metal, is formed on the gate insulating layer 424 to correspond to a center of the semiconductor layer 422.

An interlayer insulating layer 432, which is formed of an insulating material, is formed on the gate electrode 430. The interlayer insulating layer 432 may be formed of an inorganic insulating material, e.g., silicon oxide or silicon nitride, or an organic insulating material, e.g., benzocyclobutene or photo-acryl.

The interlayer insulating layer 432 includes first and second contact vias 434 and 436 contacting opposite sides of the semiconductor layer 422. The first and second contact vias 434 and 436 are positioned at opposite sides of the gate electrode 430 to be spaced apart from the gate electrode 430.

A source electrode 440 and a drain electrode 442, which are formed of a conductive material, e.g., metal, are formed on the interlayer insulating layer 432.

The source electrode 440 and the drain electrode 442 are spaced apart from each other with respect to the gate electrode 430 and respectively contact opposite sides of the semiconductor layer 422 through the first and second contact vias 434 and 436.

The semiconductor layer 422, the gate electrode 430, the source electrode 440 and the drain electrode 442 constitute the TFT Tr. The TFT Tr serves as a driving element. Namely, the TFT Tr may correspond to the driving TFT Td (of FIG. 1).

Although not shown, the gate line and the data line cross each other to define the pixel region, and the switching TFT is formed to be connected to the gate and data lines. The switching TFT is connected to the TFT Tr as the driving element.

In addition, the power line, which may be formed to be parallel to and spaced apart from one of the gate and data lines, and the storage capacitor for maintaining the voltage of the gate electrode of the TFT Tr in one frame may be further formed.

A passivation layer 450, which includes a drain contact via 452 contacting the drain electrode 442 of the TFT Tr, is formed to cover the TFT Tr.

A first electrode 460, which is connected to the drain electrode 442 of the TFT Tr through the drain contact via 452, is separately formed in each pixel region. The first electrode 460 may be an anode and may be formed of a conductive material having a relatively high work function. For example, the first electrode 460 may be formed of a transparent conductive material such as indium-tin-oxide (ITO) or indium-zinc-oxide (IZO).

When the organic light emitting display device 400 is operated in a bottom-emission type, the first electrode 460 may have a single-layered structure of the transparent conductive material layer. When the organic light emitting display device 400 is operated in a top-emission type, a reflection electrode or a reflection layer may be formed under the first electrode 460. For example, the reflection electrode or the reflection layer may be formed of silver (Ag) or aluminum-palladium-copper (APC) alloy. In this instance, the first electrode 460 may have a triple-layered structure of ITO/Ag/ITO or ITO/APC/ITO.

A bank layer 466 is formed on the passivation layer 450 to cover an edge of the first electrode 460. Namely, the bank layer 466 is positioned at a boundary of the pixel region and exposes a center of the first electrode 460 in the red, green and blue pixel regions RP, GP and BP.

An organic emitting layer 462 is formed on the first electrode 460. The organic emitting layer 462 includes a first emitting part being adjacent to the first electrode 460 and emitting the blue light, a second emitting part being adjacent to the second electrode 464 and emitting the blue light and at least one third emitting part being positioned between the first and second emitting parts. The third emitting part emits the yellow-green light or the red-green light.

In addition, the organic emitting layer 462 may further include a charge generation layer between adjacent emitting parts.

Each emitting part includes an emitting material layer (EML). In addition, each emitting part may further include at least one of a hole injection layer (HIL), a hole transporting layer (HTL), an electron blocking layer (EBL), a hole blocking layer (HBL), an electron transporting layer (ETL) and an electron injection layer (EIL).

The EML layer in the first and second emitting parts includes an anthracene derivative (e.g., an anthracene compound), and the anthracene derivative in the first EML and the anthracene derivative in the second EML have different deuteration ratios. As a result, the emitting efficiency and the lifespan of the OLED D and the organic light emitting display device 400 are improved.

The second electrode 464 is formed over the substrate 410 where the organic emitting layer 462 is formed. The second electrode 464 covers an entire surface of the display area and may be formed of a conductive material having a relatively low work function to serve as a cathode. For example, the second electrode 464 may be formed of aluminum (Al), magnesium (Mg), silver (Ag) or their alloy, e.g., Al—Mg alloy (AlMg) or Ag—Mg alloy (MgAg).

Since the light from the organic emitting layer 462 is incident to the color filter layer 480 through the second electrode 464, the second electrode 464 has a thin profile (small thickness) to provide a light transmittance property (or a semi-transmittance property).

The first electrode 460, the organic emitting layer 462 and the second electrode 464 constitute the OLED D, and the OLED D in the red, green and blue pixel regions RP, GP and BP provides the blue emission.

Since the OLED D emits the white light in the red, green and blue pixel regions RP, GP and BP, the emitting layer 462 may be formed as a common layer in the red, green and blue pixel regions RP, GP and BP without separation in the red, green and blue pixel regions RP, GP and BP. The bank layer 466 may be formed to prevent the current leakage at an edge of the first electrode 460 and may be omitted.

The color filter layer 480 is positioned over the OLED D and includes a red color filter 482, a green color filter 484 and a blue color filter 486 respectively corresponding to the red, green and blue pixel regions RP, GP and BP. The color filter layer 480 may be formed on a lower surface (e.g., an inner surface) of the second substrate 470.

Although not shown, the color filter layer 480 may be attached to the OLED D by using an adhesive layer. Alternatively, the color filter layer 480 may be formed directly on the OLED D.

An encapsulation film (not shown) may be formed to prevent penetration of moisture into the OLED D. For example, the encapsulation film may include a first inorganic insulating layer, an organic insulating layer and a second inorganic insulating layer sequentially stacked, but it is not limited thereto.

The Organic light emitting display device 400 may further include a polarization plate (not shown) for reducing an ambient light reflection. For example, the polarization plate may be a circular polarization plate. The polarization plate may be disposed at an outer side of the second substrate 470. Alternatively, in the bottom-emission type organic light emitting display device 400, the polarization plate may be disposed under the first substrate 410.

In FIG. 5, when the light from the OLED D passes through the second electrode 464, and the color filter layer 480 is disposed on or over the OLED D. Alternatively, when the light from the OLED D passes through the first electrode 460, the color filter layer 480 may be disposed between the OLED D and the first substrate 410.

A color conversion layer (not shown) may be formed between the OLED D and the color filter layer 480. The color conversion layer may include a red color conversion layer, a green color conversion layer and a blue color conversion layer respectively corresponding to the red, green and blue pixel regions RP, GP and BP. The white light from the OLED D is converted into the red light, the green light and the blue light by the red, green and blue color conversion layer, respectively.

As described above, the white light from the organic light emitting diode D passes through the red color filter 482, the green color filter 484 and the blue color filter 486 in the red pixel region RP, the green pixel region GP and the blue pixel region BP such that the red light, the green light and the blue light are provided from the red pixel region RP, the green pixel region GP and the blue pixel region BP, respectively.

In FIG. 5, the OLED D emitting the white light is used for a display device. Alternatively, the OLED D may be formed on an entire surface of a substrate without at least one of the driving element and the color filter layer to be used for a lightening device. The display device and the lightening device each including the OLED D of the present disclosure may be referred to as an organic light emitting device.

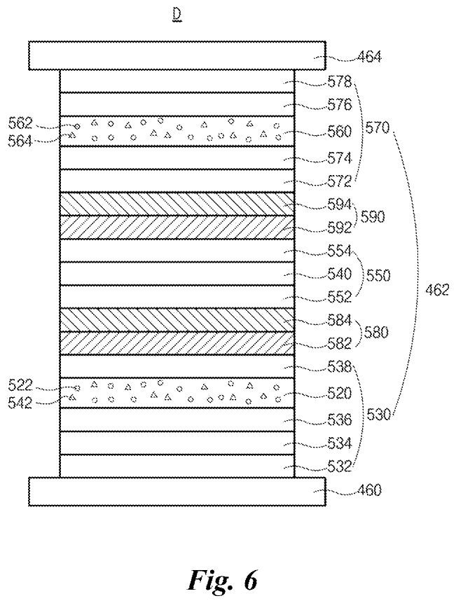

FIG. 6 is a schematic cross-sectional view illustrating an OLED according to a fifth embodiment. The OLED D in FIG. 6 can be applied to the organic light emitting display device in FIG. 5.

As shown in FIG. 6, the organic emitting layer 462, which is positioned between the first and second electrode 460 and 464, includes a first emitting part 530 including a first EML 520, a second emitting part 570 including a second EML 560 and a third emitting part 550 including a third EML 540. The organic emitting layer 462 may further include a first CGL 580 between the first and third emitting parts 530 and 550 and a second CGL 590 between the second and third emitting parts 570 and 550.

The first electrode 460 is an anode injecting a hole, and the second electrode 464 is a cathode injecting an electron. One of the first and second electrodes 460 and 464 is a reflection electrode, and the other one of the first and second electrodes 460 and 464 is a transparent electrode (or a semi-transparent electrode).

For example, the first emitting part 530, the first CGL 580, the third emitting part 550, the second CGL 590 and the second emitting part 570 are sequentially stacked on the first electrode 460. In other words, the first emitting part 530 is positioned between the first electrode 460 and the first CGL 580, the third emitting part 550 is positioned between the first and second CGLs 580 and 590, and the second emitting part 570 is positioned between the second electrode 464 and the second CGL 590.

The first emitting part 530 includes the first EML 520. In addition, the first emitting part 530 may further include an HIL 532 under the first EML 520, a first HTL 534 between the first EML 520 and the HIL 532, a first EBL 536 between the first EML 520 and the first HTL 534 and a first ETL 538 on or over the first EML 520. Namely, the HIL 532, the first HTL 534 and the first EBL 536 are sequentially stacked between the first electrode 460 and the first EML 520, and the first ETL 538 is positioned between the first EML 520 and the first CGL 580. The first emitting part 530 may further include an HBL between the first EML 520 and the first ETL 538.

The second emitting part 570 include the second EML 560. In addition, the second emitting part 570 may further include a second HTL 572 under the second EML 560, a second EBL 574 between the second EML 560 and the second HTL 572, an EIL 578 over the second EML 560, and a second ETL 576 between the second EML 560 and the EIL 578. The second emitting part 570 may further include an HBL between the second ETL 576 and the second EML 560.

The first EML 520 includes a first compound 522, and the second EML 560 includes a second compound 562. In addition, the first EML 520 may further include a third compound 524, and the second EML 560 may further include a fourth compound 564. The first and second compounds 522 and 562 act as a host in the first and second EMLs 520 and 560, respectively, and the third and fourth compounds 524 and 564 act as a dopant (emitter) in the first and second EMLs 520 and 560, respectively.

The first and second compounds 522 and 562 are the anthracene derivatives and have different deuteration ratios. The third and fourth compounds 524 and 564 may be a boron derivative (a boron compound). Each of the first and second EMLs 520 and 560 includes the anthracene derivative and the boron derivative such that the blue light is emitted from each of the first and second EMLs 520 and 560. Namely, the OLED D is a blue OLED.

The first compound 522 being the anthracene derivative included in the first EML 520, which is adjacent to the first electrode 460 being the anode, has a first deuteration ratio, and the second compound 562 being the anthracene derivative included in the second EML 560, which is adjacent to the second electrode 464 being the cathode, has a second deuteration ratio being smaller than the first deuteration ratio. Namely, the first and second compounds 522 and 562 may be an anthracene derivative having the same chemical structure (chemical formula) but different deuteration ratios.

The first compound 522 is represented by Formula 1 or Formula 3, and the second compound 562 is represented by Formula 2 or Formula 4. For example, the first compound 522 may be the compound in Formula 5, and the second compound 562 may be one of the compounds in Formula 6.

The third and fourth compounds 524 and 564 may be represented by Formula 7 and may be same or different. For example, each of the third and fourth compounds 524 and 564 may be independently one of the compounds in Formula 8.

The third compound 524 may have a weight % of 0.1 to 10, e.g., 1 to 5, in the first EML 520, and the fourth compound 564 may have a weight % of 0.1 to 10, e.g., 1 to 5, in the second EML 560. For example, the weight % of the third compound 524 in the first EML 520 may be equal to or greater than that of the fourth compound 564 in the second EML 560.

Each of the first and second EMLs 520 and 560 may have a thickness of 100 Å to 1000, e.g., 100 to 500 Å, but it is not limited thereto. For example, the thickness of the first EML 520 may be equal to or smaller than that of the second EML 560.

The third emitting part 550 may include a third HTL 552, the third EML 540 and a third ETL 554. The third HTL 552 is positioned between the first CGL 580 and the third EML 540, and the third ETL 554 is positioned between the third EML 540 and the second CGL 590.

The third EML 540 may include a host, a red dopant and a green dopant. The third EML 540 may have a single-layered structure. Alternatively, the third EML 540 may have a double-layered structure of a lower layer (or an upper layer) including a first host and a red dopant and an upper layer (or a lower layer) including a second host and a green dopant.

For example, the first host may be a spirofluorene-based organic compound and may be represented by Formula 9.

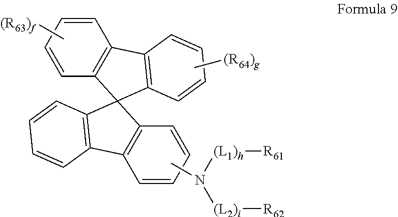

In Formula 9, each of R₆₁ and R₆₂ is independently selected from the consisting of a C6 to C30 aryl group and C3 to C30 heteroaryl group, and each of R₆₃ and R₆₄ is independently selected from the group consisting of D and a C1 to C20 alkyl group. Each off and g is a number of substituents and is independently an integer of 0 to 4. Each of L₁ and L₂ is independently a C6 to C30 arylene group, and each of h and I is independently 0 or 1.

For example, each of aryl group, heteroaryl group and arylene group may be unsubstituted or substituted with at least one of C1 to C10 alkyl and C6 to C20 aryl.

In one embodiment, each of L₁ and L₂ may be independently phenylene unsubstituted or substituted with C1 to C10 alkyl or C6 to C20 aryl, e.g., phenyl, and each of R₆₁ and R₆₂ may be independently selected from the group consisting of phenyl, naphthyl, fluorenyl, dibenzofuranyl and carbazolyl, each of which is unsubstituted or substituted with C1 to C10 alkyl or C6 to C20 aryl, e.g., phenyl.

The first host may be one of the compounds in Formula 10, but it is not limited thereto.

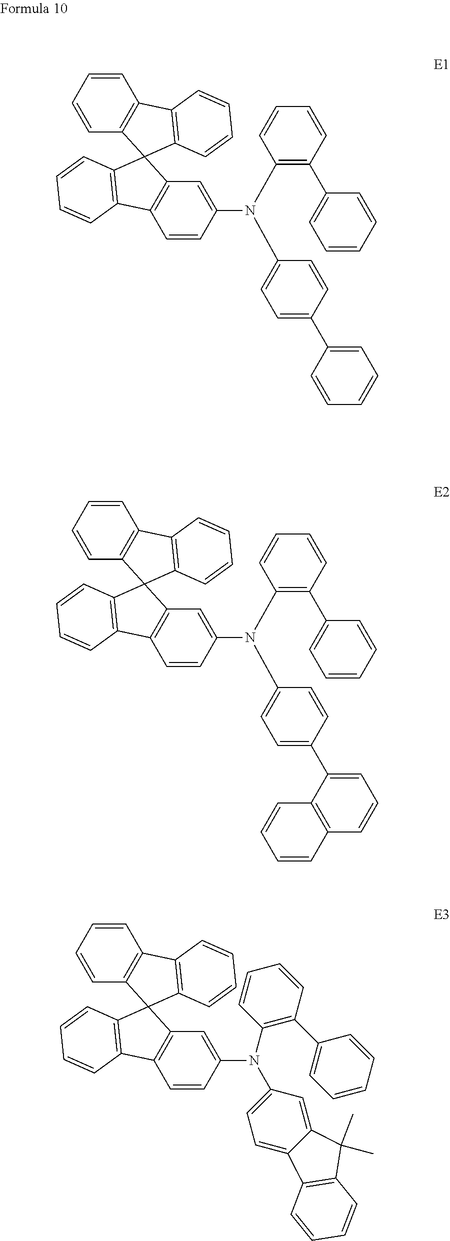 [SMILES: c1ccc(-c2ccc(N(c3ccc4c(c3)C3(c5ccccc5-c5ccccc53)c3ccccc3-4)c3ccccc3-c3ccccc3)cc2)cc1 ; c1ccc(-c2ccccc2N(c2ccc(-c3cccc4ccccc34)cc2)c2ccc3c(c2)C2(c4ccccc4-c4ccccc42)c2ccccc2-3)cc1 ; CC1(C)c2ccccc2-c2ccc(N(c3ccc4c(c3)C3(c5ccccc5-c5ccccc53)c3ccccc3-4)c3ccccc3-c3ccccc3)cc21]

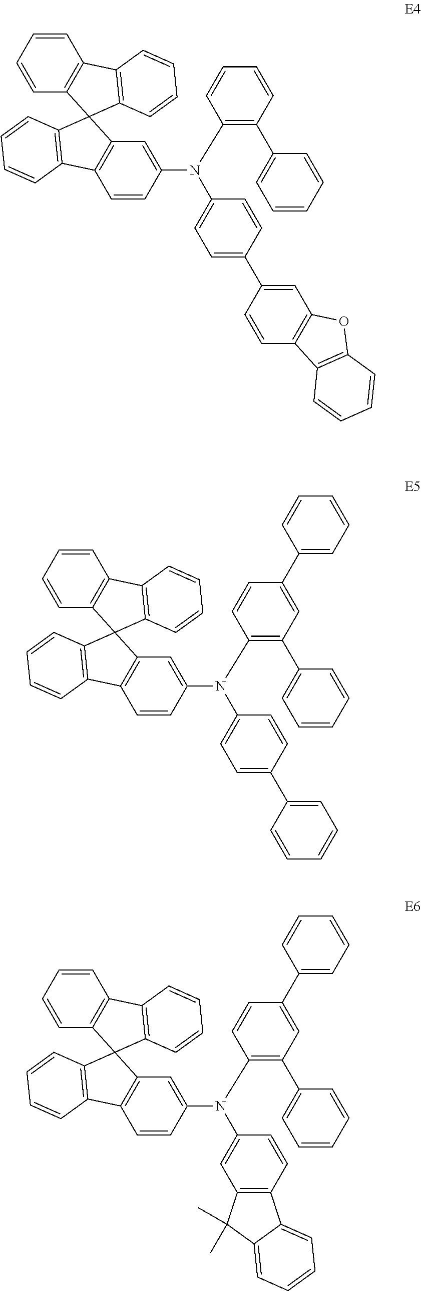 [SMILES: c1ccc(-c2ccccc2N(c2ccc(-c3ccc4c(c3)oc3ccccc34)cc2)c2ccc3c(c2)C2(c4ccccc4-c4ccccc42)c2ccccc2-3)cc1 ; c1ccc(-c2ccc(N(c3ccc4c(c3)C3(c5ccccc5-c5ccccc53)c3ccccc3-4)c3ccc(-c4ccccc4)cc3-c3ccccc3)cc2)cc1 ; CC1(C)c2ccccc2-c2ccc(N(c3ccc4c(c3)C3(c5ccccc5-c5ccccc53)c3ccccc3-4)c3ccc(-c4ccccc4)cc3-c3ccccc3)cc21]

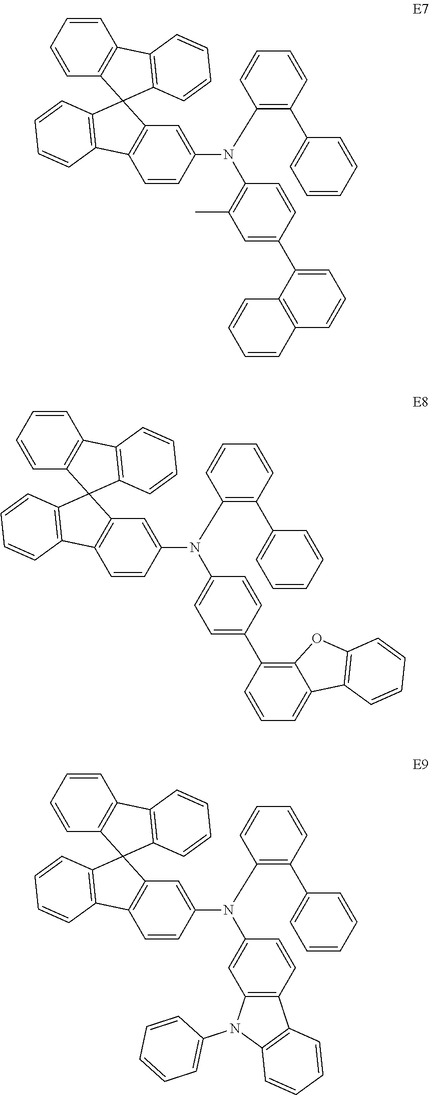 [SMILES: Cc1cc(-c2cccc3ccccc23)ccc1N(c1ccc2c(c1)C1(c3ccccc3-c3ccccc31)c1ccccc1-2)c1ccccc1-c1ccccc1 ; c1ccc(-c2ccccc2N(c2ccc(-c3cccc4c3oc3ccccc34)cc2)c2ccc3c(c2)C2(c4ccccc4-c4ccccc42)c2ccccc2-3)cc1 ; c1ccc(-c2ccccc2N(c2ccc3c(c2)C2(c4ccccc4-c4ccccc42)c2ccccc2-3)c2ccc3c4ccccc4n(-c4ccccc4)c3c2)cc1]

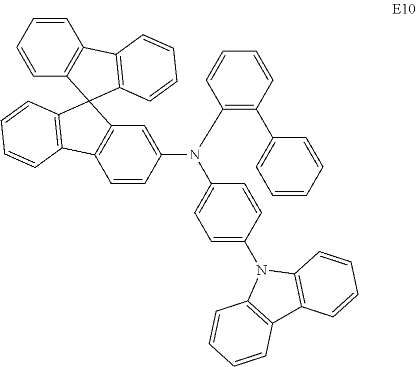 [SMILES: c1ccc(-c2ccccc2N(c2ccc(-n3c4ccccc4c4ccccc43)cc2)c2ccc3c(c2)C2(c4ccccc4-c4ccccc42)c2ccccc2-3)cc1]

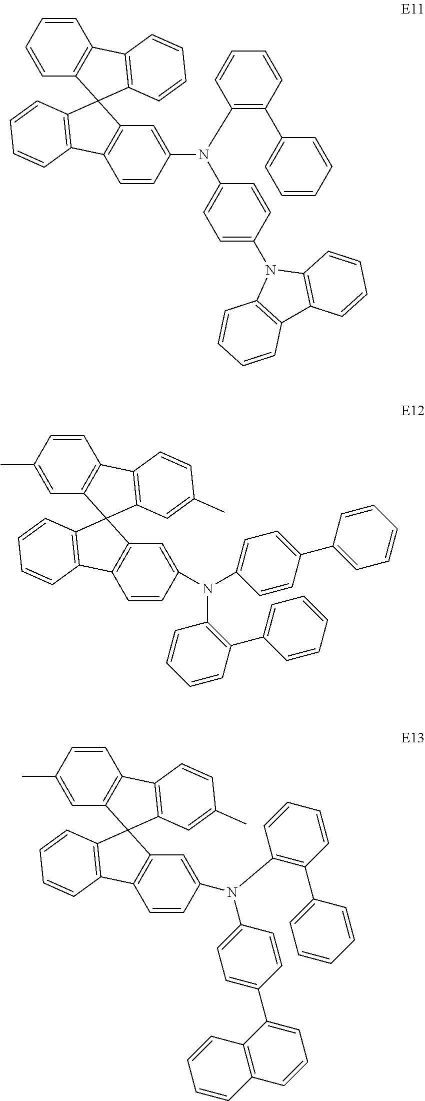 [SMILES: c1ccc(-c2ccccc2N(c2ccc(-n3c4ccccc4c4ccccc43)cc2)c2ccc3c(c2)C2(c4ccccc4-c4ccccc42)c2ccccc2-3)cc1 ; Cc1ccc2c(c1)C1(c3ccccc3-c3ccc(N(c4ccc(-c5ccccc5)cc4)c4ccccc4-c4ccccc4)cc31)c1cc(C)ccc1-2 ; Cc1ccc2c(c1)C1(c3ccccc3-c3ccc(N(c4ccc(-c5cccc6ccccc56)cc4)c4ccccc4-c4ccccc4)cc31)c1cc(C)ccc1-2]

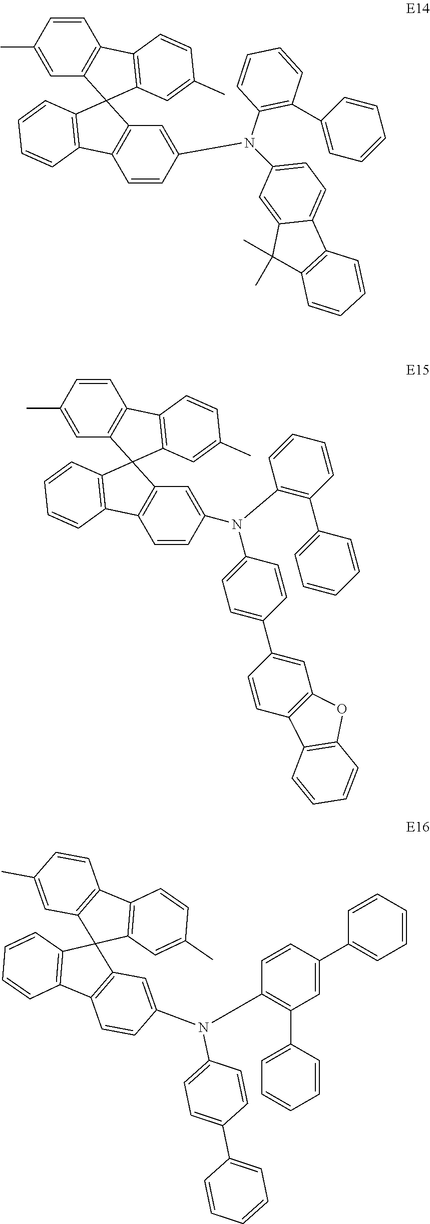 [SMILES: Cc1ccc2c(c1)C1(c3ccccc3-c3ccc(N(c4ccc5c(c4)C(C)(C)c4ccccc4-5)c4ccccc4-c4ccccc4)cc31)c1cc(C)ccc1-2 ; Cc1ccc2c(c1)C1(c3ccccc3-c3ccc(N(c4ccc(-c5ccc6c(c5)oc5ccccc56)cc4)c4ccccc4-c4ccccc4)cc31)c1cc(C)ccc1-2 ; Cc1ccc2c(c1)C1(c3ccccc3-c3ccc(N(c4ccc(-c5ccccc5)cc4)c4ccc(-c5ccccc5)cc4-c4ccccc4)cc31)c1cc(C)ccc1-2]

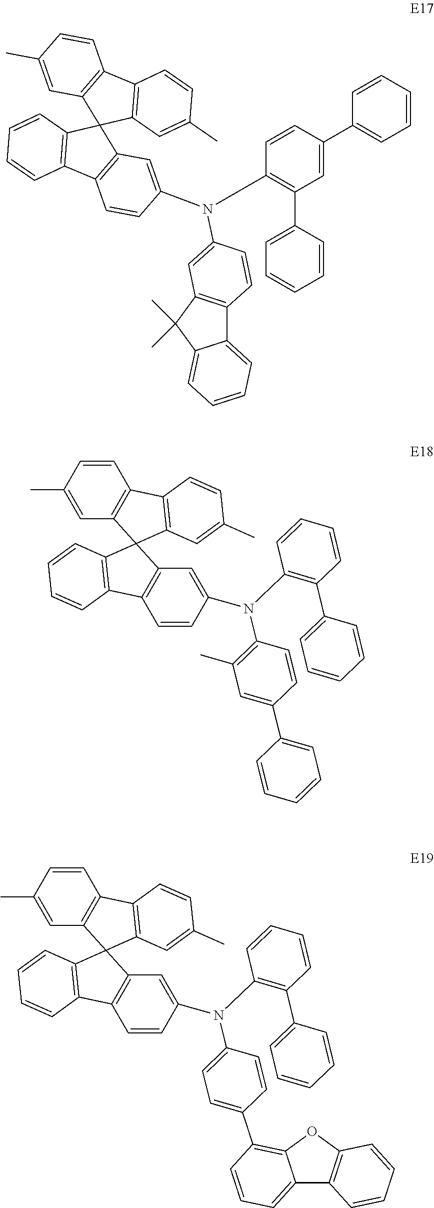 [SMILES: Cc1ccc2c(c1)C1(c3ccccc3-c3ccc(N(c4ccc5c(c4)C(C)(C)c4ccccc4-5)c4ccc(-c5ccccc5)cc4-c4ccccc4)cc31)c1cc(C)ccc1-2 ; Cc1ccc2c(c1)C1(c3ccccc3-c3ccc(N(c4ccc(-c5ccccc5)cc4C)c4ccccc4-c4ccccc4)cc31)c1cc(C)ccc1-2 ; Cc1ccc2c(c1)C1(c3ccccc3-c3ccc(N(c4ccc(-c5cccc6c5oc5ccccc56)cc4)c4ccccc4-c4ccccc4)cc31)c1cc(C)ccc1-2]

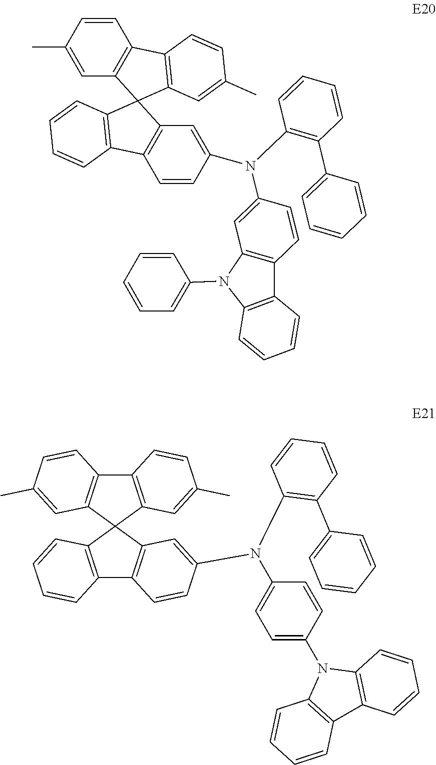 [SMILES: Cc1ccc2c(c1)C1(c3ccccc3-c3ccc(N(c4ccc5c6ccccc6n(-c6ccccc6)c5c4)c4ccccc4-c4ccccc4)cc31)c1cc(C)ccc1-2 ; Cc1ccc2c(c1)C1(c3ccccc3-c3ccc(N(c4ccc(-n5c6ccccc6c6ccccc65)cc4)c4ccccc4-c4ccccc4)cc31)c1cc(C)ccc1-2]

Alternatively, the first host may be a quinazoline-carbazole-based organic compound and may be represented by Formula 11.

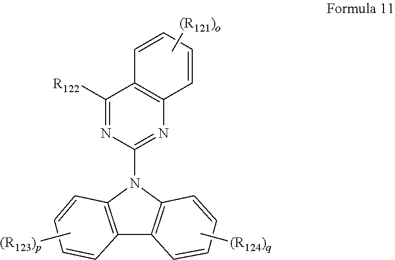

In Formula 11, R₁₂₁ is selected from the group consisting of deuterium, a C1 to C20 alkyl group and a C6 to C30 aryl group, and R₁₂₂ is a C6 to C30 aryl group. Each of R₁₂₃ and R₁₂₄ is selected from the group consisting of deuterium and a C10 to C30 heteroaryl group, or adjacent two R₁₂₃ or adjacent two R₁₂₄ together with the carbon atoms to which they are attached are connected to form a C6 to C10 aromatic ring. At least one of R₁₂₃ and R₁₂₄ is a C10 to C30 heteroaryl group. Each of o, p and q, which are a number of substituents, is independently an integer of 0 to 4.

For example, each of aryl group and heteroaryl group may be unsubstituted or substituted with C6 to C20 aryl.

The first host in Formula 11 may be one of the compounds in Formula 12, but it is not limited thereto.

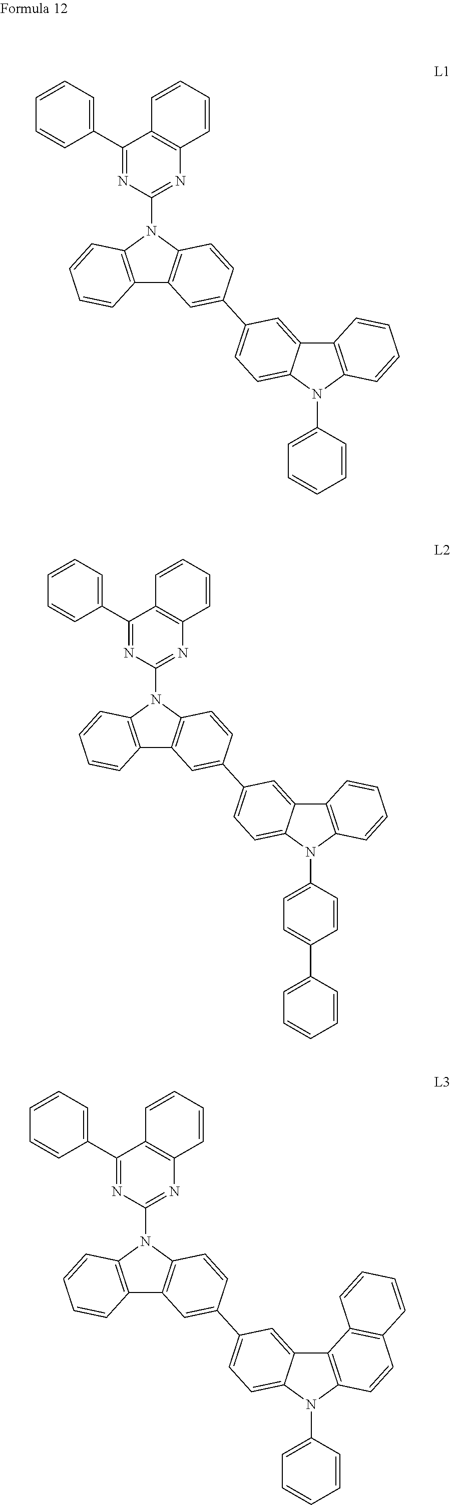 [SMILES: c1ccc(-c2nc(-n3c4ccccc4c4cc(-c5ccc6c(c5)c5ccccc5n6-c5ccccc5)ccc43)nc3ccccc23)cc1 ; c1ccc(-c2ccc(-n3c4ccccc4c4cc(-c5ccc6c(c5)c5ccccc5n6-c5nc(-c6ccccc6)c6ccccc6n5)ccc43)cc2)cc1 ; c1ccc(-c2nc(-n3c4ccccc4c4cc(-c5ccc6c(c5)c5c7ccccc7ccc5n6-c5ccccc5)ccc43)nc3ccccc23)cc1]

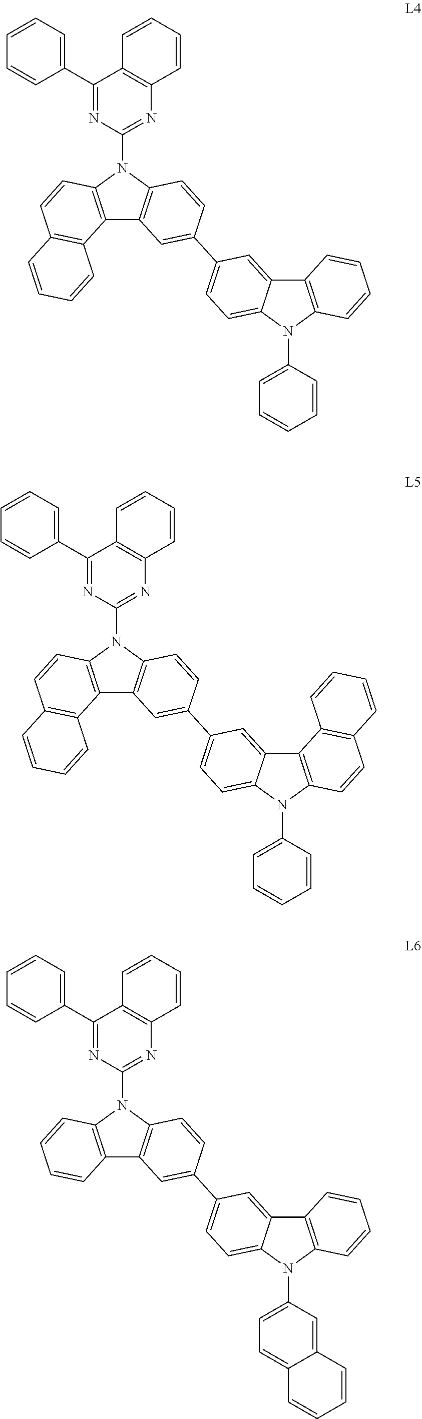 [SMILES: c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2nc(-n3c4ccc(-c5ccc6c(c5)c5c7ccccc7ccc5n6-c5ccccc5)cc4c4c5ccccc5ccc43)nc3ccccc23)cc1 ; c1ccc(-c2nc(-n3c4ccccc4c4cc(-c5ccc6c(c5)c5ccccc5n6-c5ccc6ccccc6c5)ccc43)nc3ccccc23)cc1]

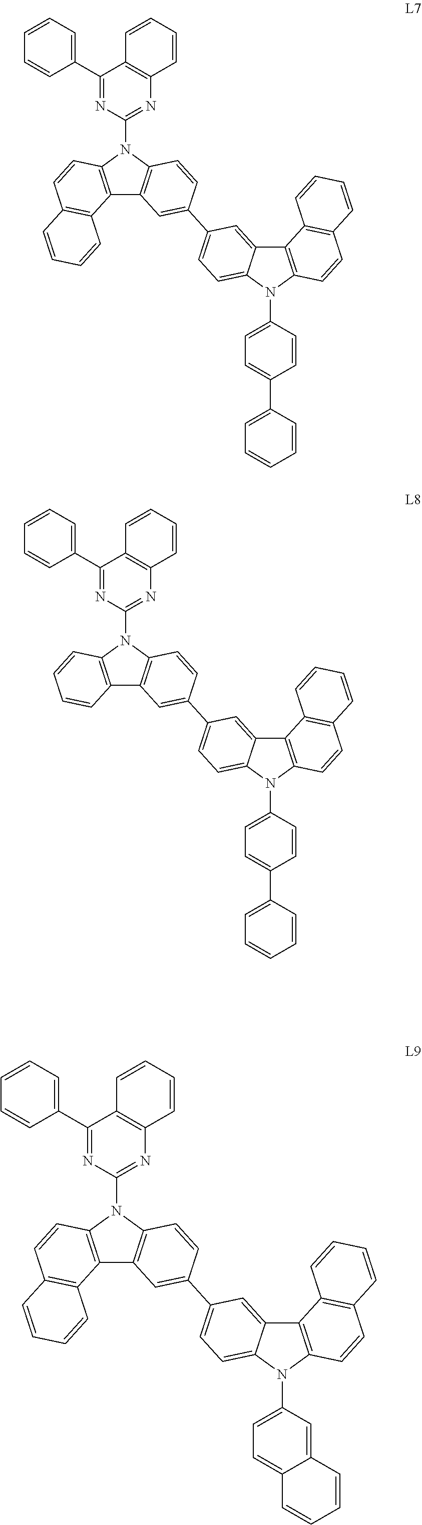 [SMILES: c1ccc(-c2ccc(-n3c4ccc(-c5ccc6c(c5)c5c7ccccc7ccc5n6-c5nc(-c6ccccc6)c6ccccc6n5)cc4c4c5ccccc5ccc43)cc2)cc1 ; c1ccc(-c2ccc(-n3c4ccc(-c5ccc6c(c5)c5ccccc5n6-c5nc(-c6ccccc6)c6ccccc6n5)cc4c4c5ccccc5ccc43)cc2)cc1 ; c1ccc(-c2nc(-n3c4ccc(-c5ccc6c(c5)c5c7ccccc7ccc5n6-c5ccc6ccccc6c5)cc4c4c5ccccc5ccc43)nc3ccccc23)cc1]

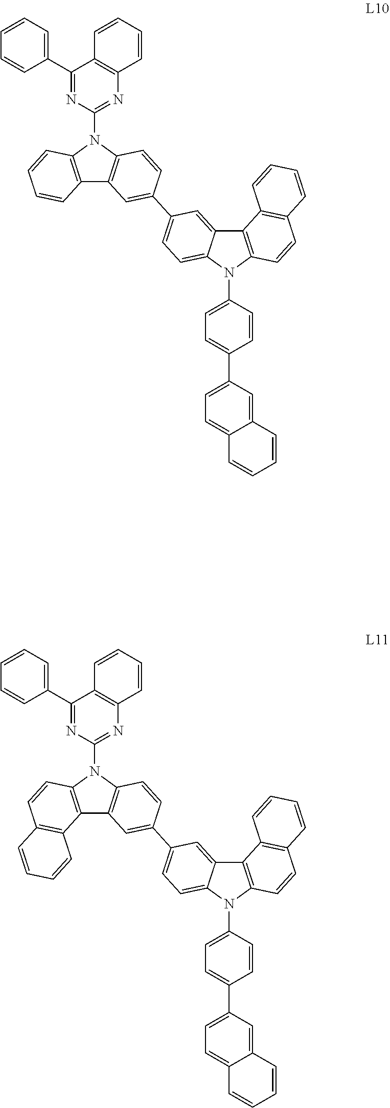 [SMILES: c1ccc(-c2nc(-n3c4ccccc4c4cc(-c5ccc6c(c5)c5c7ccccc7ccc5n6-c5ccc(-c6ccc7ccccc7c6)cc5)ccc43)nc3ccccc23)cc1 ; c1ccc(-c2nc(-n3c4ccc(-c5ccc6c(c5)c5c7ccccc7ccc5n6-c5ccc(-c6ccc7ccccc7c6)cc5)cc4c4c5ccccc5ccc43)nc3ccccc23)cc1]

The first host in the red EML may include the compound of Formula 9 as a P-type red host and the compound of Formula 11 as an N-type red host. In this instance, a weight % ratio of the P-type red host to the N-type red host may be 1:9 to 9:1, preferably 2:8 to 9:2, and more preferably 3:7 to 7:3. For example, the weight % of the P-type red host may be smaller than that of the N-type red host. The weight % ratio of the P-type red host to the N-type red host may be 1:9 to 4:6, preferably 3:7.

The red dopant may include at least one of a red phosphorescent compound, a red fluorescent compound and a red delayed-fluorescent compound. For example, the red dopant may be represented by Formula 13, but it is not limited thereto.

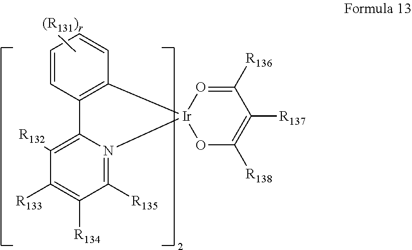

In Formula 13, R₁₃₁ is selected from the group consisting of deuterium, halogen, a C1 to C6 alkyl group, a C3 to C6 cycloalkyl group, a C6 to C10 aryl group and a C3 to C10 heteroaryl group, and r is an integer of 0 to 4. Each of R₁₃₂, R₁₃₃, R₁₃₄ and R₁₃₅ is independently selected from the group consisting of hydrogen, deuterium, halogen atom, a C1 to C6 alkyl group, a C3 to C6 cycloalkyl group, a C6 to C10 aryl group and a C3 to C10 heteroaryl group, and/or adjacent two of R₁₃₂, R₁₃₃, R₁₃₄ and R₁₃₅ together with the carbon atoms to which they are attached are connected to form a C6 to C10 aromatic ring (e.g., a fused ring). Each of R₁₃₆, R₁₃₇ and R₁₃₈ is independently selected from the group consisting of hydrogen, deuterium and a C1 to C6 alkyl group.

The red dopant may be one of the compounds in Formula 14, but it is not limited thereto.

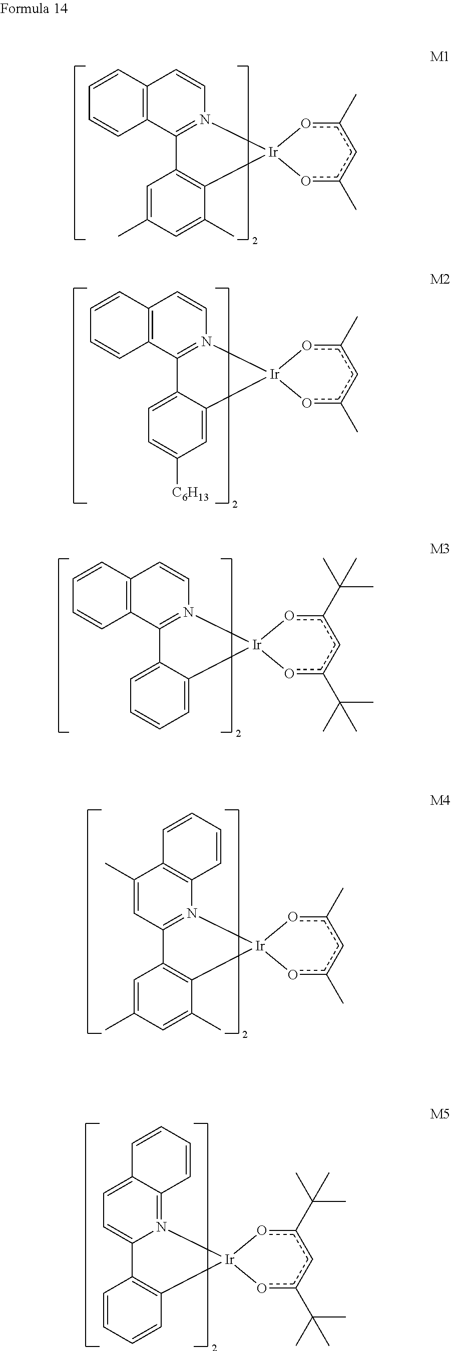

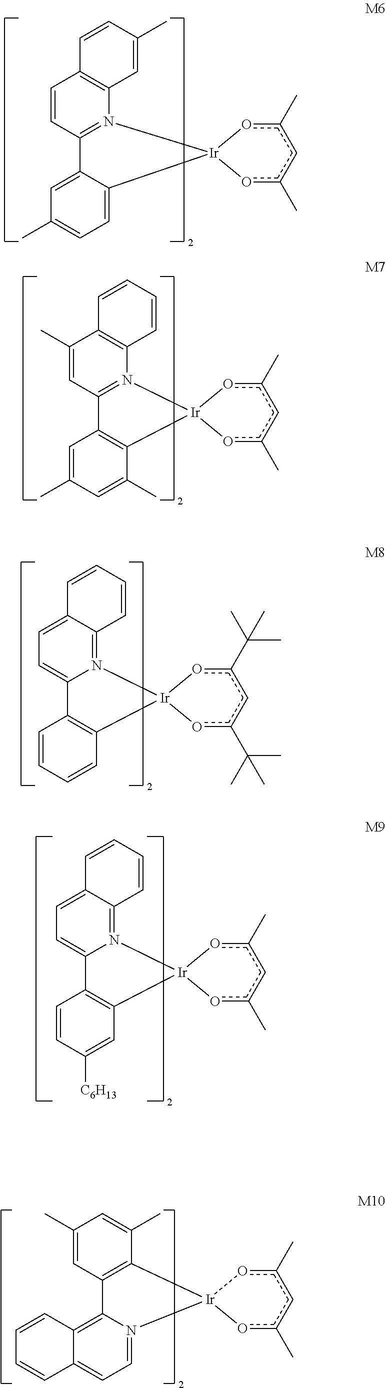

In the red EML, the red dopant may have a weight % of 1 to 10, preferably 1 to 5, but it is not limited thereto. The red EML may has a thickness of 30 to 400 Å, preferably 50 to 250 Å, but it is not limited thereto.

The second host may be a biscarbazole-based organic compound and may be represented by Formula 15.

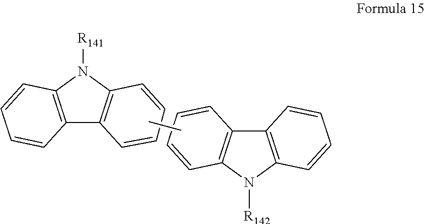

In Formula 15, each of R₁₄₁ and R₁₄₂ is independently selected from a C6 to C30 aryl group.

The aryl group may be unsubstituted or substituted with C6 to C10 aryl. For example, each of R₁₄₁ and R₁₄₂ may be independently selected from phenyl and naphthyl, and each of phenyl and naphthyl may be unsubstituted or substituted with phenyl or naphthyl.

The second host in Formula 16 may be one of the compounds in Formula 16, but it is not limited thereto.

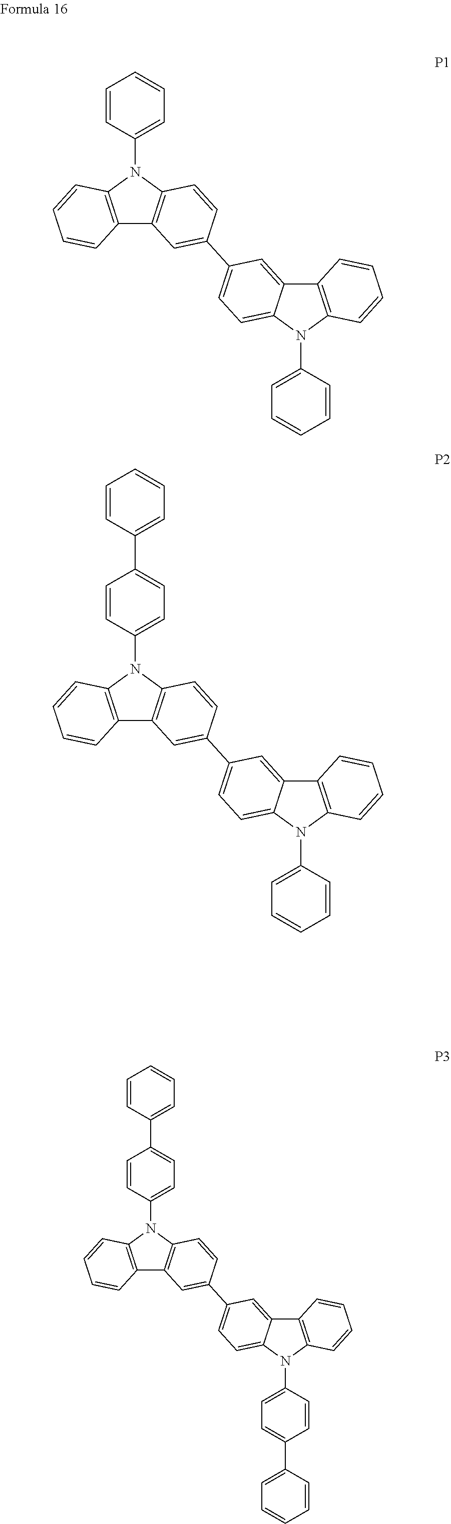 [SMILES: c1ccc(-n2c3ccccc3c3cc(-c4ccc5c(c4)c4ccccc4n5-c4ccccc4)ccc32)cc1 ; c1ccc(-c2ccc(-n3c4ccccc4c4cc(-c5ccc6c(c5)c5ccccc5n6-c5ccccc5)ccc43)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1]

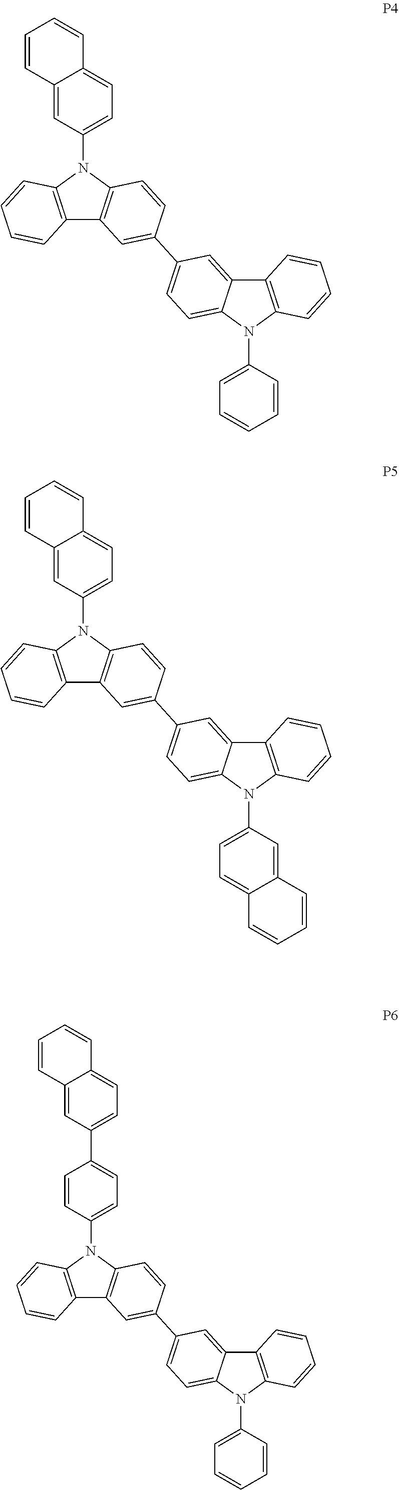 [SMILES: c1ccc(-n2c3ccccc3c3cc(-c4ccc5c(c4)c4ccccc4n5-c4ccc5ccccc5c4)ccc32)cc1 ; c1ccc2cc(-n3c4ccccc4c4cc(-c5ccc6c(c5)c5ccccc5n6-c5ccc6ccccc6c5)ccc43)ccc2c1 ; c1ccc(-n2c3ccccc3c3cc(-c4ccc5c(c4)c4ccccc4n5-c4ccc(-c5ccc6ccccc6c5)cc4)ccc32)cc1]

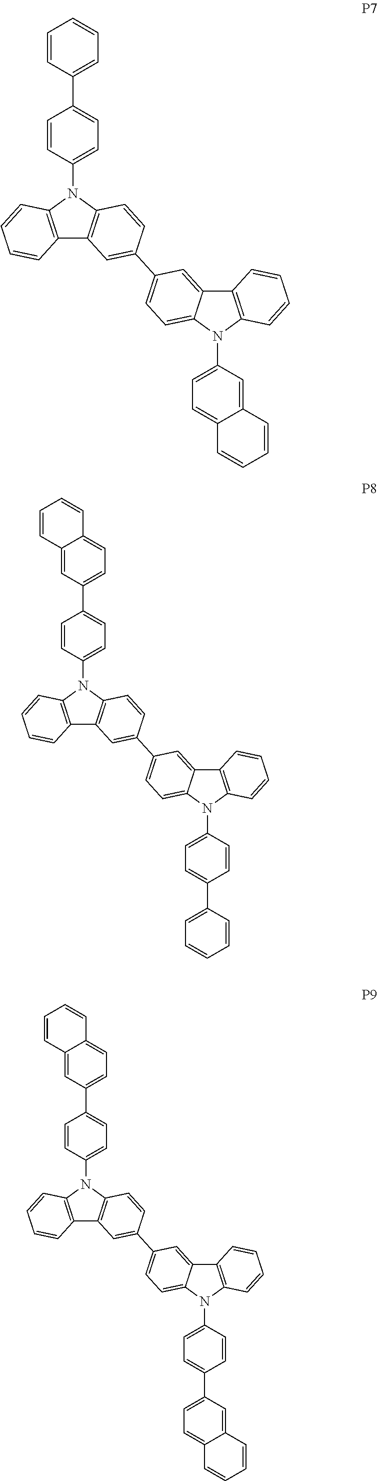 [SMILES: c1ccc(-c2ccc(-n3c4ccccc4c4cc(-c5ccc6c(c5)c5ccccc5n6-c5ccc6ccccc6c5)ccc43)cc2)cc1 ; c1ccc(-c2ccc(-n3c4ccccc4c4cc(-c5ccc6c(c5)c5ccccc5n6-c5ccc(-c6ccc7ccccc7c6)cc5)ccc43)cc2)cc1 ; c1ccc2cc(-c3ccc(-n4c5ccccc5c5cc(-c6ccc7c(c6)c6ccccc6n7-c6ccc(-c7ccc8ccccc8c7)cc6)ccc54)cc3)ccc2c1]

Alternatively, the second host may be a triazine-based organic compound and may be represented by Formula 17.

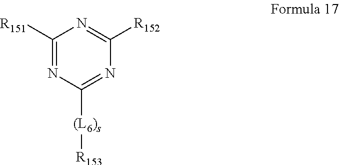

In Formula 17, each of R₁₅₁ and R₁₅₂ is independently selected from a C6 to C30 aryl group, and R₁₅₃ is a C10 to C20 fused-heteroaryl group. L₆ is a C6 to C30 arylene group, and s is 0 or 1.

Each of aryl group and the heteroaryl group may be unsubstituted or substituted with C10 to C20 fused-aryl.

For example, each of R₁₅₁ and R₁₅₂ may be independently phenyl, and R₁₅₃ may be dibenzofuranyl or dibenzothiophenyl. Each of dibenzofuranyl and dibenzothiophenyl may be substituted with triphenylene or phenanthrenyl, and L₆ may be phenylene.

The second host in Formula 17 may be one of the compounds in Formula 18, but it is not limited thereto.

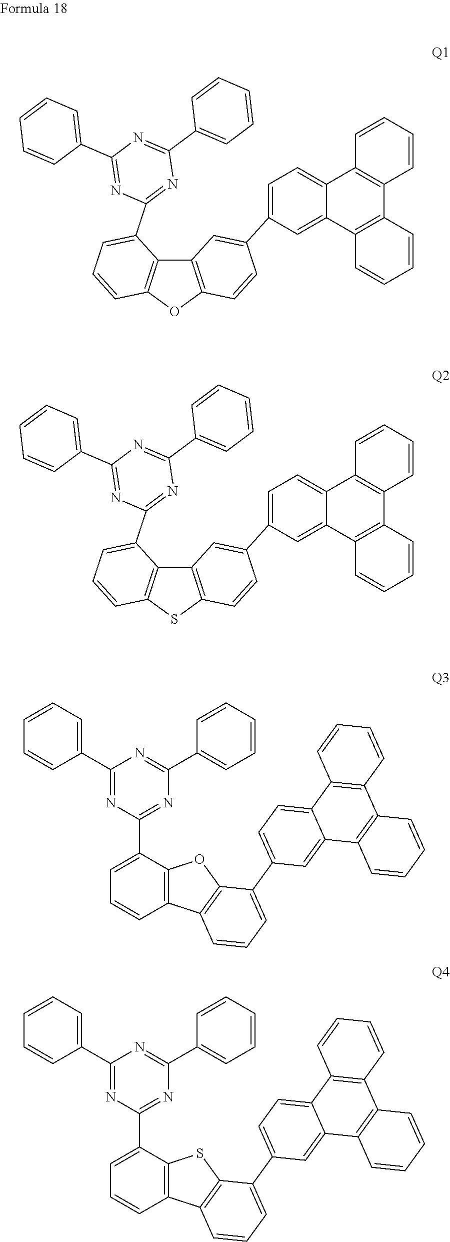 [SMILES: c1ccc(-c2nc(-c3ccccc3)nc(-c3cccc4oc5ccc(-c6ccc7c8ccccc8c8ccccc8c7c6)cc5c34)n2)cc1 ; c1ccc(-c2nc(-c3ccccc3)nc(-c3cccc4sc5ccc(-c6ccc7c8ccccc8c8ccccc8c7c6)cc5c34)n2)cc1 ; c1ccc(-c2nc(-c3ccccc3)nc(-c3cccc4c3oc3c(-c5ccc6c7ccccc7c7ccccc7c6c5)cccc34)n2)cc1 ; c1ccc(-c2nc(-c3ccccc3)nc(-c3cccc4c3sc3c(-c5ccc6c7ccccc7c7ccccc7c6c5)cccc34)n2)cc1]

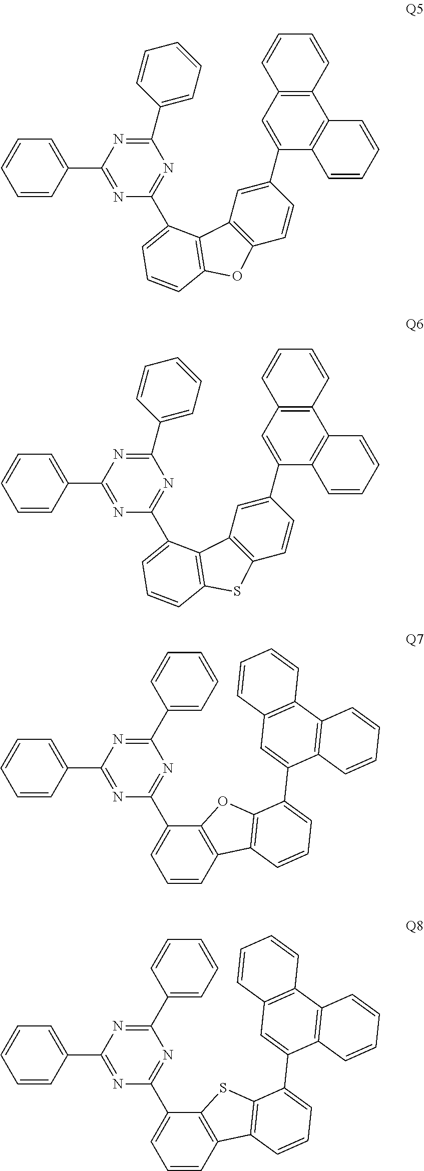 [SMILES: c1ccc(-c2nc(-c3ccccc3)nc(-c3cccc4oc5ccc(-c6cc7ccccc7c7ccccc67)cc5c34)n2)cc1 ; c1ccc(-c2nc(-c3ccccc3)nc(-c3cccc4sc5ccc(-c6cc7ccccc7c7ccccc67)cc5c34)n2)cc1 ; c1ccc(-c2nc(-c3ccccc3)nc(-c3cccc4c3oc3c(-c5cc6ccccc6c6ccccc56)cccc34)n2)cc1 ; c1ccc(-c2nc(-c3ccccc3)nc(-c3cccc4c3sc3c(-c5cc6ccccc6c6ccccc56)cccc34)n2)cc1]

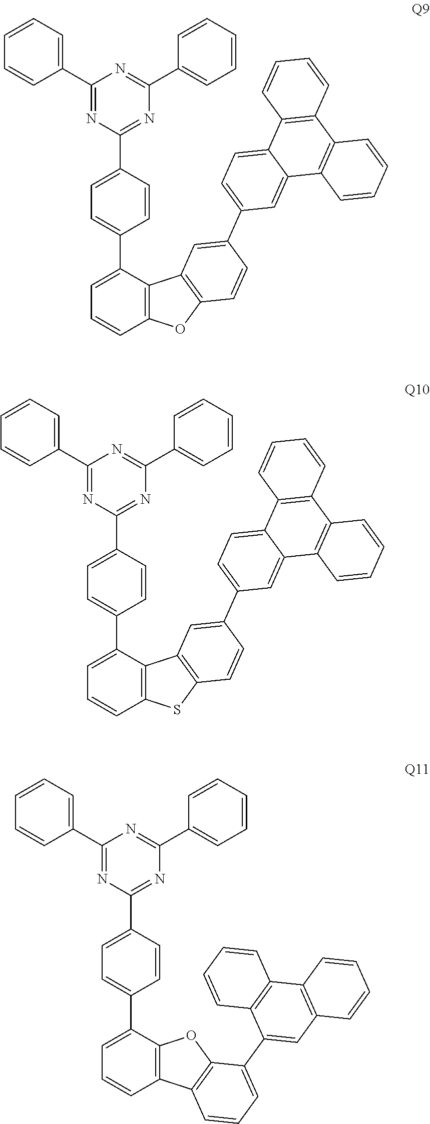 [SMILES: c1ccc(-c2nc(-c3ccccc3)nc(-c3ccc(-c4cccc5oc6ccc(-c7ccc8c9ccccc9c9ccccc9c8c7)cc6c45)cc3)n2)cc1 ; c1ccc(-c2nc(-c3ccccc3)nc(-c3ccc(-c4cccc5sc6ccc(-c7ccc8c9ccccc9c9ccccc9c8c7)cc6c45)cc3)n2)cc1 ; c1ccc(-c2nc(-c3ccccc3)nc(-c3ccc(-c4cccc5c4oc4c(-c6cc7ccccc7c7ccccc67)cccc45)cc3)n2)cc1]

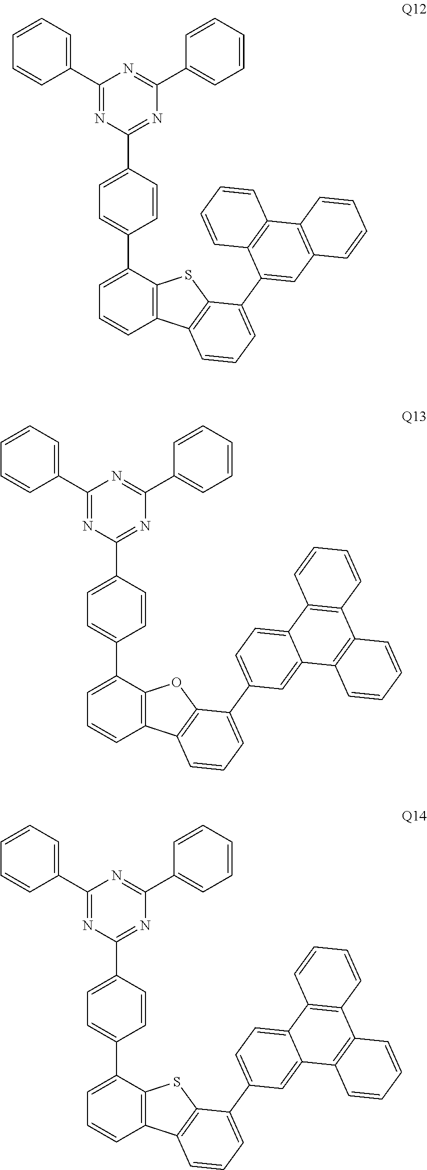 [SMILES: c1ccc(-c2nc(-c3ccccc3)nc(-c3ccc(-c4cccc5c4sc4c(-c6cc7ccccc7c7ccccc67)cccc45)cc3)n2)cc1 ; c1ccc(-c2nc(-c3ccccc3)nc(-c3ccc(-c4cccc5c4oc4c(-c6ccc7c8ccccc8c8ccccc8c7c6)cccc45)cc3)n2)cc1 ; c1ccc(-c2nc(-c3ccccc3)nc(-c3ccc(-c4cccc5c4sc4c(-c6ccc7c8ccccc8c8ccccc8c7c6)cccc45)cc3)n2)cc1]

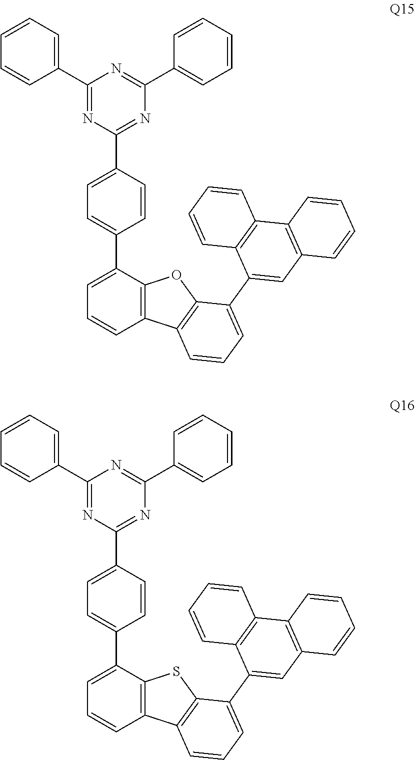 [SMILES: c1ccc(-c2nc(-c3ccccc3)nc(-c3ccc(-c4cccc5c4oc4c(-c6cc7ccccc7c7ccccc67)cccc45)cc3)n2)cc1 ; c1ccc(-c2nc(-c3ccccc3)nc(-c3ccc(-c4cccc5c4sc4c(-c6cc7ccccc7c7ccccc67)cccc45)cc3)n2)cc1]

The second host in the green EML may include the compound of Formula 15 as a P-type green host and the compound of Formula 17 as an N-type green host. In this instance, a weight % ratio of the P-type green host to the N-type green host may be 1:9 to 9:1, preferably 2:8 to 9:2, and more preferably 3:7 to 7:3. For example, the weight % of the P-type green host may be greater than that of the N-type green host. The weight % ratio of the P-type green host to the N-type green host may be 9:1 to 6:4, preferably 7:3.

The green dopant may include at least one of a green phosphorescent compound, a green fluorescent compound and a green delayed-fluorescent compound. For example, the green dopant may be represented by Formula 19, but it is not limited thereto.

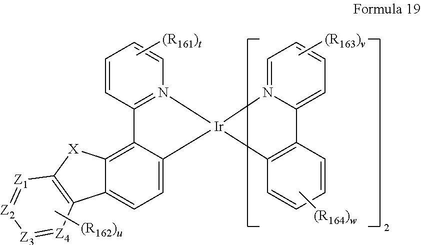

In Formula 19, each of R₁₆₁, R₁₆₂, R₁₆₃ and R₁₆₄ is independently selected from the group consisting of deuterium, halogen, a C1 to C6 alkyl group, a C3 to C6 cycloalkyl group, a C6 to C10 aryl group and a C3 to C10 heteroaryl group. Each of t, v and w is independently an integer of 0 to 4, and u is an integer of 0 to 3. X is oxygen atom or sulfur atom. Each of Z1 to Z4 is independently nitrogen or CR₁₆₅, and R₁₆₅ is selected from hydrogen, deuterium, halogen, a C1 to C6 alkyl group, a C3 to C6 cycloalkyl group, a C6 to C10 aryl group and a C3 to C10 heteroaryl group. (t, u, v and w are the number of substituents)

The green dopant may be one of the compounds in Formula 20, but it is not limited thereto.

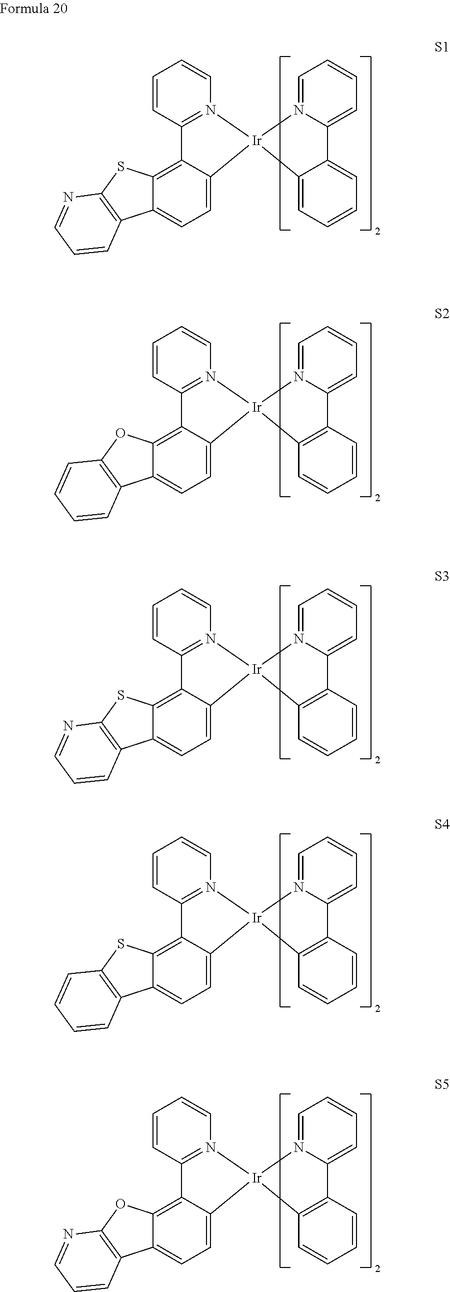

In the green EML, the green dopant may have a weight % of 1 to 10, preferably 1 to 5, but it is not limited thereto. The green EML may has a thickness of 30 to 600 Å, preferably 50 to 400 Å, but it is not limited thereto.

For example, in the third EML 540 of the third emitting part 550, a thickness of the red EML may be smaller than that of the green EML. In addition, a weight % of the red dopant in the red EML may be smaller than that of the green dopant in the green EML.

Alternatively, the third EML 540 may be a yellow-green EML. For example, the third EML 540 as the yellow-green EML may include a host and a yellow-green dopant.

The HIL 532 may include an anthracene-based compound in Formula 21 as a first hole injection material.

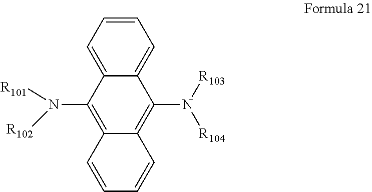

In Formula 21, each of R₁₀₁, R₁₀₂, R₁₀₃ and R₁₀₄ may be independently C6 to C30 aryl.

For example, each of R₁₀₁, R₁₀₂, R₁₀₃ and R₁₀₄ may be independently selected from the group consisting of phenyl, naphthyl (e.g., 1-naphthyl or 2-naphthyl) and phenanthrenyl and may be substituted with C1 to C10 alkyl.

The anthracene-based compound in Formula 21 may be one of the compounds in Formula 22, but it is not limited thereto.

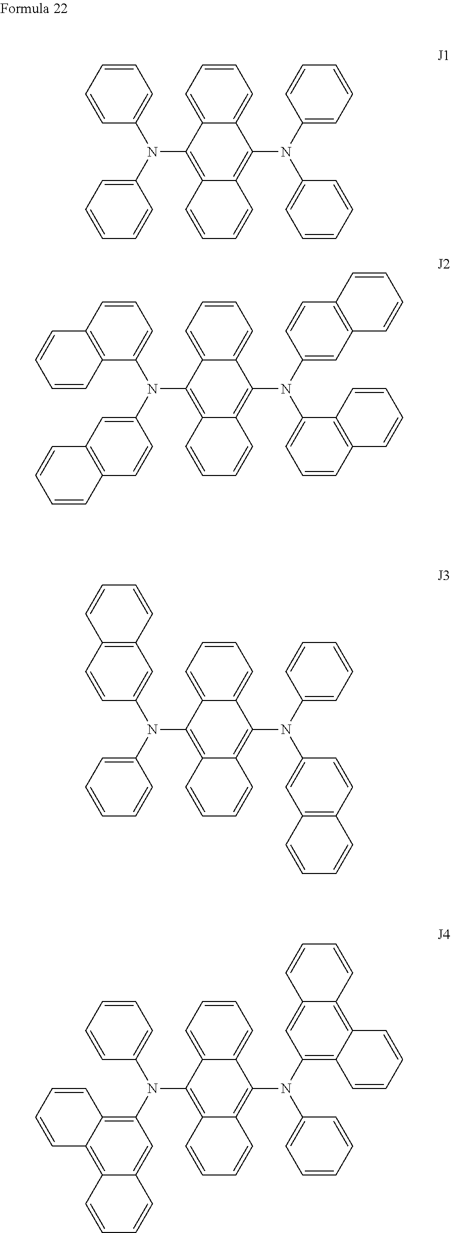

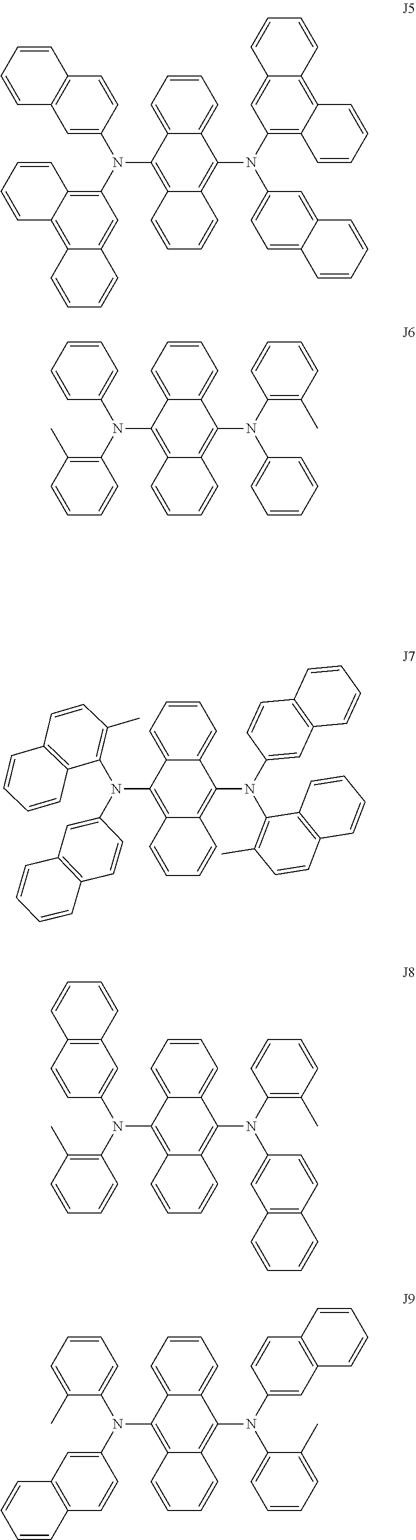

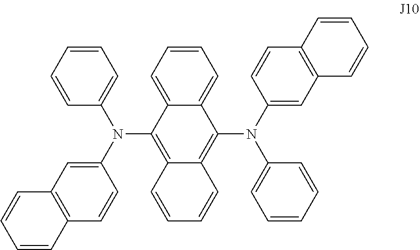 [SMILES: c1ccc(N(c2ccc3ccccc3c2)c2c3ccccc3c(N(c3ccccc3)c3ccc4ccccc4c3)c3ccccc23)cc1]

The HIL 532 may further include a halide compound of alkali metal or a halide compound of alkali earth metal as a second hole injection material. For example, the second hole injection material may include at least one of LiF, MgF₂, CaF₂, NaF and CsF.

In the HIL 532, a weight % ratio of the first hole injection material to the second hole injection material may be 8:2 to 5:5, and the HIL 532 may have a thickness of about 10 to 100 Å. However, the present disclosure is not limited thereto.

Each of the first to third HTLs 534, 572 and 552 may include the spirofluorene-based organic compound in Formula 9. For example, each of the first to third HTLs 534, 572 and 552 may include at least one of the compounds in Formula 10.

For example, a thickness of the second HTL 572 may be equal to or smaller than that of the first HTL 534 and may be greater than that of the third HTL 552. The first HTL 534 may have the thickness of about 500 to 1000 Å, the second HTL 572 may have the thickness of about 500 to 900 Å, and the third HTL 552 may have the thickness of about 10 to 150 Å.

Each of the first and second EBL 536 and 574 may include a compound of Formula 23 as an electron blocking material.

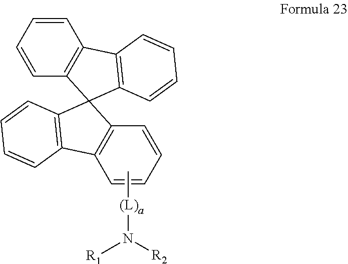

In Formula 23, L is a C6 to C30 arylene group, and a is 0 or 1. Each of R₁ and R₂ is independently selected from the group consisting of a C6 to C30 aryl group and a C5 to C30 heteroaryl group. The C6 to C30 aryl group and C5 to C30 heteroaryl group may optionally be substituted.

For example, L may be phenylene, and each of R₁ and R₂ may be independently selected from the group consisting of biphenyl, fluorenyl, phenylcarbazolyl, carbazolylphenyl, dibenzothiophenyl and dibenzofuranyl.

Namely, the electron blocking material is an amine derivative substituted with spirofluorene (e.g., spirofluorene-substituted amine derivative).

The electron blocking material in Formula 23 may be one of the compounds in Formula 24.

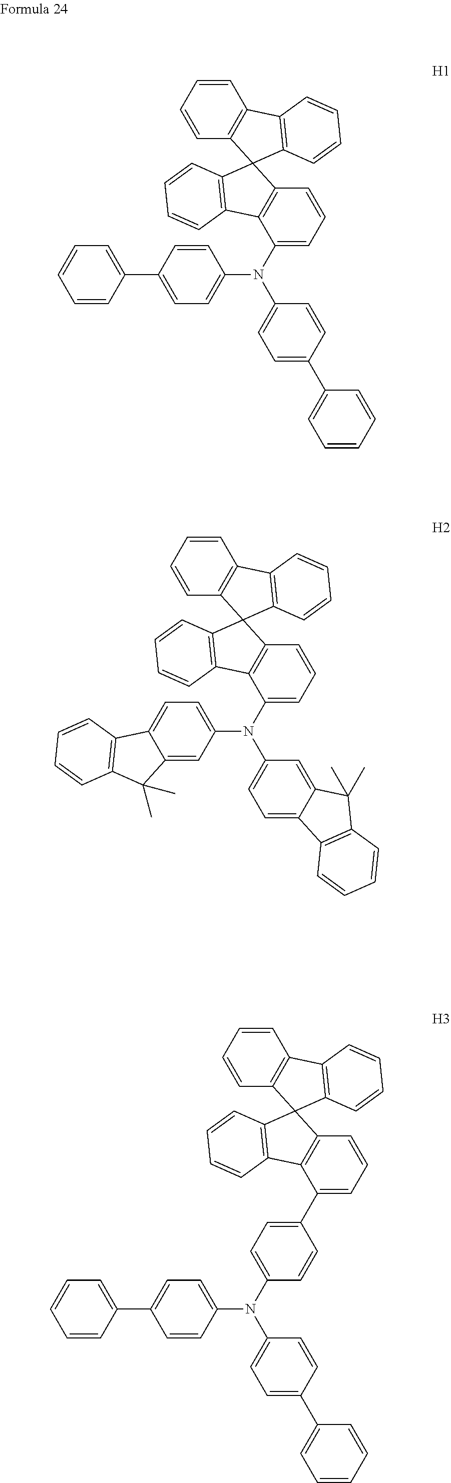 [SMILES: c1ccc(-c2ccc(N(c3ccc(-c4ccccc4)cc3)c3cccc4c3-c3ccccc3C43c4ccccc4-c4ccccc43)cc2)cc1 ; CC1(C)c2ccccc2-c2ccc(N(c3ccc4c(c3)C(C)(C)c3ccccc3-4)c3cccc4c3-c3ccccc3C43c4ccccc4-c4ccccc43)cc21 ; c1ccc(-c2ccc(N(c3ccc(-c4ccccc4)cc3)c3ccc(-c4cccc5c4-c4ccccc4C54c5ccccc5-c5ccccc54)cc3)cc2)cc1]

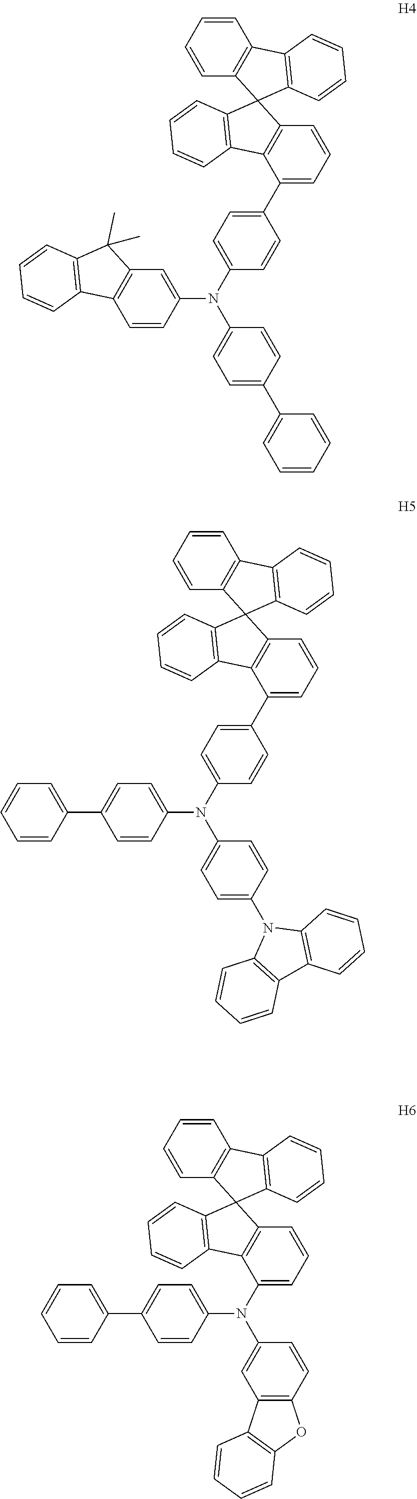 [SMILES: CC1(C)c2ccccc2-c2ccc(N(c3ccc(-c4ccccc4)cc3)c3ccc(-c4cccc5c4-c4ccccc4C54c5ccccc5-c5ccccc54)cc3)cc21 ; c1ccc(-c2ccc(N(c3ccc(-c4cccc5c4-c4ccccc4C54c5ccccc5-c5ccccc54)cc3)c3ccc(-n4c5ccccc5c5ccccc54)cc3)cc2)cc1 ; c1ccc(-c2ccc(N(c3ccc4oc5ccccc5c4c3)c3cccc4c3-c3ccccc3C43c4ccccc4-c4ccccc43)cc2)cc1]

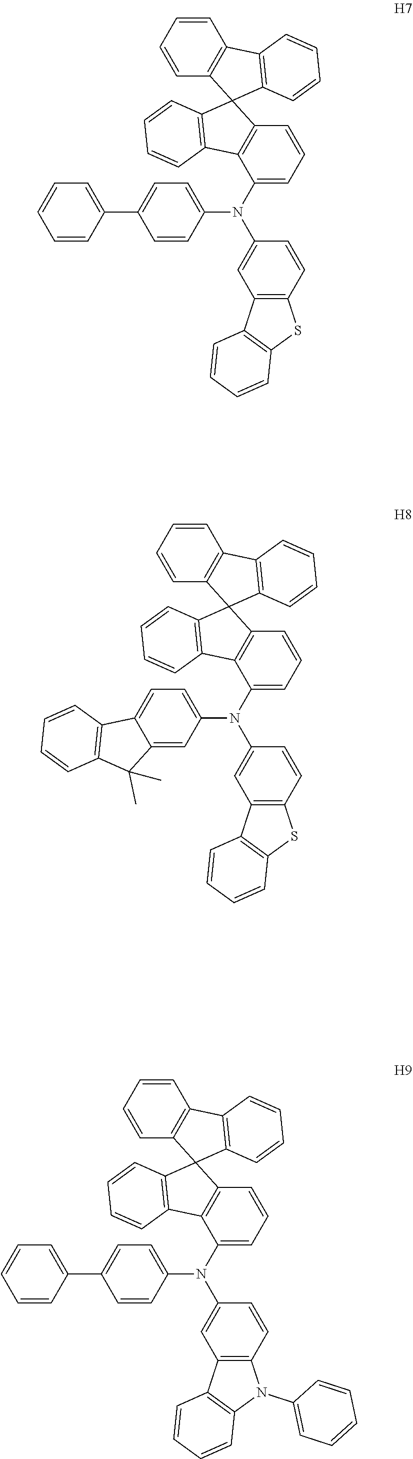 [SMILES: c1ccc(-c2ccc(N(c3ccc4sc5ccccc5c4c3)c3cccc4c3-c3ccccc3C43c4ccccc4-c4ccccc43)cc2)cc1 ; CC1(C)c2ccccc2-c2ccc(N(c3ccc4sc5ccccc5c4c3)c3cccc4c3-c3ccccc3C43c4ccccc4-c4ccccc43)cc21 ; c1ccc(-c2ccc(N(c3ccc4c(c3)c3ccccc3n4-c3ccccc3)c3cccc4c3-c3ccccc3C43c4ccccc4-c4ccccc43)cc2)cc1]

Each of the first and second EBL 536 and 574 may have a thickness of about 50 to 250 Å, but it is not limited thereto.

Each of the first to third ETL 538, 576 and 554 may include at least one of an azine-based organic compound of Formula 25 and a benzimidazole-based organic compound of Formula 26.

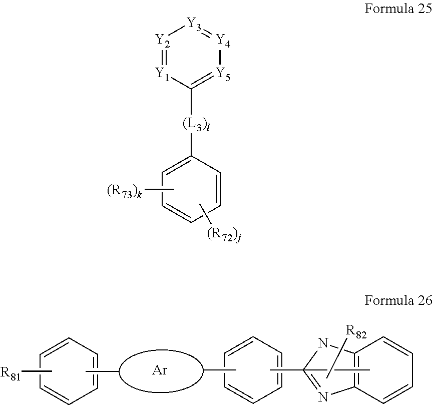

In Formula 25, each of Y₁, Y₂, Y₃, Y₄ and Y₅ is independently CR₇₁ or nitrogen atom (N), and one to three of Y₁, Y₂, Y₃, Y₄ and Y₅ is N. R₇₁ is hydrogen or a C6 to C30 aryl group, and L₃ is a C6 to C30 arylene group. R₇₂ is a C6 to C30 aryl group or a C5 to C30 heteroaryl group. R₇₃ is hydrogen, or adjacent two of R₇₃ together with the carbon atoms to which they are attached are connected to form an aromatic ring (e.g., a fused ring). In addition, j is 1 or 2, k is an integer of 0 to 4, and 1 is 0 or 1.

In Formula 26, Ar is a C1 to C30 arylene group, and R₈₁ is a C6 to C30 aryl group or an unsubstituted or substituted C5 to C30 heteroaryl group. R₈₂ is hydrogen, a C1 to C10 alkyl group or a C6 to C30 aryl group.

In Formula 25, the aryl group for R₇₂ may be unsubstituted or substituted with a C6 to C30 aryl group or a C5 to C30 heteroaryl group.

In Formula 26, Ar may be naphthylene or anthracenylene, and R₈₁ may be phenyl unsubstituted or substituted with C1 to C10 alkyl, or a benzimidazole group. R₈₂ may be methyl, ethyl or phenyl.

For example, the electron transporting material in Formula 25 may be one of the compounds in Formula 27, and the electron transporting material in Formula 26 may be one of the compounds in Formula 28.

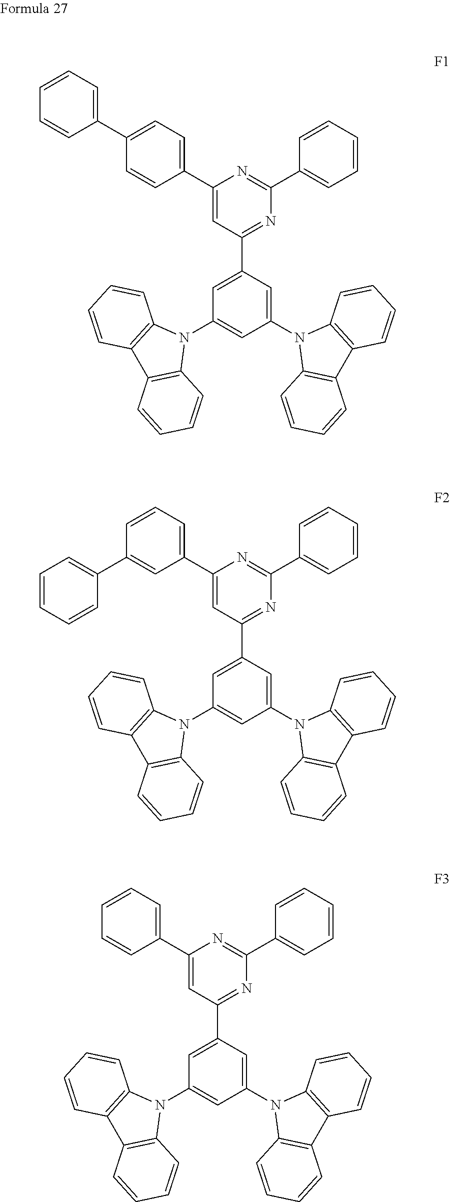 [SMILES: c1ccc(-c2ccc(-c3cc(-c4cc(-n5c6ccccc6c6ccccc65)cc(-n5c6ccccc6c6ccccc65)c4)nc(-c4ccccc4)n3)cc2)cc1 ; c1ccc(-c2cccc(-c3cc(-c4cc(-n5c6ccccc6c6ccccc65)cc(-n5c6ccccc6c6ccccc65)c4)nc(-c4ccccc4)n3)c2)cc1 ; c1ccc(-c2cc(-c3cc(-n4c5ccccc5c5ccccc54)cc(-n4c5ccccc5c5ccccc54)c3)nc(-c3ccccc3)n2)cc1]

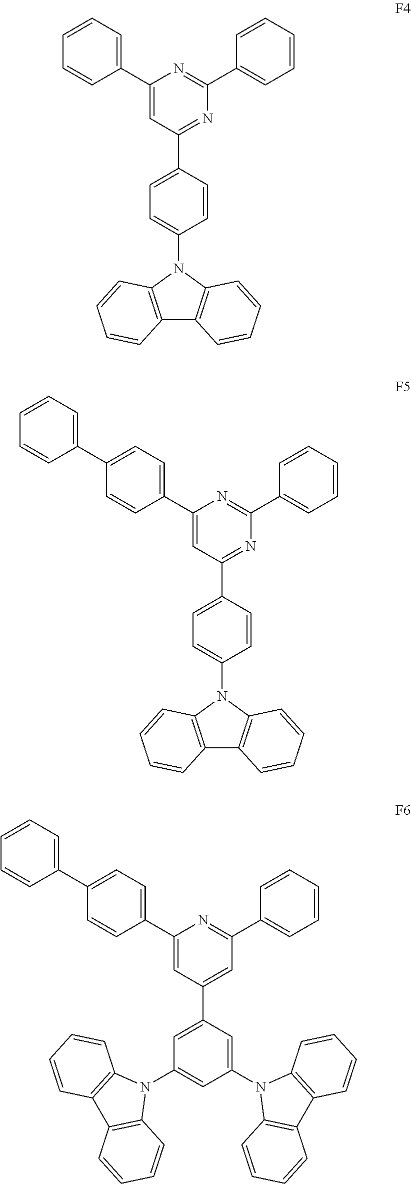 [SMILES: c1ccc(-c2cc(-c3ccc(-n4c5ccccc5c5ccccc54)cc3)nc(-c3ccccc3)n2)cc1 ; c1ccc(-c2ccc(-c3cc(-c4ccc(-n5c6ccccc6c6ccccc65)cc4)nc(-c4ccccc4)n3)cc2)cc1 ; c1ccc(-c2ccc(-c3cc(-c4cc(-n5c6ccccc6c6ccccc65)cc(-n5c6ccccc6c6ccccc65)c4)cc(-c4ccccc4)n3)cc2)cc1]

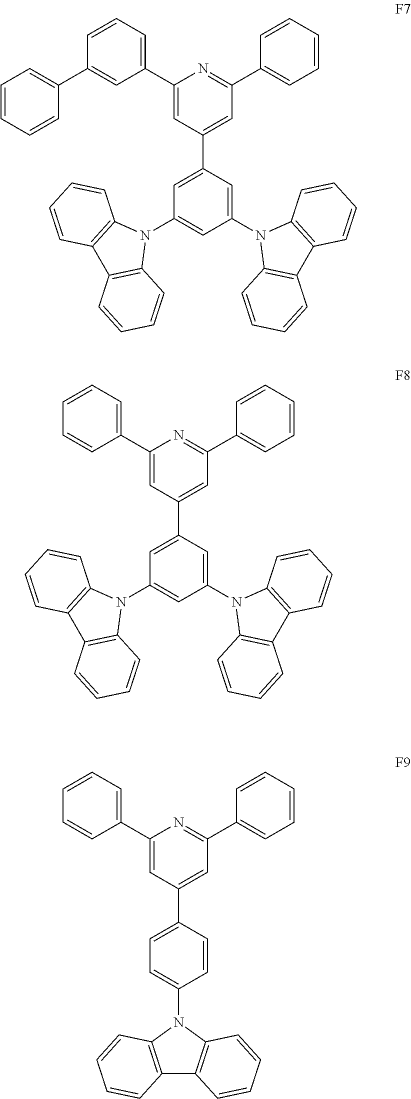 [SMILES: c1ccc(-c2cccc(-c3cc(-c4cc(-n5c6ccccc6c6ccccc65)cc(-n5c6ccccc6c6ccccc65)c4)cc(-c4ccccc4)n3)c2)cc1 ; c1ccc(-c2cc(-c3cc(-n4c5ccccc5c5ccccc54)cc(-n4c5ccccc5c5ccccc54)c3)cc(-c3ccccc3)n2)cc1 ; c1ccc(-c2cc(-c3ccc(-n4c5ccccc5c5ccccc54)cc3)cc(-c3ccccc3)n2)cc1]

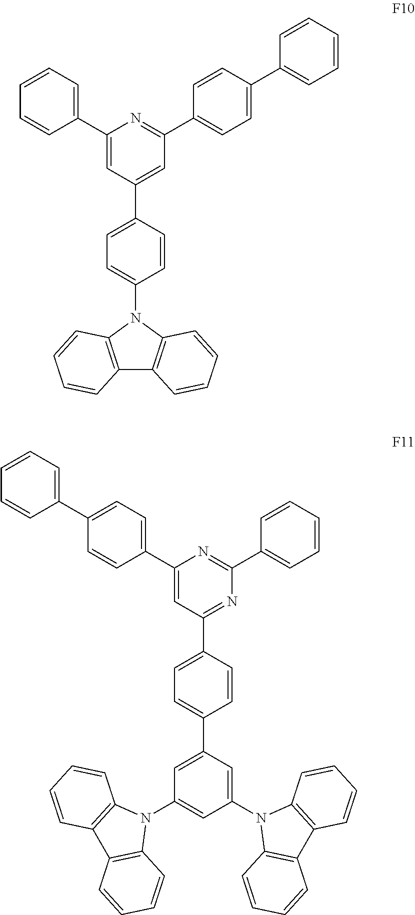 [SMILES: c1ccc(-c2ccc(-c3cc(-c4ccc(-n5c6ccccc6c6ccccc65)cc4)cc(-c4ccccc4)n3)cc2)cc1 ; c1ccc(-c2ccc(-c3cc(-c4ccc(-c5cc(-n6c7ccccc7c7ccccc76)cc(-n6c7ccccc7c7ccccc76)c5)cc4)nc(-c4ccccc4)n3)cc2)cc1]

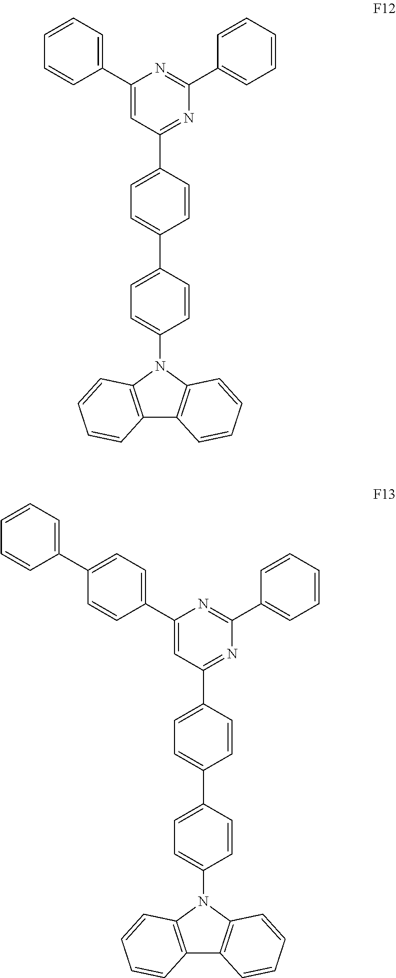 [SMILES: c1ccc(-c2cc(-c3ccc(-c4ccc(-n5c6ccccc6c6ccccc65)cc4)cc3)nc(-c3ccccc3)n2)cc1 ; c1ccc(-c2ccc(-c3cc(-c4ccc(-c5ccc(-n6c7ccccc7c7ccccc76)cc5)cc4)nc(-c4ccccc4)n3)cc2)cc1]

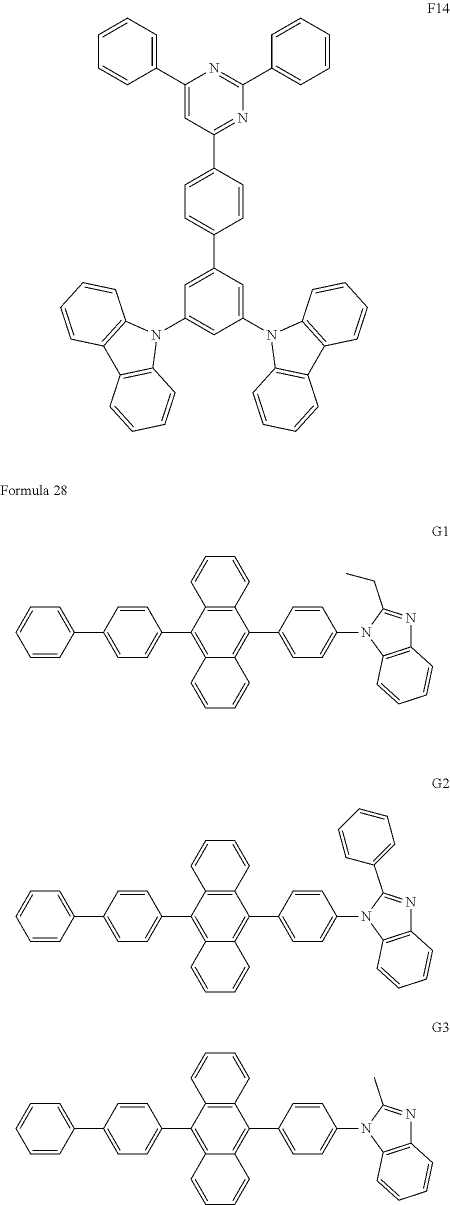 [SMILES: c1ccc(-c2cc(-c3ccc(-c4cc(-n5c6ccccc6c6ccccc65)cc(-n5c6ccccc6c6ccccc65)c4)cc3)nc(-c3ccccc3)n2)cc1 ; CCc1nc2ccccc2n1-c1ccc(-c2c3ccccc3c(-c3ccc(-c4ccccc4)cc3)c3ccccc23)cc1 ; c1ccc(-c2ccc(-c3c4ccccc4c(-c4ccc(-n5c(-c6ccccc6)nc6ccccc65)cc4)c4ccccc34)cc2)cc1 ; Cc1nc2ccccc2n1-c1ccc(-c2c3ccccc3c(-c3ccc(-c4ccccc4)cc3)c3ccccc23)cc1]

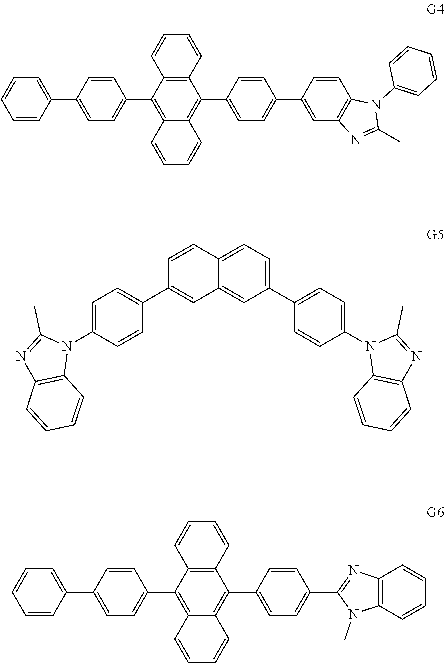 [SMILES: Cc1nc2cc(-c3ccc(-c4c5ccccc5c(-c5ccc(-c6ccccc6)cc5)c5ccccc45)cc3)ccc2n1-c1ccccc1 ; Cc1nc2ccccc2n1-c1ccc(-c2ccc3ccc(-c4ccc(-n5c(C)nc6ccccc65)cc4)cc3c2)cc1 ; Cn1c(-c2ccc(-c3c4ccccc4c(-c4ccc(-c5ccccc5)cc4)c4ccccc34)cc2)nc2ccccc21]

For example, the first ETL 538 may include the electron transporting material in Formula 25, and each of the second and third ETLs 576 and 554 may include the electron transporting material in Formula 26. The second ETL 576 may further include the electron transporting material in Formula 25. In this instance, in the second ETL 576, the electron transporting material in Formula 25 and the electron transporting material in Formula 26 may have the same weight %.

A thickness of the third ETL 554 may be greater than that of the first ETL 538 and may be equal to or smaller than that of the second ETL 576. For example, the thickness of the first ETL 538 may be about 50 to 150 Å, the thickness of the second ETL 576 may be about 50 to 350 Å, and the thickness of the third ETL 554 may be 50 to 300 Å.

The EIL 578 is positioned between the second electrode 464 and the second ETL 576 to improve the property of the second electrode 464 and the lifespan of the OLED D. For example, the EIL 578 may include at least one of an alkali halide compound, such as LiF, CsF, NaF, or BaF₂, and an organo-metallic compound, such as LiQ, lithium benzoate, or sodium stearate, but it is not limited thereto. The EIL 578 may have a thickness of 5 to 100 Å, preferably 10 to 50 Å, but it is not limited thereto.

The first CGL 580 is positioned between the first emitting part 530 and the third emitting part 550, and the second CGL 590 is positioned between the third emitting part 550 and the second emitting part 570. Namely, the first and third emitting parts 530 and 550 are connected through the first CGL 580, and the third and second emitting parts 550 and 570 are connected through the second CGL 590. The first CGL 580 may be a P-N junction CGL of an N-type CGL 582 and a P-type CGL 584, and the second CGL 590 may be a P-N junction CGL of an N-type CGL 592 and a P-type CGL 594.

In the first CGL 580, the N-type CGL 582 is positioned between the first ETL 538 and the third HTL 552, and the P-type CGL 584 is positioned between the N-type CGL 582 and the third HTL 552.

In the second CGL 590, the N-type CGL 592 is positioned between the third ETL 554 and the second HTL 572, and the P-type CGL 594 is positioned between the N-type CGL 592 and the second HTL 572.

Each of the N-type CGL 582 in the first CGL 580 and the N-type CGL 592 in the second CGL 590 may include a phenanthroline-based compound of Formula 29 as an N-type charge generation material.

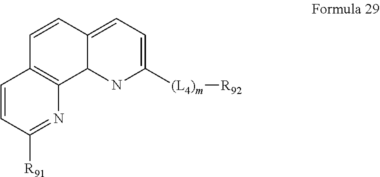

In Formula 29, R₉₁ is hydrogen or a C6 to C30 aryl group, and R₉₂ is a C6 to C30 aryl group, wherein the C6 to C30 aryl group may be substituted. L₄ is a C6 to C30 arylene group or a C5 to C30 heteroarylene group, and m is 1 or 2.

In this instance, each of aryl group, arylene group and heteroarylene group may be unsubstituted or substituted with C1 to C10 alkyl.

For example, in Formula 29, R₉₁ may be hydrogen, phenyl unsubstituted or substituted with methyl, or naphthyl unsubstituted or substituted with methyl, and R₉₂ may be phenyl unsubstituted or substituted with methyl, naphthyl unsubstituted or substituted with methyl or phenanthrenyl unsubstituted or substituted with methyl. L₄ may be phenylene, naphthylene, anthracenylene or phenanthrenylene.

The N-type charge generation material in Formula 29 may be one of the compounds in Formula 30.

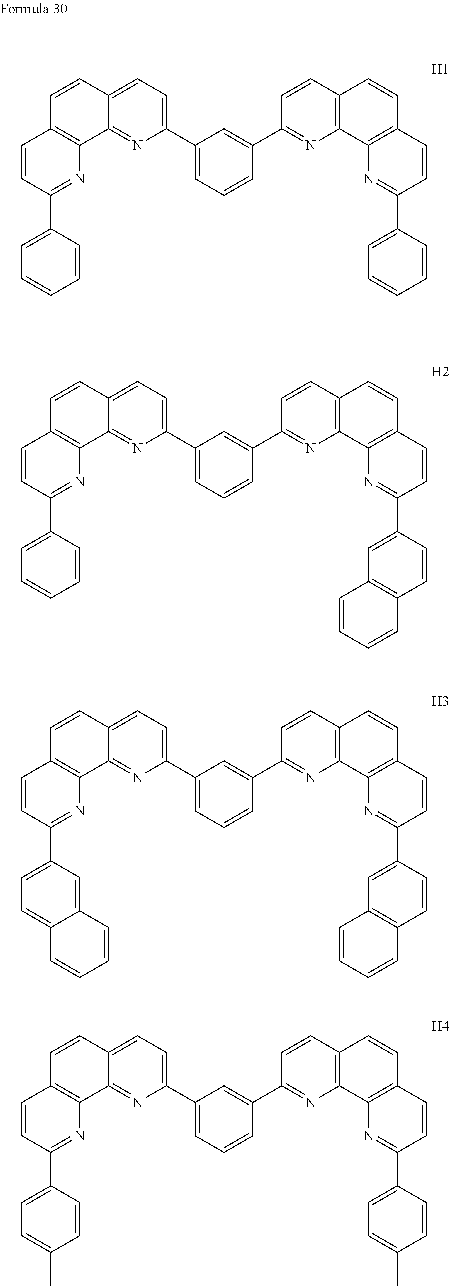 [SMILES: c1ccc(-c2ccc3ccc4ccc(-c5cccc(-c6ccc7ccc8ccc(-c9ccccc9)nc8c7n6)c5)nc4c3n2)cc1 ; c1ccc(-c2ccc3ccc4ccc(-c5cccc(-c6ccc7ccc8ccc(-c9ccc%10ccccc%10c9)nc8c7n6)c5)nc4c3n2)cc1 ; c1cc(-c2ccc3ccc4ccc(-c5ccc6ccccc6c5)nc4c3n2)cc(-c2ccc3ccc4ccc(-c5ccc6ccccc6c5)nc4c3n2)c1 ; Cc1ccc(-c2ccc3ccc4ccc(-c5cccc(-c6ccc7ccc8ccc(-c9ccc(C)cc9)nc8c7n6)c5)nc4c3n2)cc1]

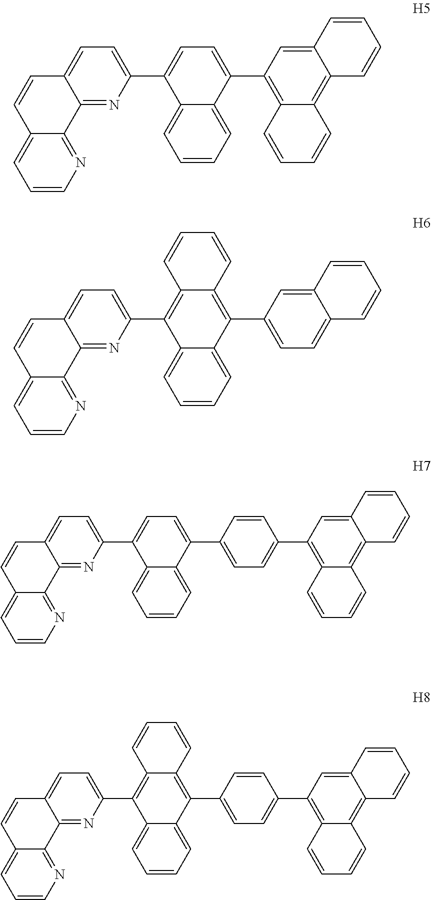 [SMILES: c1ccc2c(c1)cc(-c1ccc(-c3ccc4ccc5cccnc5c4n3)c3ccccc13)c1ccccc12 ; c1ccc2cc(-c3c4ccccc4c(-c4ccc5ccc6cccnc6c5n4)c4ccccc34)ccc2c1 ; c1ccc2c(c1)cc(-c1ccc(-c3ccc(-c4ccc5ccc6cccnc6c5n4)c4ccccc34)cc1)c1ccccc12 ; c1ccc2c(c1)cc(-c1ccc(-c3c4ccccc4c(-c4ccc5ccc6cccnc6c5n4)c4ccccc34)cc1)c1ccccc12]

Each of the N-type CGL 582 in the first CGL 580 and the N-type CGL 592 in the second CGL 590 may further include a dopant being one of alkali metal, e.g., Li, Na, K or Cs, and alkali earth metal, e.g., Mg, Sr, Ba or Ra. In this instance, the electron generation property and/or the electron injection property of the N-type CGLs 582 and 592 may be improved. In each of the N-type CGLs 582 and 592, the dopant may have a weight % of 0.1 to 10. In addition, each of the N-type CGLs 582 and 592 may have a thickness of 30 to 500 Å, preferably 50 to 300 Å. For example, the weight % of the dopant in the N-type CGL 582 in the first CGL 580 may be greater than that of the dopant in the N-type CGL 592 in the second CGL 590, and the thickness of the N-type CGL 582 in the first CGL 580 may be smaller than that of the N-type CGL 592 in the second CGL 590.

Each of the P-type CGL 584 in the first CGL 580 and the P-type CGL 594 in the second CGL 590 may include the compound in Formula 9. For example, each of the P-type CGL 584 in the first CGL 580 and the P-type CGL 594 in the second CGL 590 may include one of the compounds in Formula 10.

In addition, each of the P-type CGL 584 in the first CGL 580 and the P-type CGL 594 in the second CGL 590 may further include a compound having a radialene structure in Formula 31 as a dopant.

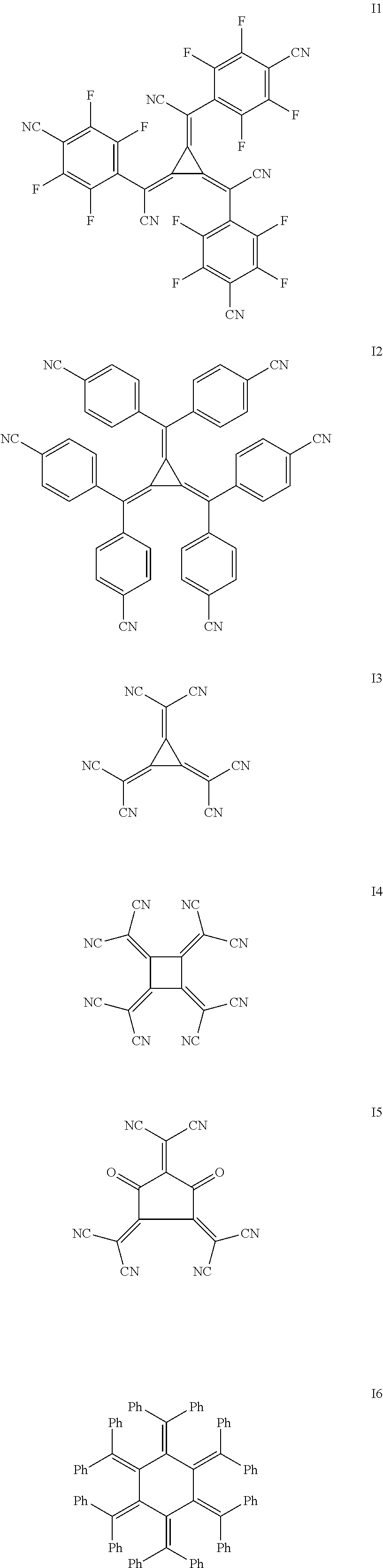

In each of the P-type CGL 584 in the first CGL 580 and the P-type CGL 594 in the second CGL 590, the dopant may have a weight % of 1 to 40, preferably 3 to 30. In addition, each of the P-type CGL 584 in the first CGL 580 and the P-type CGL 594 in the second CGL 590 may have a thickness of 30 to 500 Å, preferably 50 to 200 Å.

For example, the weight % of the dopant in the P-type CGL 584 in the first CGL 580 may be same as that of the dopant in the P-type CGL 594 in the second CGL 590, and the thickness of the P-type CGL 584 in the first CGL 580 may be smaller than that of the P-type CGL 594 in the second CGL 590.

As described above, the OLED D of the present disclosure includes a first EML 520 positioned to be closer to the first electrode 460 as the anode, a second EML 560 positioned to be closer to the second electrode 464 as the cathode and a third EML 540 positioned between the first and second EMLs 520 and 560, each of the first and second EMLs 520 and 560 respectively emit the blue light, and the third EML 540 emits the yellow-green light. Accordingly, the OLED D emits the white light.

The first EML 520 includes the first compound 522 being anthracene derivative and having a first deuteration ratio, and the second EML 560 includes the second compound 562 being anthracene derivative and having a second deuteration ratio, which is smaller than the first deuteration ratio. Accordingly, the OLED D and the organic light emitting display device 400 have advantages in the emitting efficiency and the lifespan.

### Synthesis

### 1. Synthesis of the Compound Host1-2

### (1) Intermediate H-1

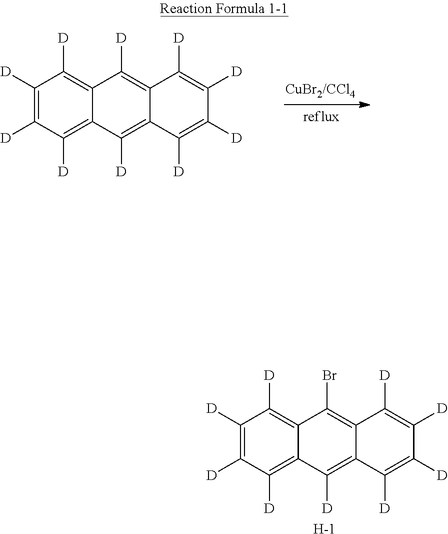

Anhydrous cupric bromide (45 g, 0.202 mol) was added into anthracene-D10 (18.8 g, 0.10 mol) CCl₄ solution. The mixture was heated and stirred under a nitrogen atmosphere for 12 hrs. After completion of reaction, white CuBr(I) compound was filtered off, and the residual liquid was refined by using 35 nm Alumina column. Under vacuum condition, the solvent was removed from the reaction solution, which is refined, by using column to obtain the mixture including the intermediate H-1 (9-bromoanthracene-D9).

The mixture includes the intermediate H-1, the starting material (anthracene-D10) and dibromo-byproduct. The mixture without additional refinement was used as the starting material in the reaction Formula 1-2.

### (2) Intermediate H-2

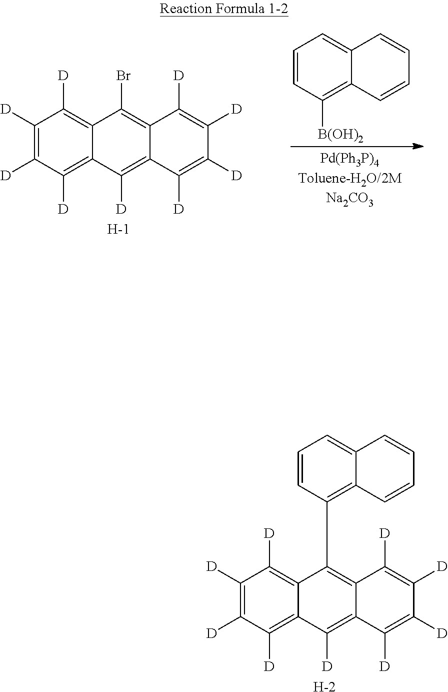

The intermediate H-1 (2.66 g, 0.01 mol) and naphtalene-1-boronic acid (1.72 g, 0.01 mol) was added into the rounded-bottom flask, and toluene (30 ml) was further added to form a mixture solution. Under a nitrogen atmosphere, the mixture solution was stirred and Na₂CO₃ aqueous solution, which is formed by dissolving Na₂CO₃ (2.12 g) into distilled water (10 ml), was added. Pd(PPh₃)₄ (0.25 g, 0.025 mmol) as catalyst was further added and stirred. After completion of reaction, the reaction solution was added into methanol solution to precipitate a product, and the precipitated product was filtered. In the reduce-pressure filter, the precipitated product was washed sequentially using water, hydrogen chloride aqueous solution (10% concentration), water and methanol. The precipitated product was refined to obtain the intermediate H-2 of white powder (2.6 g).

### (3) Intermediate H-3

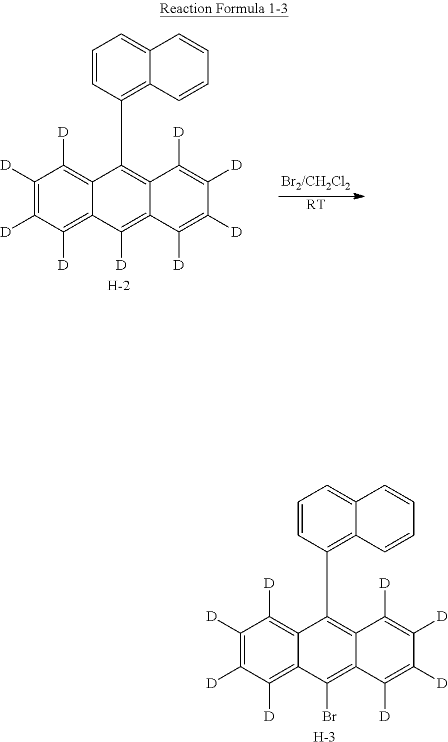

After dissolving the intermediate H-2 (2.8 g, 8.75 mmol) into dichloromethane (50 mL), Bra (1.4 g, 8.75 mmol) was added and stirred under the room temperature (RT). After completion of reaction, 2M Na₂S₂O₃ aqueous solution (10 mL) was added into the reactant and stirred. The organic layer was separated and washed using Na₂S₂O₃ aqueous solution (10% concentration, 10 mL) and distilled water. The organic layer was separated again, and water in the organic layer was removed by using MgSO₄. After the organic layer was concentrated, excessive methanol was added to obtain a product. The product was filtered to obtain the intermediate H-3 (3.3 g).

### (4) Host1-2

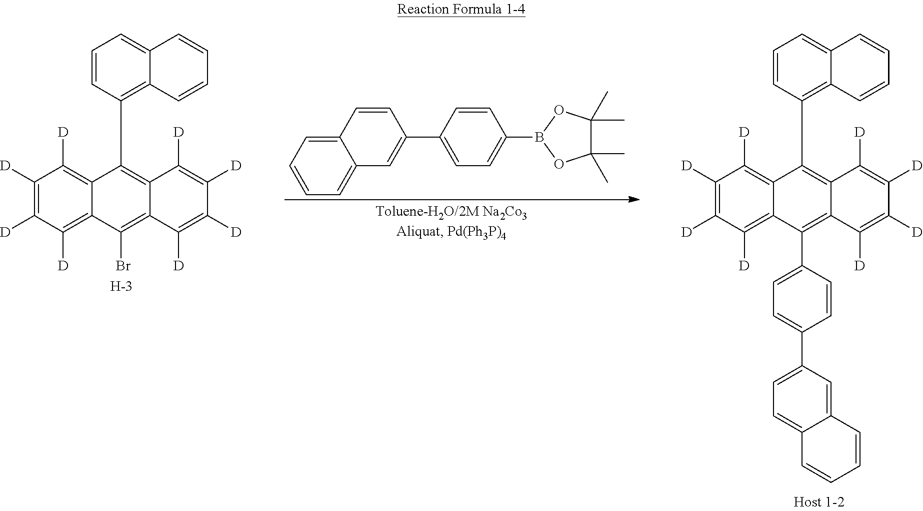

The intermediate H-3 (1.96 g, 0.05 mol) and 4-(naphthalene-2-yl)phenylboronic acid (1.49 g, 0.06 mol) were added and dissolved into toluene (30 ml). The mixture solution was stirred under a nitrogen atmosphere. Na₂CO₃ aqueous solution (1 ml), which is formed by dissolving Na₂CO₃ (1.90 g) into distilled water (8 ml), was added into the mixture solution. Pd(PPh₃)₄ (0.25 mmol) was further added. The mixture was heated and stirred under a nitrogen atmosphere. After completion of reaction, the organic layer was separated, and methanol was added into the organic layer to precipitate a white solid mixture. The white solid mixture was refined by silica-gel column chromatography using the eluent of chloroform and hexane (volume ratio=1:3) to obtain the compound Host1-2 (2.30 g).

### 2. Synthesis of the Compound Host1-3

### (1) Intermediate H-4

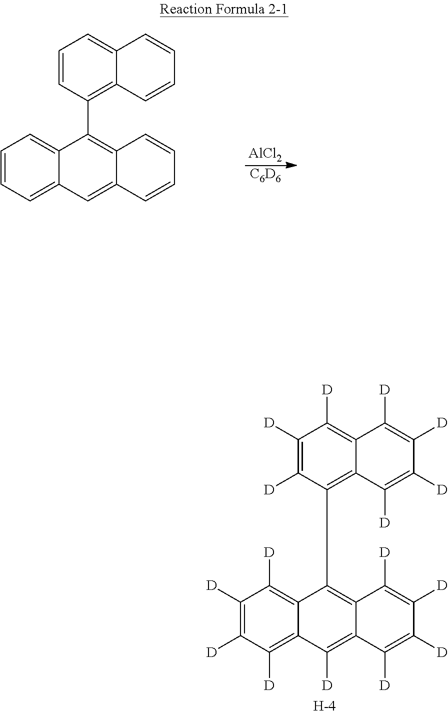

In a nitrogen atmosphere, AlCl₂ (0.391 g, 4 mmol) was added to a benzene-D6 (C₆D₆) solution (100 mL) in which 10-(naphthalene-1-yl)anthracene (3.05 g, 10 mmol) was dissolved. After the mixed solution was stirred at room temperature for 6 hours, D₂O (50 mL) was added. The organic solution layer and the aqueous layer were separated, and the aqueous layer was washed with dicholomethane. After separating the organic solution layer, magnesium sulfate was added thereto, followed by stirring and drying. The mixture was filtered to separate only the organic solution. The solvent was removed from the organic solution by rotary evaporation to obtain a crude product. The crude product was purified through column chromatography to obtain Intermediate H-4. (2.88 g, 9 mmol)

### (2) Intermediate H-5

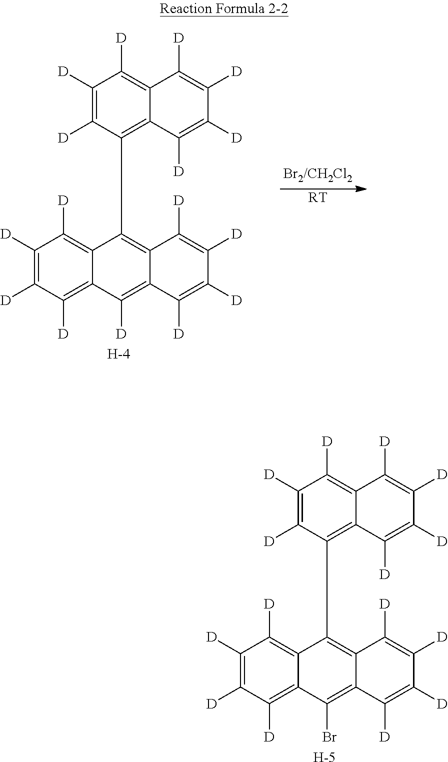

After dissolving the intermediate H-4 (2.88 g, 9 mmol) into dichloromethane (50 mL), Bra (1.45 g, 9 mmol) was added and stirred. After completion of reaction, 2M Na₂S₂O₃ aqueous solution (10 mL) was added into the reactant and stirred. The organic layer was separated and washed using Na₂S₂O₃ aqueous solution (10% concentration, 10 mL) and distilled water. The organic layer was separated again, and water in the organic layer was removed by using MgSO₄. After the organic layer, from which the water was removed, was concentrated, excessive methanol was added to obtain a product. The product was filtered to obtain the intermediate H-5 (2.8 g).

### (3) Host1-3

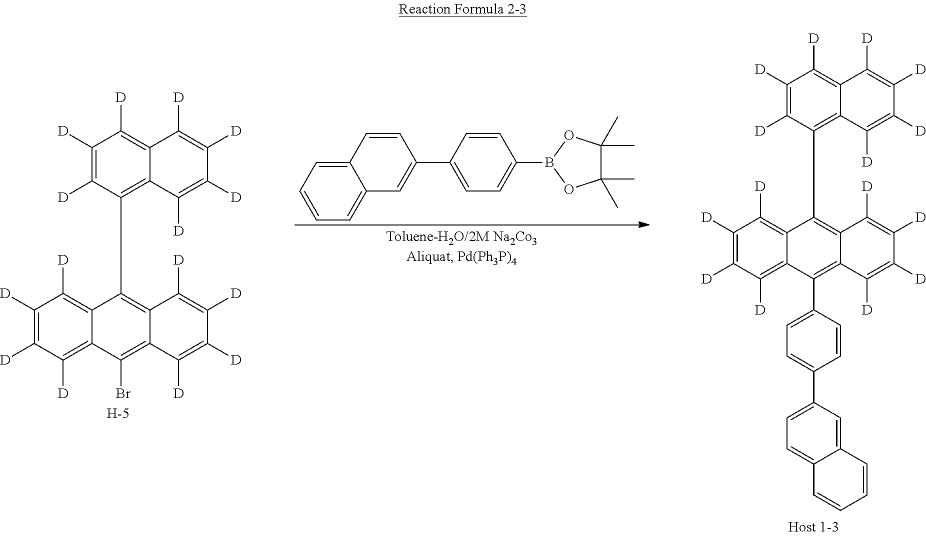

The intermediate H-5 (2.8 g, 7 mmol) and 4-(naphthalene-2-yl)phenylboronic acid (2.4 g, 8 mmol) were added and dissolved into toluene (30 ml). The mixture solution was stirred under a nitrogen atmosphere. Na₂CO₃ aqueous solution (1 ml), which is formed by dissolving Na₂CO₃ (1.90 g) into distilled water (8 ml), was added into the mixture solution. Pd(PPh₃)₄ (0.25 mmol) was further added. The mixture was heated and stirred under a nitrogen atmosphere. After completion of reaction, the organic layer was separated, and methanol was added into the organic layer to precipitate a white solid mixture. The white solid mixture was refined by silica-gel column chromatography using the eluent of chloroform and hexane (volume ratio=1:3) to obtain the compound Host1-3 (3.1 g).

### 3. Synthesis of the Compound Host1-4

### (1) Intermediate H-6

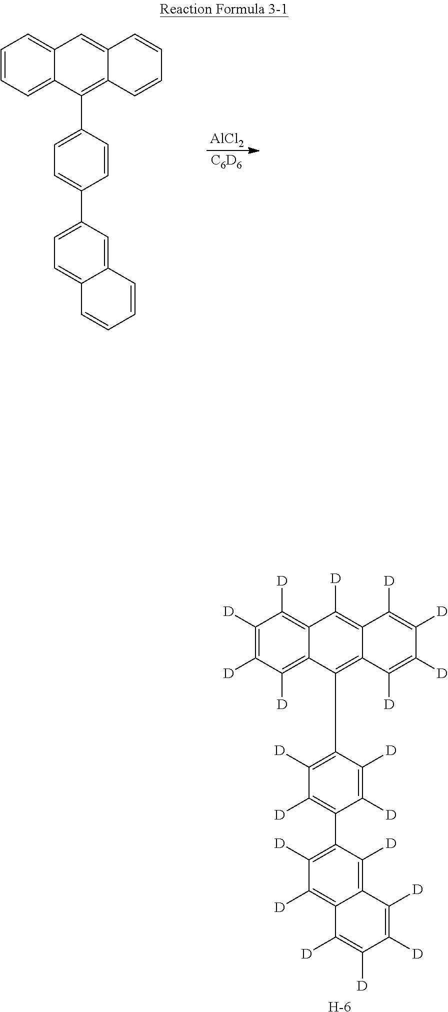

In a nitrogen atmosphere, AlCl₂ (0.391 g, 4 mmol) was added to a benzene-D6 (C₆D₆) solution (100 mL) in which 10-(4-(naphthalene-2-yl)phenyl)anthracene (3.8 g, 10 mmol) was dissolved. After the mixed solution was stirred at room temperature for 6 hours, D₂O (50 mL) was added. The organic solution layer and the aqueous layer were separated, and the aqueous layer was washed with dicholomethane. After separating the organic solution layer, magnesium sulfate was added thereto, followed by stirring and drying. The mixture was filtered to separate only the organic solution. The solvent was removed from the organic solution by rotary evaporation to obtain a crude product. The crude product was purified through column chromatography to obtain Intermediate H-6. (63.6 g, 9 mmol)

### (2) Intermediate H-7

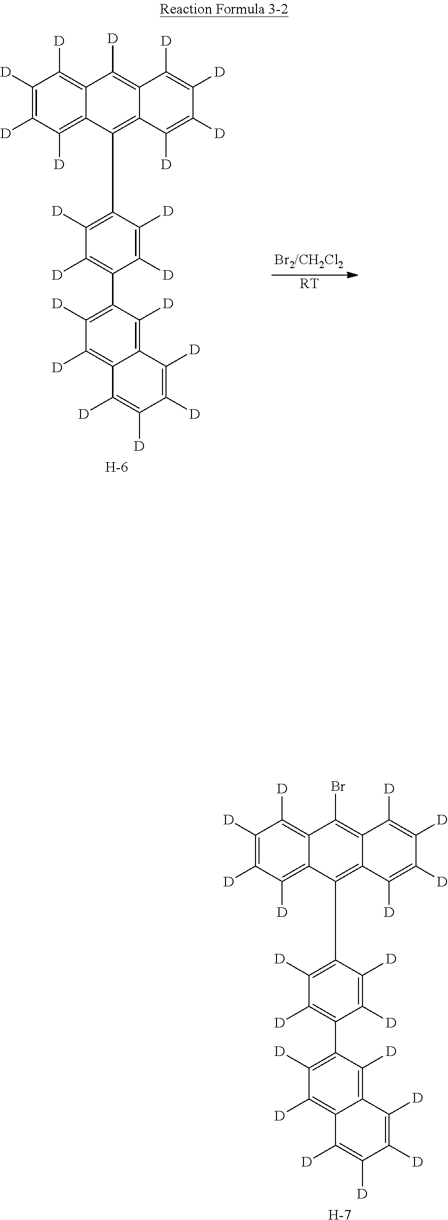

After dissolving the intermediate H-6 (63.6 g, 9 mmol) into dichloromethane (50 mL), Bra (1.45 g, 9 mmol) was added and stirred. After completion of reaction, 2M Na₂S₂O₃ aqueous solution (10 mL) was added into the reactant and stirred. The organic layer was separated and washed using Na₂S₂O₃ aqueous solution (10% concentration, 10 mL) and distilled water. The organic layer was separated again, and water in the organic layer was removed by using MgSO₄. After the organic layer was concentrated, excessive methanol was added to obtain a product. The product was filtered to obtain the intermediate H-7 (3.34 g).

### (3) Host1-4

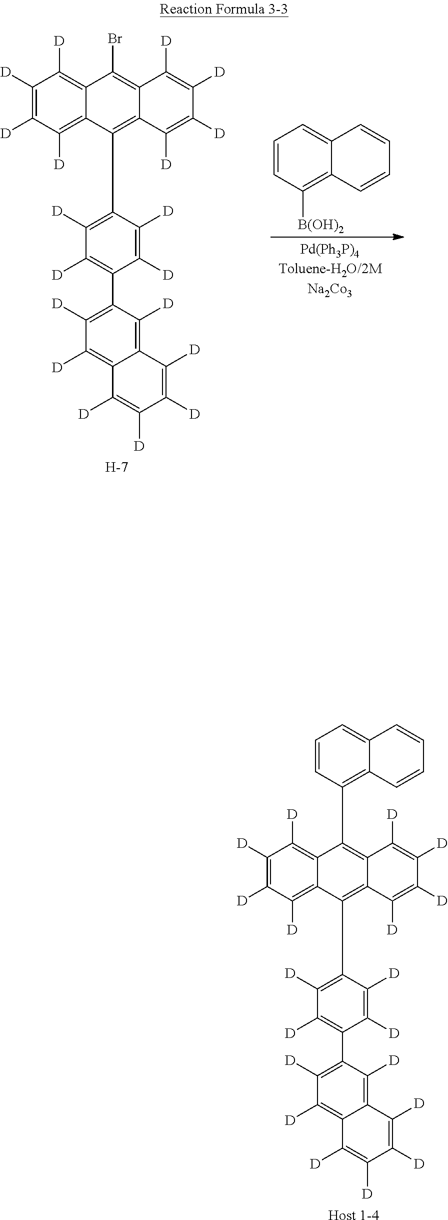

The intermediate H-7 (3.35 g, 7 mmol) and naphthalene-1-yl-1-boronic acid (1.38 g, 8 mmol) were added and dissolved into toluene (30 ml). The mixture solution was stirred under a nitrogen atmosphere. Na₂CO₃ aqueous solution (1 ml), which is formed by dissolving Na₂CO₃ (1.90 g) into distilled water (8 ml), was added into the mixture solution. Pd(PPh₃)₄ (0.25 mmol) was further added. The mixture was heated and stirred under a nitrogen atmosphere. After completion of reaction, the organic layer was separated, and methanol was added into the organic layer to precipitate a white solid mixture. The white solid mixture was refined by silica-gel column chromatography using the eluent of chloroform and hexane (volume ratio=1:3) to obtain the compound Host1-4 (3.2 g).

### 4. Synthesis of the Compound Host1-5

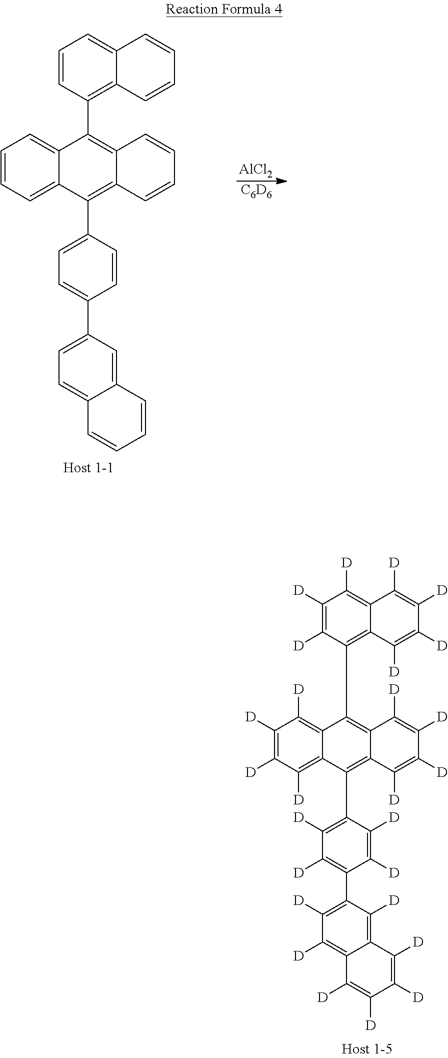

In a nitrogen atmosphere, AlCl₂ (0.391 g, 4 mmol) was added to a benzene-D6 (C₆D₆) solution (100 mL) in which the compound Host1-1 (5.06 g, 10 mmol) was dissolved. After the mixed solution was stirred at room temperature for 6 hours, D₂O (50 mL) was added. The organic solution layer and the aqueous layer were separated, and the aqueous layer was washed with dicholomethane. After separating the organic solution layer, magnesium sulfate was added thereto, followed by stirring and drying. The mixture was filtered to separate only the organic solution. The solvent was removed from the organic solution by rotary evaporation to obtain a crude product. The crude product was purified through column chromatography to obtain the compound Host1-5. (4.26 g)

### Organic Light Emitting Diode

On the anode (ITO), the HIL (the compound J4 in Formula 22 and MgF₂ (weight % ratio=1:1), 70 Å), the first HTL (the compound E3 in Formula 10, 850 Å), the first EBL (the compound H3 in Formula 24, 150 Å), the first blue EML (host and dopant (the compound Dopant2, 3 wt % doping), 200 Å), the first ETL (the compound F1 in Formula 27, 60 Å), the first N-type CGL (the compound H1 in Formula 30 and L₁ (1.5 wt % doping), 170 Å), the first P-type CGL (the compound E3 in Formula 10 and the compound I1 in Formula 31 (10 wt % doping), 75 Å), the third HTL (the compound E3 in Formula 10, 50 Å), the red EML (host (the compound E3 in Formula 10 and the compound L₉ in Formula 12 (weight % ratio=3:7) and dopant (the compound M10 in Formula 14, 3.5 wt % doping), 150 Å), the green EML (host (the compound P2 in Formula 16 and the compound Q10 in Formula 18 (weight % ratio=7:3) and dopant (the compound S5 in Formula 20, 10 wt % doping), 350 Å), the third ETL (the compound G1 in Formula 28, 180 Å), the second N-type CGL (the compound H1 in Formula 30 and L₁ (0.7 wt % doping), 240 Å), the second P-type CGL (the compound E3 in Formula 10 and the compound I1 in Formula 31 (10 wt % doping), 110 Å), the second HTL (the compound E3 in Formula 10, 640 Å), the second EBL (the compound H3 in Formula 24, 150 Å), the second blue EML (host and dopant (the compound Dopant2, 2.5 wt % doping), 300 Å), the second ETL (the compound G1 in Formula 28, 230 Å), the EIL (LiF, 13.5 Å) and the cathode (AgMg (weight % ratio=10:1), 175 Å) was sequentially deposited. An encapsulation film is formed by using an UV curable epoxy and a moisture getter to form the OLED.

### 1. COMPARATIVE EXAMPLES

### (1) Comparative Example 1 (Ref1)

The compound Host1-1 is used as the host in each of the first and second blue EMLs.

### (2) Comparative Example 2 (Ref2)

The compound Host1-1 is used as the host in the first blue EML, and the compound Host1-5 is used as the host in the second blue EML.

### (3) Comparative Example 3 (Ref3)

The compound Host1-2 is used as the host in each of the first and second blue EMLs.

### (4) Comparative Example 4 (Ref4)

The compound Host1-3 is used as the host in each of the first and second blue EMLs.

### (5) Comparative Example 5 (Ref5)

The compound Host1-4 is used as the host in each of the first and second blue EMLs.

### (6) Comparative Example 6 (Ref6)

The compound Host1-5 is used as the host in each of the first and second blue EMLs.

### (7) Comparative Example 7 (Ref7)

The compound Host1-3 is used as the host in the first blue EML, and the compound Host1-5 is used as the host in the second blue EML.

### (8) Comparative Example 8 (Ref8)

The compound Host1-4 is used as the host in the first blue EML, and the compound Host1-5 is used as the host in the second blue EML.

### 2. EXAMPLES

### (1) Example 1 (Ex1)

The compound Host1-5 is used as the host in the first blue EML, and the compound Host1-1 is used as the host in the second blue EML.

### (2) Example 2 (Ex2)

The compound Host1-5 is used as the host in the first blue EML, and the compound Host1-3 is used as the host in the second blue EML.

### (3) Example 3 (Ex3)

The compound Host1-5 is used as the host in the first blue EML, and the compound Host1-4 is used as the host in the second blue EML.

The properties, i.e., voltage (V), efficiency (Cd/A), lifespan (T95) and color coordinate (CIE), of the OLEDs manufactured in Comparative Examples 1 to 8 and Examples 1 to 3 are measured using the current supply (KEITJLE) and a photo-meter (PR-650) and listed in Table 1.

TABLE 1

| | V | cd/A | T95 [hr] | CIEx | CIEy |
|---|---|---|---|---|---|
| Ref1 | 12.68 | 4.36 | 204 | 0.26 | 0.269 |
| Ref2 | 12.88 | 4.14 | 282 | 0.26 | 0.269 |
| Ref3 | 12.93 | 4.22 | 308 | 0.26 | 0.269 |
| Ref4 | 12.08 | 4.51 | 388 | 0.26 | 0.269 |
| Ref5 | 11.98 | 4.56 | 389 | 0.26 | 0.269 |
| Ref6 | 13.13 | 4.12 | 406 | 0.26 | 0.269 |
| Ref7 | 12.93 | 4.14 | 392 | 0.26 | 0.269 |
| Ref8 | 12.93 | 4.15 | 392 | 0.26 | 0.269 |
| Ex1 | 12.93 | 4.32 | 296 | 0.26 | 0.269 |
| Ex2 | 12.08 | 4.48 | 398 | 0.26 | 0.269 |
| Ex3 | 11.98 | 4.53 | 404 | 0.26 | 0.269 |

As shown in Table 1, in comparison to the OLEDs of Ref1 to Ref8, where the anthracene derivatives as the host in the first and second blue EMLs have the same deuteration ratio or the anthracene derivative in the second blue EML has a deuteration ratio being greater than the anthracene derivative in the first blue EML, the OLEDs of Ex1 to Ex3, where a deuteration ratio of the anthracene derivative as the host in the first blue EML is greater than that of the anthracene derivative as the host in the second blue EML, have advantages in the emitting efficiency and the lifespan.

For example, in comparison to the OLEDs of Ref2, Ref7 and Ref8, where the first blue EML includes the compound Host1-1 having a deuteration ratio of 0%, the compound Host1-3 having a deuteration ratio of 57% or the compound Host1-4 having a deuteration ratio of 73% and the second blue EML includes the compound Host1-5 having a deuteration ratio of 100%, the emitting efficiency and the lifespan of the OLEDs of Ex1 to Ex3, where the first blue EML includes the compound Host1-5 having the deuteration ratio of 100% and the second EML includes the compound Host1-1 having the deuteration ratio of 0%, the compound Host1-3 having the deuteration ratio of 57% or the compound Host1-4 having the deuteration ratio of 73%, are significantly increased.

On the other hand, in comparison to the OLED of Ref6, where both of the first and second blue EMLs include the compound Host1-5, the lifespan of the OLEDs of Ex1 to Ex3 is little short. However, since the anthracene derivative used in the OLEDs of Ex1 to Ex3 includes less deuterium atoms, which is very expensive, than the anthracene derivative used in the OLEDs of Ref6, the increase of the production cost of the OLED in Examples 1 to 3 is minimized and the OLED in Examples 1 to 3 provides sufficient lifespan increase.

As described above, the OLED of the present disclosure includes a first EML, i.e., a first blue EML, positioned between the anode and the cathode and including the anthracene derivative and a second EML, i.e., a second blue EML, positioned between the first EML and the cathode and including the anthracene derivative, and a deuteration ratio of the anthracene derivative in the first EML is greater than that of the anthracene derivative in the second EML. Accordingly, the emitting efficiency and the lifespan of the OLED and the organic light emitting display device are increased.

It will be apparent to those skilled in the art that various modifications and variations can be made in the embodiments of the present disclosure without departing from the spirit or scope of the present disclosure. Thus, it is intended that the modifications and variations cover this disclosure provided they come within the scope of the appended claims and their equivalents.

The various embodiments described above can be combined to provide further embodiments. All of the U.S. patents, U.S. patent application publications, U.S. patent applications, foreign patents, foreign patent applications and non-patent publications referred to in this specification and/or listed in the Application Data Sheet are incorporated herein by reference, in their entirety. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. An organic light emitting diode, comprising:
a first electrode;
a second electrode facing the first electrode;
a first emitting material layer including a first compound and positioned between the first and second electrodes; and
a second emitting material layer including a second compound and positioned between the first emitting material layer and the second electrode,
wherein the first compound is represented by Formula 1, and the second compound is represented by Formula 2: 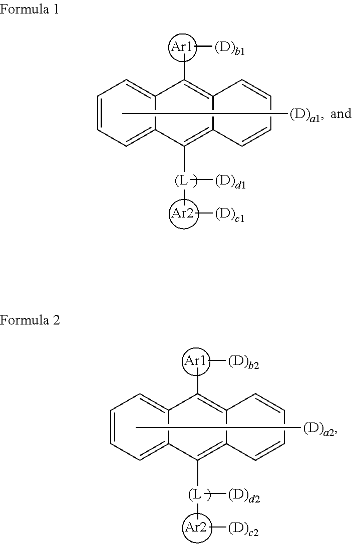
wherein:
each of Ar1 and Ar2 is independently a C6 to C20 aryl group,
L is a C6 to C20 arylene group,
each of a1 and a2 is independently an integer of 0 to 8,
each of b1, b2, c1, c2, d1 and d2 is independently an integer of 0 to 20, and
a sum of a1, b1, c1 and d1 is greater than a sum of a2, b2, c2 and d2.

2. The organic light emitting diode according to claim 1, wherein the first compound is represented by Formula 3, and the second compound is represented by Formula 4: 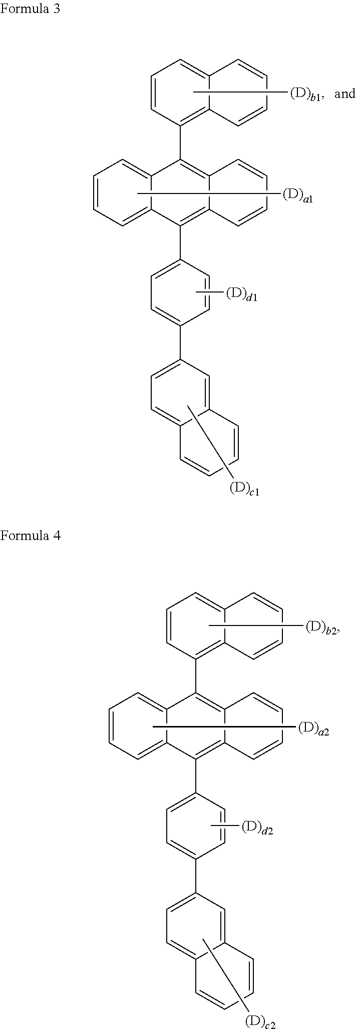
wherein:
each of a1 and a2 is independently an integer of 0 to 8,
each of b1, b2, c1 and c2 is independently an integer of 0 to 7, each of d1 and d2 is independently an integer of 0 to 4, and a sum of a1, b1, c1 and d1 is greater than a sum of a2, b2, c2 and d2.

3. The organic light emitting diode according to claim 1, wherein the first compound is a compound of Formula 5:

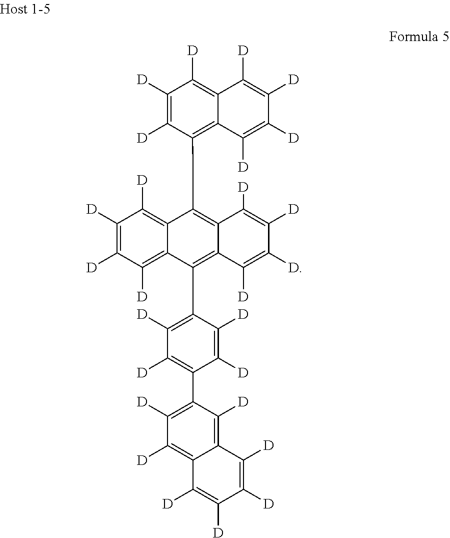

4. The organic light emitting diode according to claim 1, wherein the second compound is one of compounds of Formula 6:

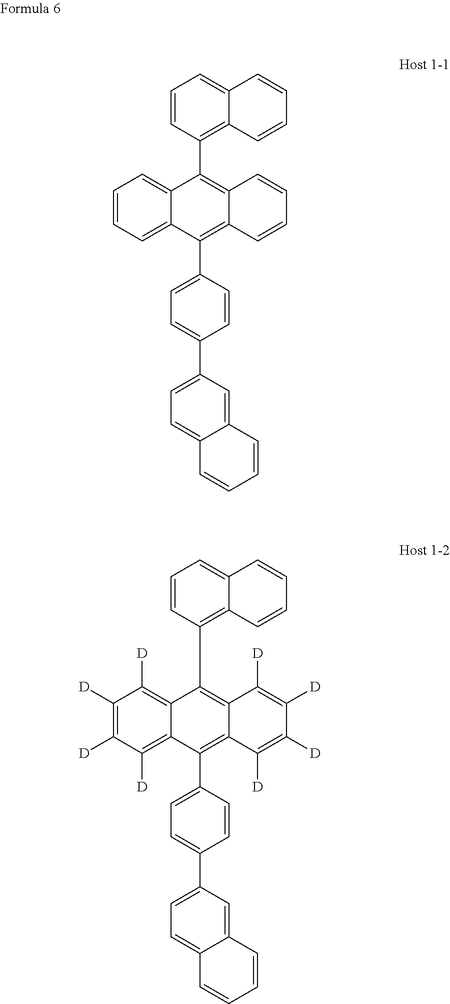

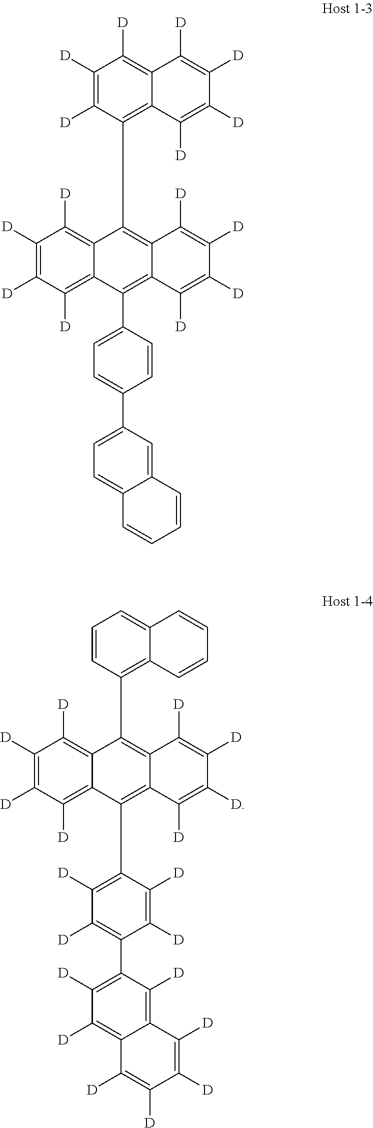

5. The organic light emitting diode according to claim 1, wherein the first emitting material layer includes a third compound being a boron derivative, and the second emitting material layer includes a fourth compound being a boron derivative.

6. The organic light emitting diode according to claim 5, wherein each of the third and fourth compounds is represented by Formula 7: 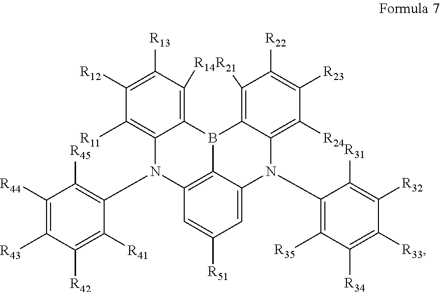
wherein:
each of R₁₁, R₁₂, R₁₃ and R₁₄, each of R₂₁, R₂₂, R₂₃ and R₂₄, each of R₃₁, R₃₂, R₃₃, R₃₄ and R₃₅ and each of R₄₁, R₄₂, R₄₃, R₄₄ and R₄₅ is independently selected from the group consisting of hydrogen, deuterium, a C1 to C10 alkyl group, a C6 to C30 aryl group unsubstituted or substituted with C1-C10 alkyl, a C12 to C30 arylamino group and a C5 to C30 heteroaryl group, or adjacent two of R₁₁, R₁₂, R₁₃ and R₁₄, adjacent two of R₂₁, R₂₂, R₂₃ and R₂₄, adjacent two of R₃₁, R₃₂, R₃₃, R₃₄ and R₃₅ and adjacent two of R₄₁, R₄₂, R₄₃, R₄₄ and R₄₅ together with the carbon atoms to which they are attached are connected to form a fused ring, and
R₅₁ is selected from the group consisting of hydrogen, deuterium (D), a C1 to C10 alkyl group, a C3 to C30 cycloalkyl group, a C6 to C30 aryl group, a C5 to C30 heteroaryl group unsubstituted or substituted with at least one of deuterium and C1-C10 alkyl and a C6 to C30 arylamino group unsubstituted or substituted with at least one of deuterium and C1-C10 alkyl.

7. The organic light emitting diode according to claim 6, wherein each of the third and fourth compounds is independently selected from compounds of Formula 8:

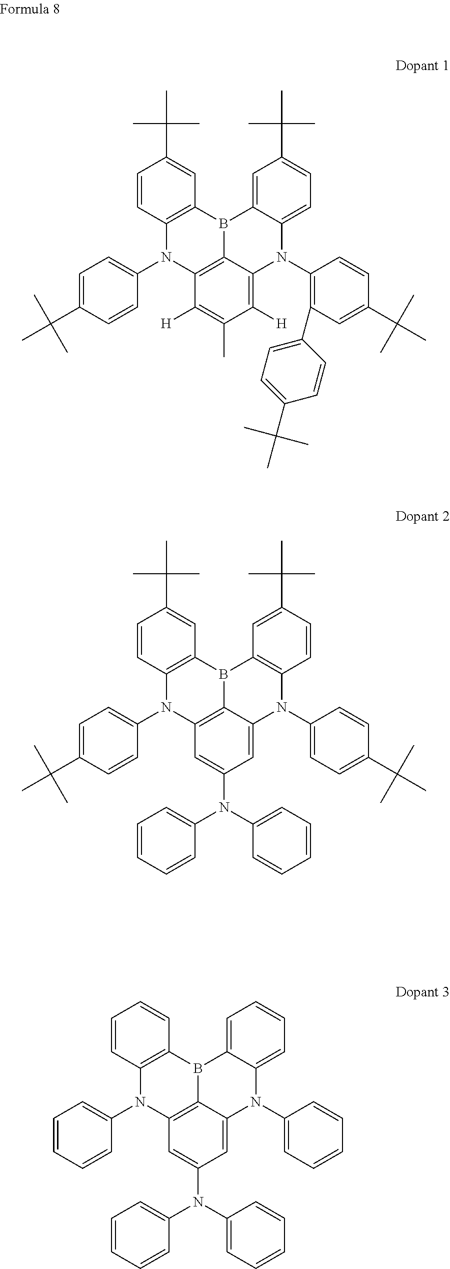

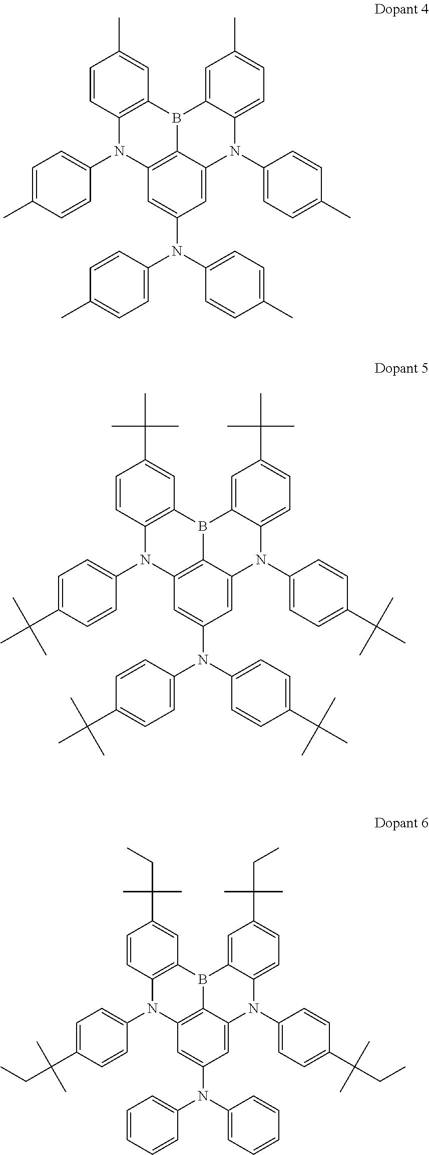

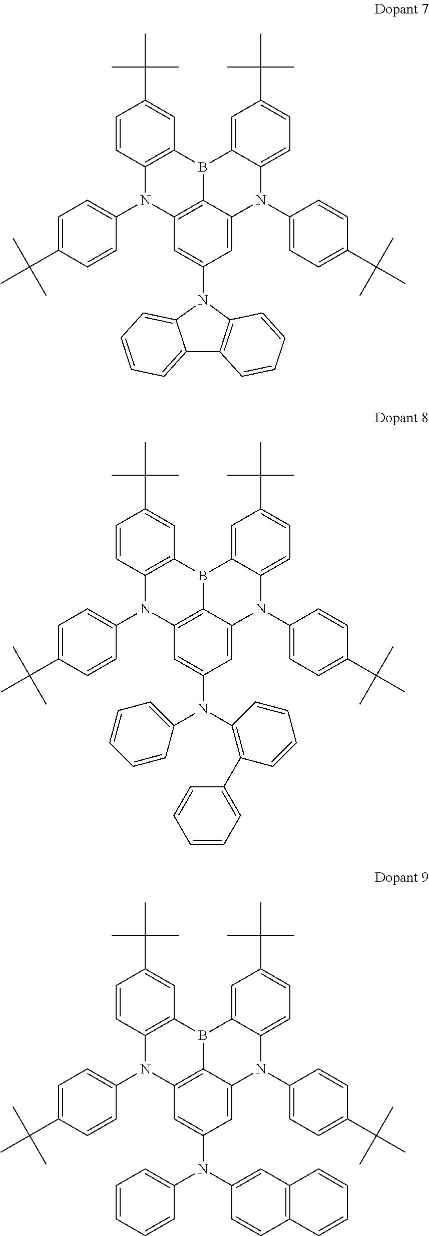

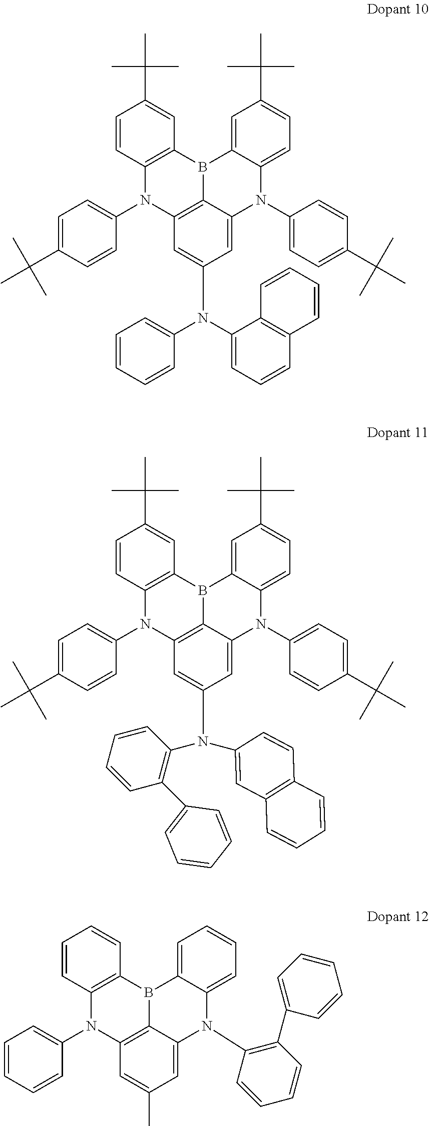

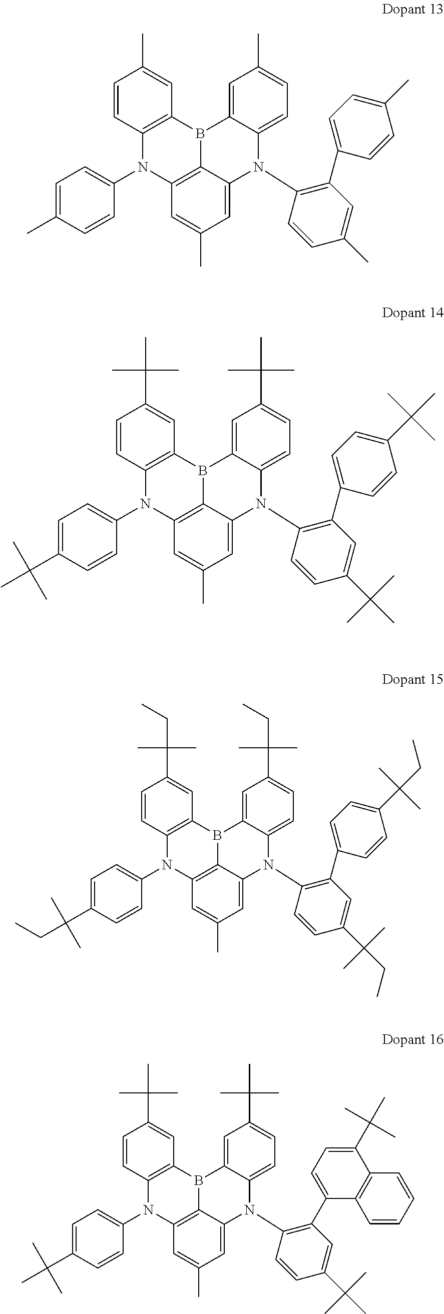

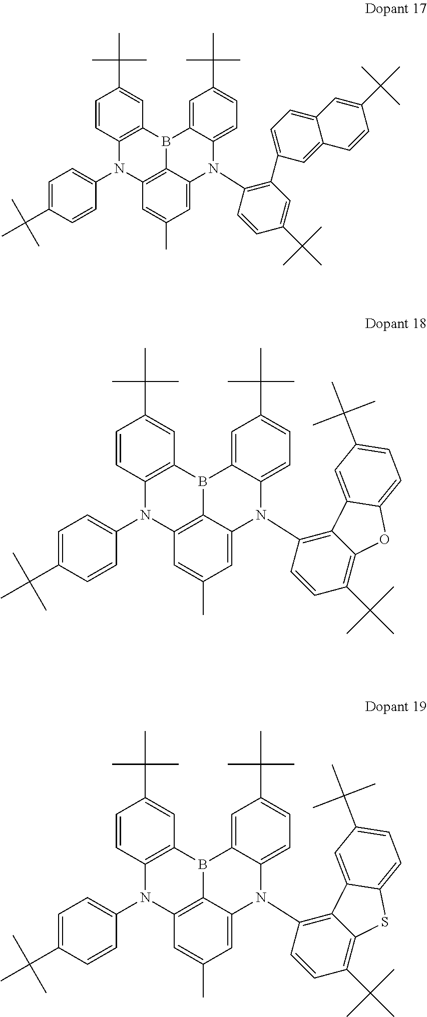

8. The organic light emitting diode according to claim 5, wherein a weight % of the third compound in the first emitting material layer is equal to or greater than a weight % of the fourth compound in the second emitting material layer.

9. The organic light emitting diode according to claim 8, wherein a thickness of the first emitting material layer is equal to or smaller than a thickness of the second emitting material layer.

10. The organic light emitting diode according to claim 1, further comprising a charge generation layer between the first and second emitting material layers.

11. The organic light emitting diode according to claim 1, further comprising:
a third emitting material layer between the first and second emitting material layers;
a first charge generation layer between the first and third emitting material layers; and
a second charge generation layer between the second and third emitting material layers.

12. The organic light emitting diode according to claim 11, wherein the third emitting material layer includes a red emitting material layer and a green emitting material layer.

13. An organic light emitting device, comprising:
a substrate; and
an organic light emitting diode positioned on the substrate and including:
a first electrode;
a second electrode facing the first electrode;
a first emitting material layer including a first compound and positioned between the first and second electrodes; and
a second emitting material layer including a second compound and positioned between the first emitting material layer and the second electrode,
wherein the first compound is represented by Formula 1, and the second compound is represented by Formula 2: 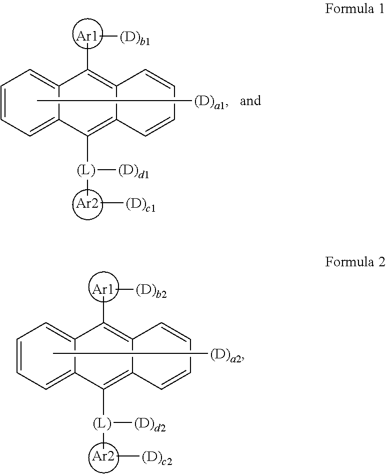
wherein:
each of Ar1 and Ar2 is independently a C6 to C20 aryl group,
L is a C6 to C20 arylene group,
each of a1 and a2 is independently an integer of 0 to 8,
each of b1, b2, c1, c2, d1 and d2 is independently an integer of 0 to 20, and
a sum of a1, b1, c1 and d1 is greater than a sum of a2, b2, c2 and d2.

14. The organic light emitting device according to claim 13, wherein the first compound is represented by Formula 3, and the second compound is represented by Formula 4: 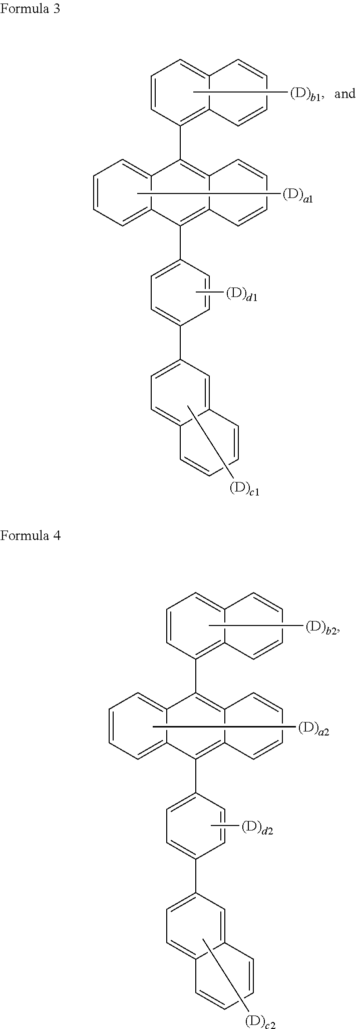
wherein:
each of a1 and a2 is independently an integer of 0 to 8,
each of b1, b2, c1 and c2 is independently an integer of 0 to 7,
each of d1 and d2 is independently an integer of 0 to 4, and
a sum of a1, b1, c1 and d1 is greater than a sum of a2, b2, c2 and d2.

15. The organic light emitting device according to claim 13, wherein the first compound is a compound of Formula 5, and wherein the second compound is one of compounds of Formula 6:

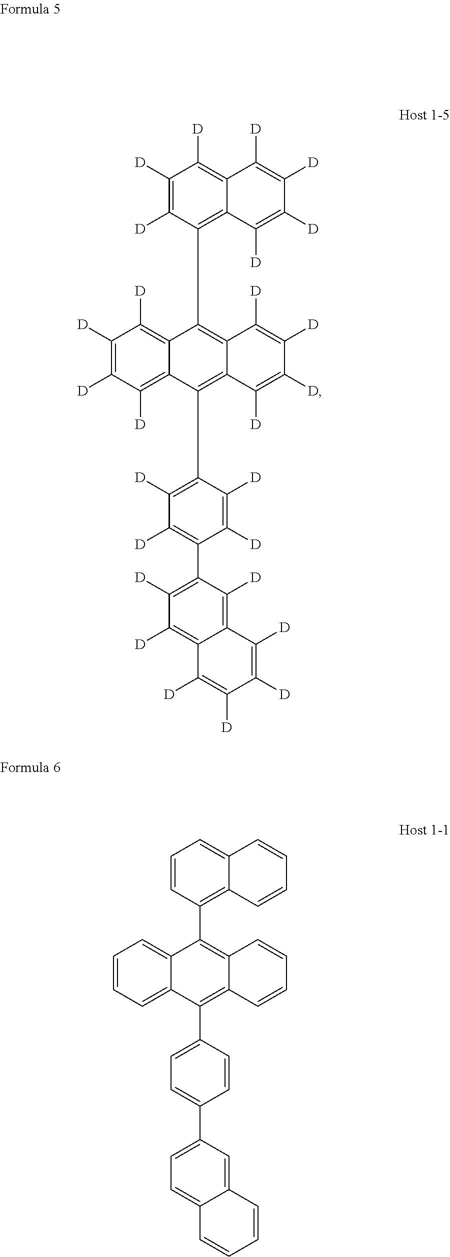

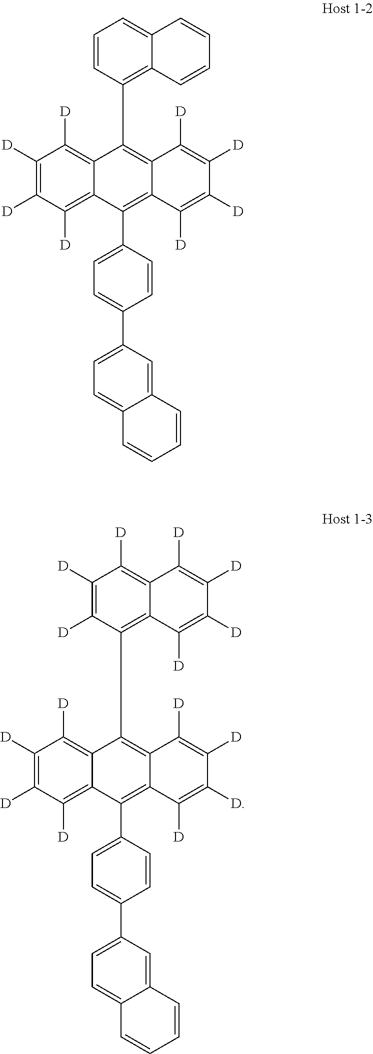

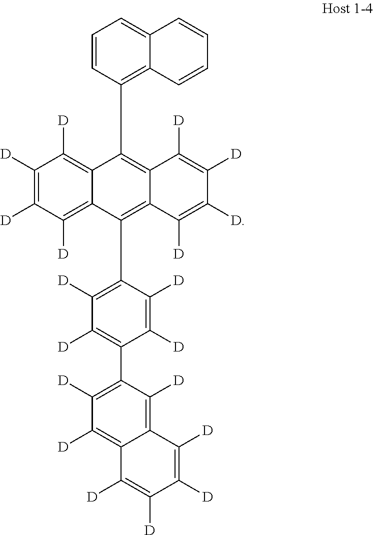

16. The organic light emitting device according to claim 13 wherein the first emitting material layer includes a third compound being a boron derivative, and the second emitting material layer includes a fourth compound being a boron derivative.

17. The organic light emitting device according to claim 16, wherein each of the third and fourth compounds is represented by Formula 7: 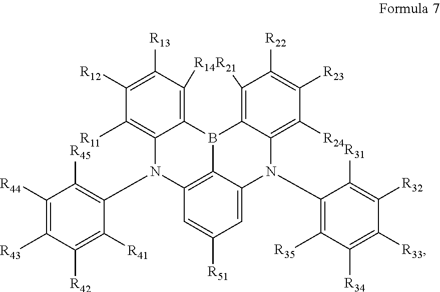
each of R₁₁, R₁₂, R₁₃ and R₁₄, each of R₂₁, R₂₂, R₂₃ and R₂₄, each of R₃₁, R₃₂, R₃₃, R₃₄ and R₃₅ and each of R₄₁, R₄₂, R₄₃, R₄₄ and R₄₅ is independently selected from the group consisting of hydrogen, deuterium, a C1 to C10 alkyl group, a C6 to C30 aryl group unsubstituted or substituted with C1-C10 alkyl, a C12 to C30 arylamino group and a C5 to C30 heteroaryl group, or adjacent two of R₁₁, R₁₂, R₁₃ and R₁₄, adjacent two of R₂₁, R₂₂, R₂₃ and R₂₄, adjacent two of R₃₁, R₃₂, R₃₃, R₃₄ and R₃₅ and adjacent two of R₄₁, R₄₂, R₄₃, R₄₄ and R₄₅ together with the carbon atoms to which they are attached are connected to form a fused ring, and
R₅₁ is selected from the group consisting of hydrogen, deuterium (D), a C1 to C10 alkyl group, a C3 to C30 cycloalkyl group, a C6 to C30 aryl group, a C5 to C30 heteroaryl group unsubstituted or substituted with at least one of deuterium and C1-C10 alkyl and a C6 to C30 arylamino group unsubstituted or substituted with at least one of deuterium and C1-C10 alkyl.

18. The organic light emitting device according to claim 17, wherein each of the third and fourth compounds is independently selected from compounds of Formula 8:

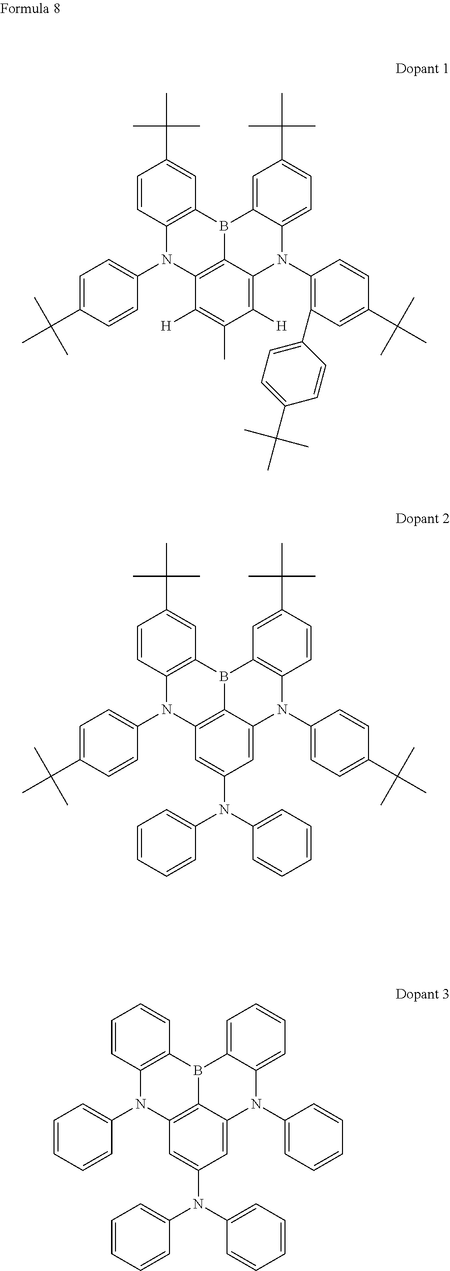

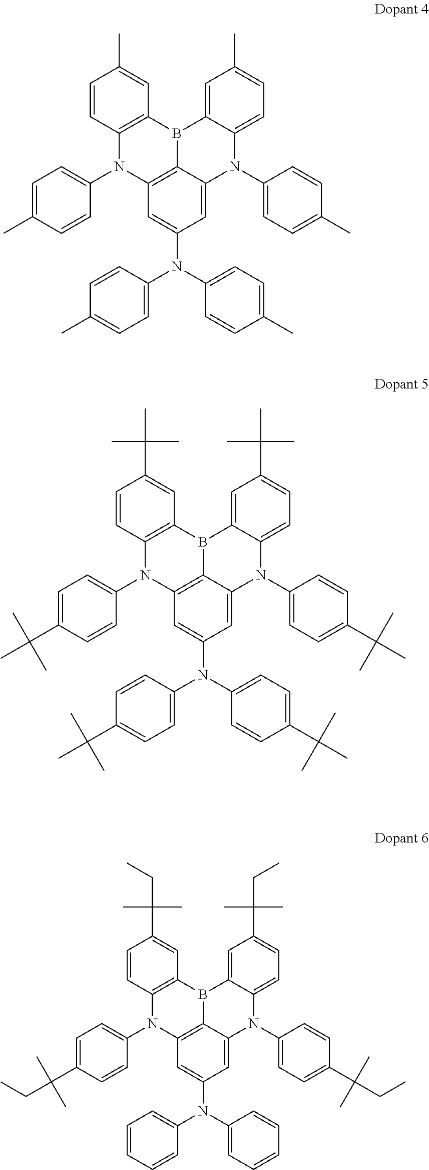

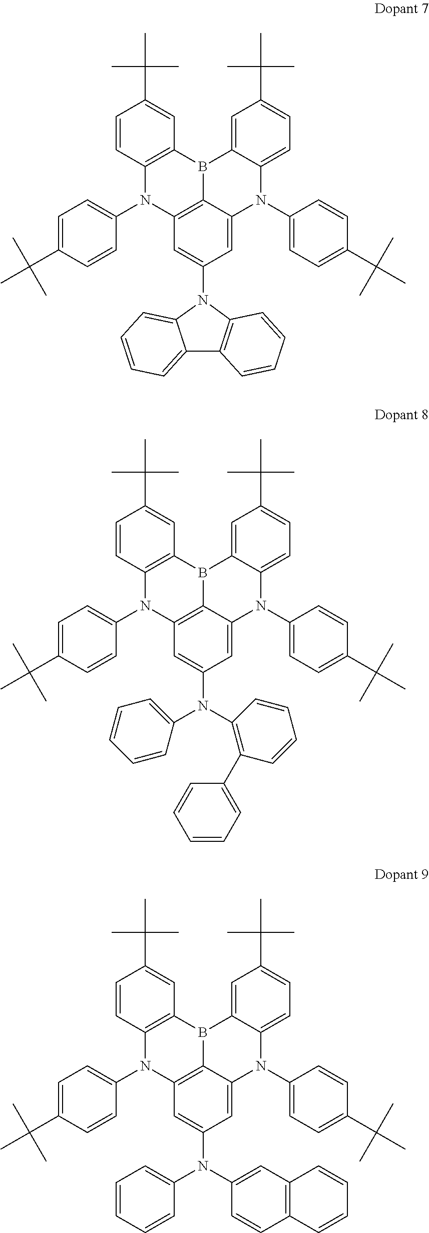

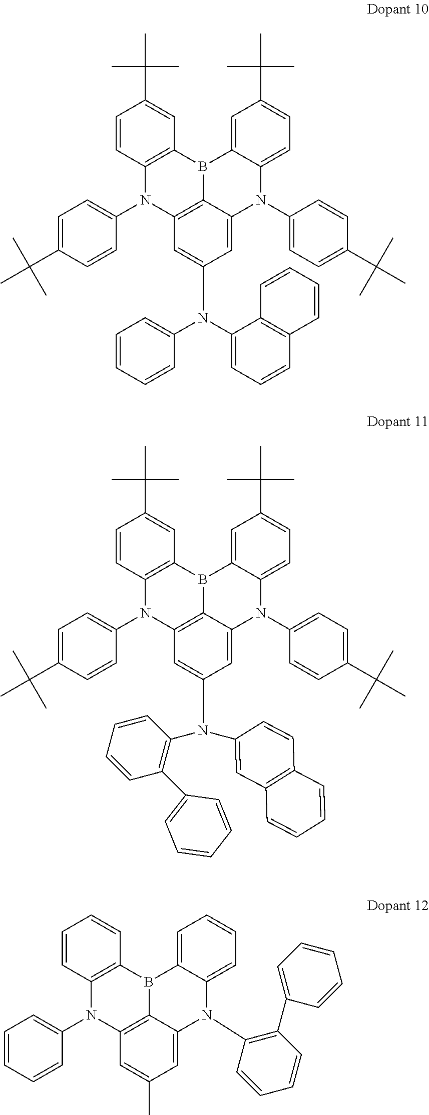

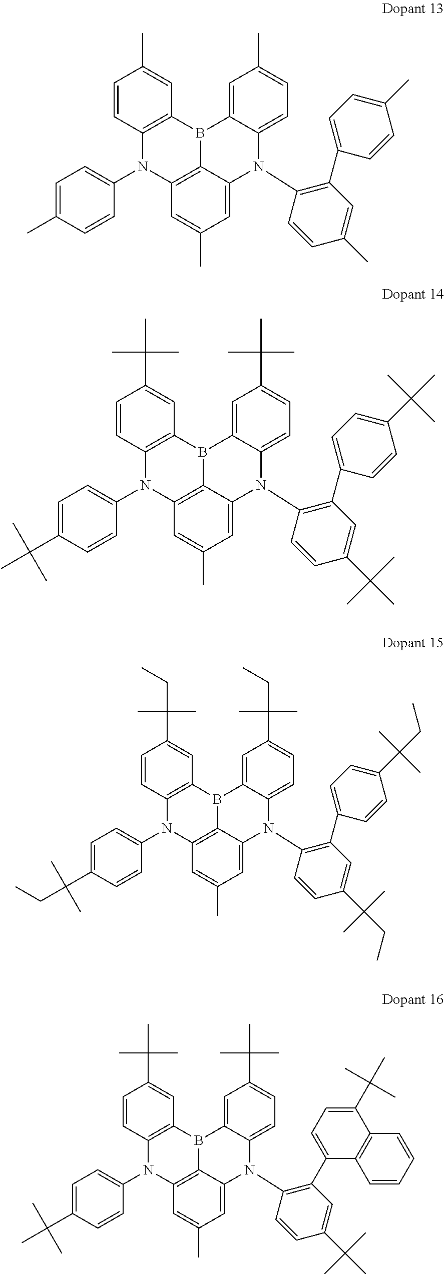

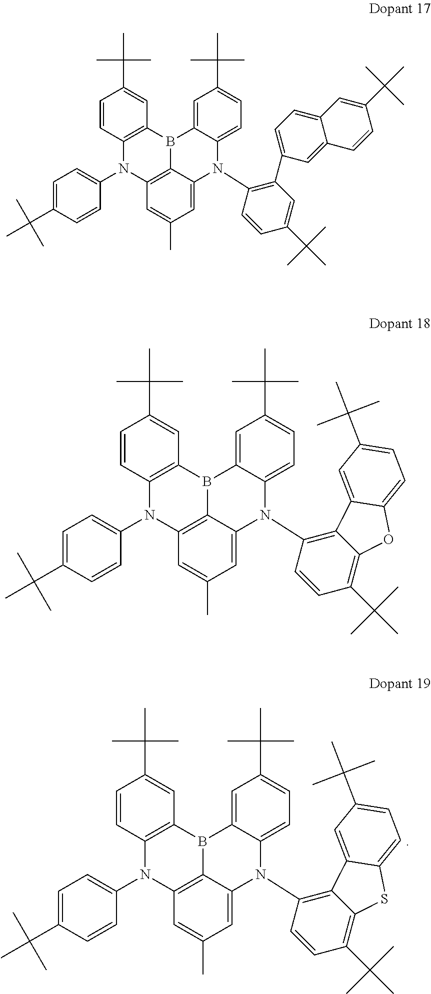

19. The organic light emitting device according to claim 16, wherein a weight % of the third compound in the first emitting material layer is equal to or greater than a weight % of the fourth compound in the second emitting material layer, and wherein a thickness of the first emitting material layer is equal to or smaller than a thickness of the second emitting material layer.

20. The organic light emitting device according to claim 13, further comprising:
a third emitting material layer between the first and second emitting material layers;
a first charge generation layer between the first and third emitting material layers; and
a second charge generation layer between the second and third emitting material layers.
